(19) United States
(12) Patent Application Publication
(10) Pub. No.: US 2009/0233222 A1
(43) Pub. Date: Sep. 17, 2009

(54) LITHOGRAPHIC PRINTING PLATE PRECURSOR

(76) Inventors: Takanori Mori, Shizuoka (JP); Shinya Kurokawa, Shizuoka (JP)

Correspondence Address: BIRCH STEWART KOLASCH & BIRCH, PO BOX 747, FALLS CHURCH, VA, 22040-0747, US

(21) Appl. No.: 12/402,377

(22) Filed: Mar. 11, 2009

(30) Foreign Application Priority Data
Mar. 12, 2008 (JP) P2008-062942

(51) Int. Cl. G03F 7/004

(52) U.S. Cl. 430/270.1

(57) ABSTRACT

A lithographic printing plate precursor includes an image recording layer and a support obtained by subjecting an aluminum plate having an iron content of 0.28 mass % or less to a surface roughening treatment and to an anodization treatment.

### CROSS-REFERENCE TO RELATED APPLICATIONS

This application claims the benefit of Japanese Patent Application JP 2008-062942, filed Mar. 12, 2008, the entire content of which is hereby incorporated by reference, the same as if set forth at length.

### FIELD OF THE INVENTION

The present invention relates to a negative lithographic printing plate precursor capable of being on-press developed with a printing ink and/or a fountain solution, particularly, a lithographic printing plate precursor excellent in the resistance to staining associated with corrosion of an aluminum plate.

### BACKGROUND OF THE INVENTION

The lithographic printing plate generally consists of a lipophilic image part of receiving an ink in the process of printing and a hydrophilic non-image part of receiving a fountain solution. The lithographic printing is a printing method where attachment of ink to the surface of a lithographic printing plate is made to differ between the ink-receiving part assigned to the lipophilic image part of the lithographic printing plate and the fountain solution-receiving part (ink non-receiving part) assigned to the hydrophilic non-image part by utilizing the property of water and oil-based ink repelling each other and after inking only the image part, the ink is transferred to a printing material such as paper.

For producing such a lithographic printing plate, a lithographic printing plate precursor (PS plate) comprising a hydrophilic support having provided thereon a lipophilic photosensitive resin layer (image recording layer) has been heretofore widely used. Usually, a lithographic printing plate is obtained by a plate-making method of exposing a lithographic printing plate precursor through an original image such as lith film and while allowing the image recording layer corresponding to an image part to remain, dissolving and removing the unnecessary image recording layer corresponding to a non-image part with an alkaline developer or an organic solvent-containing developer to reveal the hydrophilic support surface, thereby forming a non-image part.

In the plate-making process using a conventional lithographic printing plate precursor, a step of dissolving and removing the unnecessary image recording layer with a developer or the like must be provided after exposure but as one problem to be solved, it is demanded to dispense with or simplify such an additive wet processing. In particular, treatment of a waste solution discharged in the course of wet processing is recently a great concern to the entire industry in view of consideration for global environment and the demand for solving the above-described problem is becoming stronger.

As one of simple plate-making methods to cope with such a requirement, a method called on-press development has been proposed, where an image recording layer allowing for removal of the unnecessary portion of the image recording layer in a normal printing process is used and after exposure, the unnecessary portion of the image recording layer is removed on a printing press to obtain a lithographic printing plate.

Specific examples of the on-press development method include a method using a lithographic printing plate precursor having an image recording layer dissolvable or dispersible in a fountain solution, an ink solvent or an emulsified product of fountain solution and ink, a method of mechanically removing the image recording layer through contact with rollers or a blanket cylinder of a printing press, and a method of weakening the cohesion of the image recording layer or adhesion between the image recording layer and the support by the impregnation of a fountain solution, an ink solvent or the like and then mechanically removing the image recording layer through contact with rollers or a blanket cylinder.

On the other hand, a digitization technique of electronically processing, storing and outputting image information by using a computer has been recently widespread and various new image-output systems coping with such a digitization technique have been put into practical use. Along with this, a computer-to-plate technique is attracting attention, where digitized image information is carried on a highly converging radiant ray such as laser light and a lithographic printing plate precursor is scan-exposed by this light to directly produce a lithographic printing plate without intervention of a lith film. Accordingly, one of important technical problems to be solved is to obtain a lithographic printing plate precursor suited for such a technique.

For the simplification of the above-described plate-making operation, in view of ease of operation, a system using an image recording layer and a light source both handleable in a bright room or under a yellow lamp is preferred. As for the laser light source, a solid laser of emitting an infrared ray at a wavelength of 760 to 1,200 nm, such as semiconductor laser and YAG laser, is very useful, because a high-output and compact laser becomes inexpensively available. A UV laser may also be used.

As regards the on-press developable lithographic printing plate precursor of performing image recording by an infrared laser, for example, Japanese Patent No. 2,938,397 (corresponding to U.S. Pat. No. 6,030,750) describes a lithographic printing plate precursor where an image-forming layer comprising a hydrophilic binder having dispersed therein hydrophobic thermoplastic polymer particles is provided on a hydrophilic support. In Japanese Patent No. 2,938,397 (corresponding to U.S. Pat. No. 6,030,750), it is indicated that this lithographic printing plate precursor is exposed by an infrared laser to cause coalescence of hydrophobic thermoplastic polymer particles by the effect of heat and thereby form an image and after loading on a cylinder of a printing press, the lithographic printing plate precursor can be on-press developed with a fountain solution and/or an ink.

Also, JP-A-2001-277740 (the term “JP-A” as used herein means an “unexamined published Japanese patent application”) (corresponding to US 2001/0018159 A1) and JP-A-2001-277742 (corresponding to US 2001/0018159 A1) describe a heat-sensitive lithographic printing plate precursor comprising a hydrophilic support having thereon a layer containing a polymerizable compound-enclosing microcapsule. Furthermore, JP-A-2002-287334 (corresponding to US 2002/0177074 A1) describes a lithographic printing plate precursor comprising a support having provided thereon a photosensitive layer containing an infrared absorbent, a radical polymerization initiator and a polymerizable compound.

However, in these negative lithographic printing plate precursors, an image recording layer removable with a printing ink and/or a fountain solution is provided and this gives rise to a problem that because of many hydrophilic components contained in the image recording layer, the image recording layer is liable to contain water by the effect of outer air or the like and depending on the amounts of water and an anion component, corrosion of the aluminum substrate is caused, as a result, the non-image part is readily contaminated with an ink.

### SUMMARY OF THE INVENTION

An object of the present invention is to provide a negative lithographic printing plate precursor capable of being on-press developed with a printing ink and/or a fountain solution and excellent in the resistance to staining associated with corrosion of an aluminum plate.

As a result of intensive investigations, the present inventors have found that when the iron content in the substrate is decreased, corrosion of the aluminum plate is suppressed and staining of the non-image part is improved, and has accomplished the present invention. The present invention is as follows.

1. A lithographic printing plate precursor having an on-press developable image recording layer on a support obtained by subjecting an aluminum plate having an iron content of 0.28 mass % or less to a surface roughening treatment and then to an anodization treatment.

2. The lithographic printing plate precursor as described in 1 above, wherein the iron content of the aluminum plate is 0.26 mass % or less.

3. The lithographic printing plate precursor as described in 1 or 2 above, wherein the content of an anion component in the lithographic printing plate precursor is 0.7 mmol/m² or less.

4. The lithographic printing plate precursor as described in 3 above, wherein the content of an anion component in the lithographic printing plate precursor is 0.5 mmol/m² or less.

5. The lithographic printing plate precursor as described in 4 above, wherein the content of an anion component in the lithographic printing plate precursor is 0.3 mmol/m² or less.

6. The lithographic printing plate precursor as described in any one of 1 to 5 above, wherein the image recording layer is of photopolymerization type.

In the present invention, the iron content in an aluminum plate used for the support of the lithographic printing plate precursor is specified to be 0.28 mass % or less, whereby staining of the non-image part, particularly, dot-like printing stain of the non-image portion, can be improved. The operation mechanism therefor is considered as follows. The dot-like printing stain is ascribable to corrosion of an aluminum support during storage, but by setting the iron content in the aluminum plate to be 0.28 mass % or less, an intermetallic compound is decreased and an anodic oxide film allows for less generation of a defect area, as a result, the corrosion resistance is enhanced and the staining is improved.

According to the present invention, a negative lithographic printing plate precursor capable of being on-press developed with a printing ink and/or a fountain solution and excellent in the resistance to staining associated with corrosion of an aluminum plate can be provided.

### BRIEF DESCRIPTION OF THE DRAWINGS

FIG. 1 is a schematic cross-sectional view of the apparatus for performing a water washing treatment with a liquid film in a free-fall curtain shape, which is used for a water washing treatment in a production method of the lithographic printing plate support of the present invention.

FIG. 2 is a waveform diagram showing an example of the trapezoidal waveform in an electrochemical surface-roughening treatment using an alternating current, which is suitably employed in the present invention.

FIG. 3 is a side view showing an example of the radial type cell in an electrochemical surface-roughening treatment, which is suitably employed in the present invention.

FIG. 4 is a schematic view of the water vapor pore-sealing treatment tank suitably employed in the present invention.

### DESCRIPTION OF REFERENCE NUMERALS AND SIGNS

11: Aluminum plate
12: Radial drum roller
13a, 13b: Main electrode
14: Acidic aqueous solution
15: Solution supply port
16: Slit
17: Solution pathway
18: Auxiliary anode
19a, 19b: Thyristor
20: AC power source
21: Main electrolytic cell
22: Auxiliary anode cell
30: Treatment tank
31, 32: Water seal tank
33: Aluminum plate
34: Nip roller
35: Water vapor spray tube
36: Heat exchanger
37: Boiler water tank
100: Apparatus of performing a water washing treatment with a liquid film in a free-fall curtain shape
102: Water
104: Water storage tank
106: Water supply tube
108: Flow controller part

### DETAILED DESCRIPTION OF THE INVENTION

The present invention is described in detail below.

### [Support]

### <Aluminum Plate>

The aluminum plate used for the support of the lithographic printing plate precursor of the present invention is not particularly limited in its composition as long as the content of iron (Fe) is 0.28 mass % or less. The Fe content is preferably 0.26 mass % or less, and pure aluminum is more preferred.

When the Fe content of the aluminum plate is in this range, corrosion of the aluminum support is suppressed, as a result, the problem of the non-image part being readily contaminated with an ink can be solved.

Since perfectly pure aluminum is difficult to produce in view of refining technique, in the present invention, aluminum containing trace heteroelements (as for Fe, its content is 0.28 mass % or less) may be used. Conventionally known materials described, for example, in Aluminum Handbook, 4th ed., Keikinzoku Kyokai (1990), such as JIS 1050 material, JIS 1100 material, JIS 1070 material, Mn-containing JIS 3004 material and international registered alloy 3103A, may be used. Also, an Al—Mg-based alloy and an Al—Mn-Mg-based alloy (JIS 3005 material), where 0.1 mass % or more of magnesium is added to such an aluminum alloy for the purpose of increasing the tensile strength, may be used. Furthermore, an Al—Zr-based or Al—Si-based alloy containing Zr or Si may also be used. In addition, an Al—Mg—Si-based alloy may also be used.

In the present invention, the aluminum alloy preferably contains Si, Cu and Mg. More specifically, an aluminum alloy comprising from 0.01 to 0.2 mass % of Si, from 0.005 to 0.035 mass % of Cu and from 0.005 to 0.4 mass % of Mg, with the balance being Al and unavoidable impurities, is preferably used.

The JIS 1050 material is described in JP-A-59-153861, JP-A-61-51395, JP-A-62-146694, JP-A-60-215725, JP-A-60-215726, JP-A-60-215727, JP-A-60-216728, JP-A-61-272367, JP-A-58-11759, JP-A-58-42493, JP-A-58-221254, JP-A-62-148295, JP-A-4-254545, JP-A-4-165041, JP-B-3-68939 (the term “JP-B” as used herein means an “examined Japanese patent publication”), JP-A-3-234594, JP-B-1-47545 and JP-A-62-140894. Also, techniques described in JP-B-1-35910, JP-B-55-28874 and the like are known.

The JIS 1070 material is described in JP-A-7-81260, JP-A-7-305133, JP-A-8-49034, JP-A-8-73974, JP-A-8-108659 and JP-A-8-92679.

The Al—Mg-based alloy is described in JP-B-62-5080, JP-B-63-60823, JP-B-3-61753, JP-A-60-203496, JP-A-60-203497, JP-B-3-11635, JP-A-61-274993, JP-A-62-23794, JP-A-63-47347, JP-A-63-47348, JP-A-63-47349, JP-A-64-1293, JP-A-63-135294, JP-A-63-87288, JP-B-4-73392, JP-B-7-100844, JP-A-62-149856, JP-B-4-73394, JP-A-62-181191, JP-B-5-76530, JP-A-63-30294 and JP-B-6-37116. Such a material is also described, for example, in JP-A-2-215599 and JP-A-61-201747.

The Al—Mn-based alloy is described in JP-A-60-230951, JP-A-1-306288 and JP-A-2-293189. Such a material is also described, for example, in JP-B-54-42284, JP-B-4-19290, JP-B-4-19291, JP-B-4-19292, JP-A-61-35995, JP-A-64-51992, J-A-4-226394, and U.S. Pat. Nos. 5,009,722 and 5,028,276.

The Al—Mn-Mg-based alloy is described in JP-A-62-86143 and JP-A-3-222796. Such a material is also described, for example, in JP-B-63-60824, JP-A-60-63346, JP-A-60-63347, JP-A-1-293350, European Patent 223,737, U.S. Pat. No. 4,818,300 and British Patent 1,222,777.

The Al—Zr-based alloy is described in JP-B-63-15978 and JP-A-61-51395. Such a material is also described, for example, in JP-A-63-143234 and JP-A-63-143235.

The Al—Mg—Si-based alloy is described, for example, in British Patent 1,421,710.

The aluminum alloy may be formed into a plate material, for example, by the following method. First, a molten aluminum alloy adjusted to have predetermined alloy component contents is purified and cast by an ordinary manner. In the purification treatment, unnecessary gases such as hydrogen in the molten metal are removed by performing a flux treatment; a degassing treatment using argon gas, chlorine gas or the like; a filtering treatment using a so-called rigid media filter such as ceramic tube filter or ceramic foam filter, a filter employing alumina flake, alumina ball or the like as the filter media, a glass cloth filter or the like; or a combination of a degassing treatment and a filtering treatment.

Such a purification treatment is preferably performed so as to prevent defects due to foreign matters such as non-metal inclusion and oxide in the molten metal or defects due to a gas mixed into the molten metal. The filtering of the molten metal is described, for example, in JP-A-6-57432, JP-A-3-162530, JP-A-5-140659, JP-A-4-231425, JP-A-4-276031, JP-A-5-311261 and JP-A-6-136466. The degassing of the molten metal is described, for example, in JP-A-5-51659 and JP-UM-A-5-49148 (the term “JP-UM-A” as used herein means an “unexamined published Japanese utility model application”). Techniques regarding the degassing of a molten metal are described in JP-A-7-40017.

The thus-purified molten metal is then cast. The casting method includes a method using a fixed mold, as typified by DC casting, and a method using a driven mold, as typified by continuous casting.

In the DC casting, solidification occurs at a cooling rate of 0.5 to 30° C./sec. If the cooling rate is less than 1° C., many coarse intermetallic compounds may be formed. In the case of performing the DC casting, an ingot having a plate thickness of 300 to 800 mm can be produced. The ingot is, if desired, scalped in an ordinary manner, and the surface layer is scalped usually in a thickness of 1 to 30 mm, preferably from 1 to 10 mm. Before or after the scalping, a soaking treatment may be performed, if desired. In the case of performing a soaking treatment, a heat treatment is performed at 450 to 620° C. for 1 to 48 hours so as not to coarsen the intermetallic compound. If the heat-treatment time is less than one hour, insufficient soaking effect may result. When a soaking treatment is not performed, this is advantageous in that the cost can be reduced.

Thereafter, hot rolling and cold rolling are performed to obtain an aluminum rolled plate. The hot rolling initiation temperature is suitably from 350 to 500° C. Before, after or during hot rolling, an intermediate annealing treatment may be performed. As for the conditions of the intermediate annealing treatment, the treatment is performed by heating the aluminum plate in a batchwise annealing furnace at 280 to 600° C. for 2 to 20 hours, preferably at 350 to 500° C. for 2 to 10 hours, or in a continuous annealing furnace at 400 to 600° C. for 6 minutes or less, preferably at 450 to 550° C. for 2 minutes or less. Also, the crystal structure may be microstructured by heating the aluminum plate in a continuous annealing furnace at a temperature-rising rate of 10 to 200° C./sec.

The aluminum plate finished to a predetermined thickness, for example, from 0.1 to 0.5 mm through the above-described steps may be further improved in the planarity by a straightening device such as roller leveler or tension leveler. The step of improving the planarity may be performed after the aluminum plate is cut into a sheet form, but in order to enhance the productivity, the step is preferably performed while the aluminum is in a continuous coil state. The aluminum plate may also be passed through a slitter line to work it to a predetermined plate width. Furthermore, in order to prevent generation of scratches due to friction of aluminum plates with each other, a thin oil film may be provided on the surface of the aluminum plate. A volatile or non-volatile oil film is appropriately used, if desired.

The continuous casting method which is employed in industry includes a twin roll method (Hunter method), a method using a cold roller, as typified by 3C method, a twin belt method (Hazellett method), and a method using a cooling belt or a cooling block, as typified by Model Alusuisse Caster II. In the case of using the continuous casting method, solidification occurs at a cooling rate of 100 to 1,000° C./sec. In the continuous casting method, the cooling rate is generally high as compared with the DC casting method and therefore, the method is characterized in that the degree of solid solution of alloy components in the aluminum matrix can be made high. The continuous casting method is described in JP-A-3-79798, JP-A-5-201166, JP-A-5-156414, JP-A-6-262203, JP-A-6-122949, JP-A-6-210406 and JP-A-6-26308.

In the case of performing the continuous casting, for example, when a method using a cooling roll such as Hunter method is employed, a cast plate having a plate thickness of 1 to 10 mm can be directly and continuously produced and the hot rolling step can be advantageously dispensed with. Also, when a method using a cooling belt such as Hazellett method is employed, a cast plate having a plate thickness of 10 to 50 mm can be produced and by disposing a hot rolling roller and continuously rolling the aluminum plate immediately after the casting, a continuously cast and rolled plate having a plate thickness of 1 to 10 mm can be obtained.

The continuously cast and rolled plate is, similarly to the DC casting, passed through the steps such as cold rolling, intermediate annealing, improvement of planarity and slitting, and thereby finished to a predetermined thickness, for example, from 0.1 to 0.5 mm. The intermediate annealing conditions and cold rolling conditions in the case of using the continuous casting method are described in JP-A-6-220593, JP-A-6-210308, JP-A-7-54111 and JP-A-8-92709.

The aluminum plate for use in the present invention is preferably an aluminum plate subjected to tempering H18 specified in JIS.

The thus-produced aluminum plate is expected to have the following various properties. As for the strength of the aluminum plate, the 0.2% proof strength is preferably 120 MPa or more so as to obtain a firm elasticity required of the lithographic printing plate support. Also in the case of performing a burning treatment, the 0.2% proof strength after a heat treatment at 270° C. for 3 to 10 minutes is preferably 80 MPa or more, more preferably 100 MPa or more, so as to obtain a certain firm elasticity. In particular, when firm elasticity is required of the aluminum plate, an aluminum material having added thereto Mg or Mn may be employed, but increase in the firm elasticity may deteriorate the ease of fitting to a plate cylinder of a printing press. Therefore, the material and the amounts added of trace components are appropriately selected according to usage. These are described, for example, in JP-A-7-126820 and JP-A-62-140894.

The aluminum sheet preferably has a tensile strength of 160±15 N/mm², a 0.2% proof strength of 140±15 MPa, and an elongation, specified in JIS Z2241 and Z2201, of 1 to 10%.

The crystal structure of the aluminum plate is preferably not so coarse on the surface, because when a chemical surface roughening treatment or an electrochemical surface roughening treatment is performed, the crystal structure on the surface of the aluminum plate sometimes gives rise to the generation of failure in the surface quality. The crystal structure on the surface of the aluminum plate preferably has a width of 200 μm or less, more preferably 100 μm or less, still more preferably 50 μm or less, and the length of the crystal structure is preferably 5,000 μm or less, more preferably 1,000 μm or less, still more preferably 500 μm or less. These are described, for example, in JP-A-6-218495, JP-A-7-39906 and JP-A-7-124609.

The alloy component distribution of the aluminum plate is preferably not so non-uniform on the surface, because when a chemical surface roughening treatment or an electrochemical surface roughening treatment is performed, the non-uniform distribution of alloy components on the surface of the aluminum plate sometimes gives rise to the generation of failure in the surface quality. These are described, for example, in JP-A-6-48058, JP-A-5-301478 and JP-A-7-132689.

As for the intermetallic compound of the aluminum plate, the size or density of the intermetallic compound sometimes affects the chemical surface roughening treatment or electrochemical surface roughening treatment. These are described, for example, in JP-A-7-138687 and JP-A-4-254545.

The aluminum plate for use in the present invention is a continuous belt-like sheet or plate material. That is, the aluminum plate may be an aluminum web or a foliated sheet cut into, for example, a size corresponding to the lithographic printing plate precursor shipped as a product.

A scratch on the surface of the aluminum plate has a possibility of becoming a defect when worked into a lithographic printing plate support and therefore, generation of a scratch must be prevented as much as possible at the stage before a surface treatment step of producing a lithographic printing plate support. For this purpose, the aluminum plate is preferably packaged in a stable form insusceptible to scratching during transportation.

In the case of an aluminum web, the packaging form of aluminum is, for example, such that a hard board and a felt are spread in an iron-made pallet, a donut-like corrugated board is padded to both ends of the product, the entire is wrapped with a polytube, a donut-shaped wood is inserted into the inner part of a coil, a felt is padded to the outer periphery of the coil, an iron belt is braced, and an index is applied to the circumference thereof. A polyethylene film can be used as the packaging material, and a needle felt or a hard board can be used as the padding. Other than these, various forms may be employed. As long as the transportation or the like can be stably performed without causing a scratch, the packaging form is not limited to the method above.

The thickness of the aluminum plate for use in the present invention is approximately from 0.1 to 0.6 mm, preferably from 0.15 to 0.4 mm, more preferably from 0.2 to 0.3 mm. This thickness may be appropriately changed according to the size of the printing press, the size of the printing plate, the request by the user, or the like.

### <Surface Treatment>

The support for use in the lithographic printing plate precursor of the present invention is obtained by subjecting the above-described aluminum plate to at least a electrochemical surface-roughening treatment and an anodization treatment in this order.

Suitable examples of the method for forming a grained shape on the surface of the lithographic printing plate support for use in the present invention include a method of performing, in order, (a) a mechanical surface-roughening treatment, (b) an etching treatment in an aqueous alkali solution (hereinafter, simply referred to as an “alkali etching treatment”), (c) a desmutting treatment with an acid (hereinafter, simply referred to as a “desmutting treatment”), (d) an electrochemical surface-roughening treatment using a nitric acid-containing aqueous solution as an electrolytic solution (hereinafter, simply referred to as “nitric acid electrolysis”), (e) an alkali etching treatment, (f) a desmutting treatment, (g) an electrochemical surface-roughening treatment using a hydrochloric acid-containing aqueous solution as an electrolytic solution (hereinafter, simply referred to as “hydrochloric acid electrolysis”), (h) an alkali etching treatment, (i) a desmutting treatment, and (j) an anodization treatment.

Other examples include a method omitting (a) from the above-described method, a method omitting (g) to (i) from the above-described method, a method omitting (a) and (g) to (i) from the above-described method, a method omitting (d) to (f) from the above-described method, and a method omitting (a) and (d) to (f) from the above-described method.

Depending on the case, a hole-sealing treatment and/or a hydrophilic treatment may be applied after the anodization treatment (j).

A water washing treatment is usually performed between respective treatments above so as not carry over the processing solution to the next step. The water washing treatment is preferably a treatment where water washing is performed using an apparatus of effecting a water washing treatment with a liquid film in a free-fall curtain shape and then the aluminum plate is further washed with water by using a spray tube.

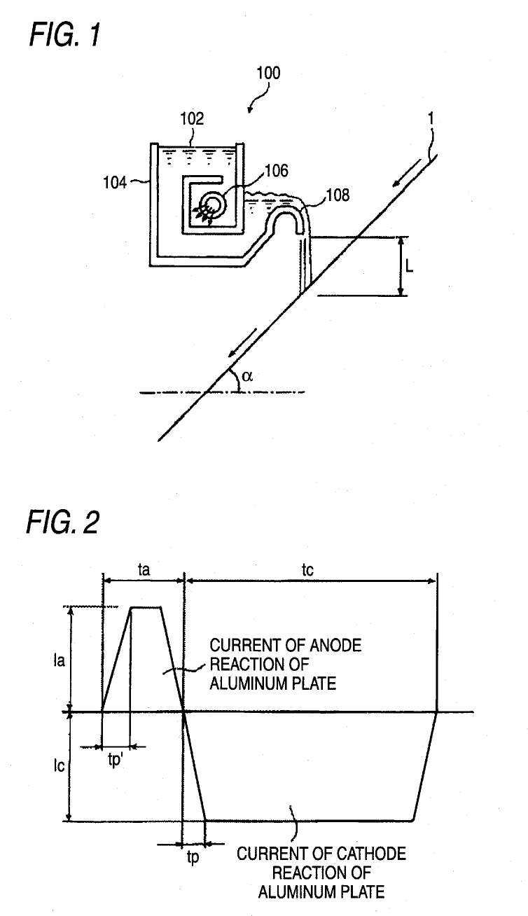

FIG. 1 is a schematic cross-sectional view of an apparatus of effecting a water washing treatment with a liquid film in a free-fall curtain shape. As shown in FIG. 1, an apparatus 100 of performing a water washing treatment with a liquid film in a free-fall curtain shape comprises a water storage tank 104 for storing water 102, a water supply tube 106 for supplying water to the water storage tank 104, and a flow controller part 108 for supplying a liquid film in a free-fall curtain shape from the water storage tank 104 to an aluminum plate 1.

In the apparatus 100, water 102 is supplied from the water supply tube 106 to the water storage tank 104 and the water flow is controlled by the flow controller part 108 when the water 102 overflows from the water storage tank 104, whereby a liquid film in a free-fall curtain shape is supplied to the aluminum plate 1. In the case of using the apparatus 100, the fluid volume is preferably from 10 to 100 L/min. Also, the distance L in which water 102 exists as a liquid film in a free-fall curtain shape between the apparatus 100 and the aluminum 1 is preferably from 20 to 50 mm. Furthermore, the angle α of the aluminum plate is preferably from 30 to 80° with respect to the horizontal direction.

When an apparatus shown in FIG. 1 of effecting a water washing treatment with a liquid film in a free-fall curtain shape is used, a water washing treatment can be uniformly applied to the aluminum plate and therefore, uniformity of the treatment performed before the water washing treatment can be enhanced.

Suitable examples of the apparatus of effecting a water washing treatment with a liquid film in a free-fall curtain shape include an apparatus described in JP-A-2003-96584.

As regards the spray tube for use in the water washing treatment, for example, a spray tube with a plurality of spray tips arranged in the width direction of the aluminum plate and configured to fan out the injection water may be used. The distance between spray tips is preferably from 20 to 100 mm, and the fluid volume per one spray tip is preferably from 0.5 to 20 L/min. It is preferred to use a plurality of such spray tubes.

Respective steps of the surface treatment illustrated above are described in detail below.

### <Mechanical Surface-Roughening Treatment>

A mechanical surface-roughening treatment can form a surface with irregularities having an average wavelength of 5 to 100 μm at a low cost as compared with an electrochemical surface-roughening treatment and therefore, is effective as means for a surface-roughening treatment.

Examples of the mechanical surface-roughening treatment which can be used include a wire brush graining method of scratching an aluminum plate surface with a metal wire, a ball graining method of graining an aluminum plate surface with an abrasive ball and an abrasive, and a brush graining method of graining a surface with a nylon brush and an abrasive described in JP-A-6-135175 and JP-B-50-40047.

In the brush graining method, a roller bush prepared by implanting a large number of brush bristles such as synthetic resin bristle made of a synthetic resin (e.g., Nylon (trademark), propylene, vinyl chloride resin) on a cylindrical barrel is used, and one surface or both surfaces of the aluminum plate are rubbed with the brush while splashing a slurry solution containing an abrasive on the rotating roller brush. In place of the roller brush and slurry solution above, an abrasive roller where an abrasive layer is provided on the surface may also be used.

In the case of using a roller brush, a brush bristle having a bending modulus of preferably 10,000 to 40,000 kg/cm², more preferably from 15,000 to 35,000 kg/cm², and a firm elasticity of preferably 500 g or less, more preferably 400 g or less, is used. The diameter of the brush bristle is generally from 0.2 to 0.9 mm. The length of the brush bristle may be appropriately determined according to the outer diameter of the roller brush and the diameter of the barrel but is generally from 10 to 100 mm.

As for the abrasive, a known abrasive may be used. Examples of the abrasive which can be used include an abrasive such as pumice stone, silica sand, aluminum hydroxide, alumina powder, silicon carbide, silicon nitride, volcanic ash, carborundum and emery, and a mixture thereof. Among these, pumice stone and silica sand are preferred, and silica sand is more preferred because this is hard and not easily broken as compared with pumice stone and ensures an excellent surface-roughening efficiency.

The average particle diameter of the abrasive is preferably from 3 to 50 μm, more preferably from 6 to 45 μl, from the standpoint that the surface-roughening efficiency is excellent and the graining pitch can be narrowed. The abrasive is used, for example, as a slurry solution by suspending it in water. In addition to an abrasive, the slurry solution may contain a thickener, a dispersant (for example, a surfactant), an antiseptic agent and the like. The specific gravity of the slurry solution is preferably from 0.5 to 2.

Examples of the apparatus suitable for the mechanical surface-roughening treatment by the brush graining method include an apparatus described in JP-B-50-40047.

In the present invention, suitable examples of the method for the mechanical surface-roughening treatment include a method of forming irregularities by press rolling or transfer.

Above all, the treatment is preferably performed by a method where in combination with cold rolling of adjusting the aluminum plate to a final plate thickness (final cold rolling step) or finish cold rolling of finishing the surface profile after the final plate thickness adjustment, an embossing roll as a rolling roll having formed thereon an irregularity surface is press-contacted with the aluminum plate to transfer the surface profile and form an irregularity pattern on the aluminum plate surface. Specifically, the method described in JP-A-6-262203 may be suitably used.

By use of an aluminum plate having on the surface thereof an irregularity pattern, an irregularity pattern uniform in the average pitch and depth as compared with an irregularity pattern formed by using a brush and an abrasive can be obtained and therefore, stain resistance is enhanced. Also, the amount of a fountain solution on a printing press can be easily adjusted while reducing the energy consumption in the subsequent alkaline etching treatment.

The rolling for transferring the irregularity profile is preferably performed by 1 to 3 passes, and the rolling reduction in each pass is preferably from 3 to 8%.

Also, the irregularities imparted by transfer are preferably imparted to both sides of the aluminum plate. In this case, the elongation percentage of the aluminum plate can be adjusted to the same level between the front side and the back side and therefore, an aluminum plate with good planarity can be obtained.

Examples of the method for obtaining an embossing roll include a method of subjecting a steel-made roll to a surface-roughening treatment by shot blasting or sand blasting, a method of polishing the roll surface with an abrasive grain-containing grinding stone or a sandpaper, a method of irradiating a laser to form pits, and a method of applying a chemical or electrochemical surface-roughening treatment.

The surface-roughening treatment by shot blasting or sand blasting may be a wet system or a dry system. When an alumina particle with individual particles having a sharp edge is used for the grit, deep and uniform irregularities can easily formed on the surface of the embossing roll. The average particle diameter of the alumina particle is preferably from 1 to 300 μm, more preferably 5 to 100 μm, still more preferably from 10 to 50 μm. Within this range, a surface roughness sufficiently large as an embossing roll can be obtained and in the aluminum plate imparted with irregularities by using this embossing roll, the surface roughness can become sufficiently large and a sufficiently large number of pits can be formed.

In the air blasting method using shot blasting or sand blasting, blasting is preferably performed twice. When blasting is performed twice, non-uniform protruded portions in irregularities formed by the first blasting can be shaved off by the second blasting and this hardly allows for local formation of deep recessed portions on the surface of the aluminum plate imparted with irregularities by using the transfer roll obtained. As a result, the on-press developability (sensitivity) of the lithographic printing plate becomes excellent.

After the air blasting treatment but before the plating treatment described later, the transfer roll is preferably polished with a sandpaper or a grinding stone until the average surface roughness (Rₐ) is reduced by 10 to 40% based on the value after air blasting. By virtue of polishing, the protruded portions on the surface of the embossing roll can have a uniform height and this hardly allows for local formation of deep portions on the surface of the aluminum plate imparted with irregularities by using the transfer roll obtained. As a result, the on-press developability of the lithographic printing plate becomes excellent.

In the case of applying a chemical or electrochemical surface-roughening treatment, it is also possible to coat a resist, form a pattern through exposure and development, and perform an etching treatment to form irregularities in the pattern. Furthermore, irregularities may also be formed by subjecting the roll surface to an electrolysis in an aqueous solution containing at least one acid selected from the group consisting of nitric acid, hydrochloric acid, sulfuric acid, chromic acid and phosphoric acid, by using the roll as the anode.

The embossing roll obtained by the method above is then preferably subjected to a hardening treatment such as quenching or hard chromium plating so as to prevent wear of the surface.

The hardening treatment is preferably hard chromium plating. The hard chromium plating may be performed by an electroplating method using a CrO₃—SO₄ bath, a CrO₃—SO₄-fluoride bath or the like, which is conventionally well-known as an industrial chromium plating method.

The thickness of the hard chromium plating film is preferably from 3 to 15 μm, more preferably from 5 to 10 μm. Within this range, plate delamination less occurs, that is, the plating film portion is scarcely separated from the interface between the roll surface substrate and the plating film, and moreover, the effect of enhancing wear resistance is sufficiently high. The thickness of the hard chromium plating film can be adjusted by controlling the plating treatment time.

The aluminum plate having formed thereon an irregularity pattern by using the embossing roll preferably has a structure where irregularities having an average opening diameter (pitch) of 5 to 100 μm are formed on the surface.

In this case, the average surface roughness Rₐ is preferably from 0.4 to 1.5 μm, more preferably from 0.4 to 0.8 μm. Rₘₐₓ is preferably from 1 to 6 μm, more preferably from 2 to 5 μm, an Rₘₐₓ is preferably from 5 to 150 μm, more preferably from 10 to 100 μm.

The number of recesses is preferably from 200 to 40,000 recesses/mm².

As regards the method for measuring the average surface roughness Rₐ of the aluminum plate, after performing two-dimensional roughness measurement by using a stylus-type roughness meter (e.g., Surfcom 575 manufactured by Tokyo Seimitsu Co., Ltd.), the average surface roughness Rₐ specified in ISO 4287 is measured five times, and the average thereof is taken as the average roughness.

The conditions in the two-dimensional roughness measurement are set forth below.

### (Measurement Conditions)

Cutoff value: 0.8 mm, slope correction: FLAT-ML, measurement length: 3 mm, vertical magnification: 10,000 times, scan rate: 0.3 mm/sec, stylus tip diameter: 2 μm.

Incidentally, Rₘₐₓ and Rₛₘ can be measured according to ISO 4287.

The aspect ratio (length in the long axis direction of an elliptical pit/length in the short axis direction) of a recess formed on the aluminum plate surface is measured as follows. For example, the aluminum plate surface is photographed from directly above at a magnification of 500 to 1,000 times, preferably from 700 to 800 times, by using an electron microscope. In the obtained electron micrograph, at least 50 elliptical recesses are extracted, the length of the long axis direction and the length in the short axis direction of each recess are read, the ratio of length in the long axis direction/length in the short axis direction is determined, and an average value is calculated.

The number of recesses on the surface can be determined similarly by photographing the aluminum plate surface from directly above by using an electron microscope.

Other than these mechanical surface-roughening treatments, the methods described, for example, in JP-A-61-162351 and JP-A-63-104889 may also be used.

In the present invention, the above-described methods may also be used in combination by taking into account the productivity and the like. Such a mechanical surface-roughening treatment is preferably performed before an electrochemical surface-roughening treatment.

### <Electrochemical Surface-Roughening Treatment>

The electrochemical surface-roughening treatment is a step of electrochemically roughening the surface of the aluminum plate in an acidic aqueous solution by passing an alternating current and using the aluminum plate as an electrode.

As for the acidic aqueous solution used in the electrochemical surface-roughening treatment, those usually employed in an electrochemical surface-roughening treatment using a direct current or an alternating current may be used. Above all, an aqueous solution containing nitric acid and/or hydrochloric acid is preferably used.

In the present invention, when the ratio Q_{C}/Q_{A} between the quantity of electricity when the aluminum plate serves as the cathode in the electrochemical surface-roughening treatment, that is, the quantity of electricity Q_{C} at cathode time, and the quantity of electricity when the plate serves as the anode, that is, the quantity of electricity Q_{A} at anode time, is set to fall within the range of 0.5 to 2.0, uniform honeycomb pits can be produced on aluminum plate surface. If Q_{C}/Q_{A} is less than 0.50, non-uniform honeycomb pits are liable to result, and also if it exceeds 2.0, non-uniform honeycomb pits are readily formed. The Q_{C}/Q_{A} ratio is preferably in a range of 0.8 to 1.5.

The waveform of the alternating current used in electrochemical surface-roughening treatment includes, for example, a sinusoidal wave (sine wave), a rectangular wave, a triangular wave and a trapezoidal wave. Also, in view of the production cost of the power source device, the frequency of the alternating current is preferably from 30 to 200 Hz, more preferably from 40 to 120 Hz, still more preferably from 50 to 60 Hz.

FIG. 2 shows one example of the trapezoidal wave that can be suitably used in the present invention. In FIG. 2, the ordinate indicates the current value and the abscissa indicates the time. Also, ta is the anode reaction time, tc is the cathode reaction time, tp is the time until the current value reaches a peak on the cathode cycle side from zero, tp′ is the time until the current value reaches a peak on the anode cycle side from zero, Ia is the peak current on the anode cycle side, and Ic is the peak current on the cathode cycle side. In the case of using a trapezoidal wave as the alternating current waveform, the times tp and tp′ until the current reaches a peak from zero each is preferably from 0.1 to 2 msec, more preferably from 0.3 to 1.5 msec. If tp and tp′ each is less than 0.1 msec, this affects the power circuit impedance and a large power supply voltage is required during rise in the current waveform, leading to an increase in the cost of the power source equipment, whereas if tp and tp′ each exceeds 2 msec, the trace components in the acidic aqueous solution come to have a great effect and this sometimes make it difficult to perform a uniform surface-roughening treatment.

In view of uniform surface roughening, the duty of the alternating current used in the electrochemical surface-roughening treatment is preferably from 0.25 to 0.75, more preferably from 0.4 to 0.6. The term “duty” as used in the present invention means a ratio ta/T, where T is the period of the alternating current and ta is the time for which the anode reaction of the aluminum plate continues (anode reaction time). In particular, not only production of a smut component mainly composed of aluminum hydroxide but also occurrence of dissolution or breakdown of the oxide film proceeds on the aluminum plate surface during the cathode reaction, and these become a starting point of the pitting reaction at the subsequent anode reaction of the aluminum plate. Therefore, selection of the duty of the alternating current has a great effect on uniform surface-roughening.

As for the current density of the alternating current, in the case of a trapezoidal or rectangular wave, the current density lap at the peak on the anode cycle side and the current density Icp at the peak on the cathode cycle side each is preferably from 10 to 200 A/dm². Also, the ratio Icp/Iap is preferably from 0.9 to 1.5.

In the electrochemical surface-roughening treatment, the total amount of electricity used in the anode reaction of the aluminum plate at the completion of the electrochemical surface-roughening treatment is preferably from 50 to 1,000 C/dm². The electrochemical surface-roughening treatment time is preferably from 1 second to 30 minutes.

In the electrochemical surface-roughening treatment, a known electrolytic apparatus such as vertical type, flat type and radial type may be used, but a radial electrolytic apparatus as described in JP-A-5-195300 is particularly preferred.

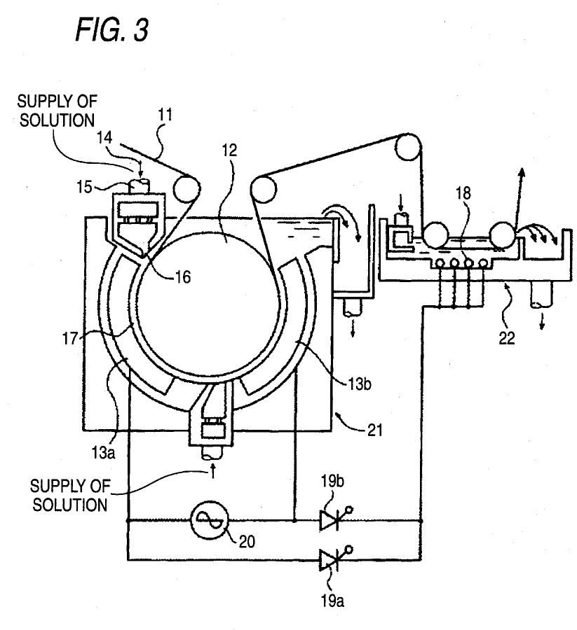

FIG. 3 is a schematic view of a radial electrolytic apparatus suitable used in the present invention. In the radial electrolytic apparatus of FIG. 3, an aluminum plate 11 is wrapped around a radial drum roller 12 disposed in a main electrolytic cell 21 and in the course of transportation, electrolytically treated by means of main electrodes 13a and 13b connected to an AC power source 20. The acidic aqueous solution 14 is supplied from a solution supply port 15 through a slit 16 to a solution channel 17 located between the radial drum roller 12 and the main electrodes 13a and 13b.

The aluminum plate 11 treated in the main electrolytic cell 21 is then electrolytically treated in an auxiliary anode cell 22. In this auxiliary anode cell 22, an auxiliary anode 18 is disposed to face the aluminum plate 11 and the acidic aqueous solution 14 is supplied to flow between the auxiliary anode 18 and the aluminum plate 11. The current flowed to the auxiliary anode is controlled by thyristors 19a and 19b. The auxiliary anode cell 22 may be disposed before or after or both before and after the main electrolytic cell 21.

The main electrodes 13a and 13b may be selected, for example, from carbon, platinum, titanium, niobium, zirconium, stainless steel and an electrode used in a fuel cell cathode, but carbon is particularly preferred. Examples of the carbon that can be used include commercially available normal impervious graphite for chemical equipment, and resin-impregnated graphite.

The auxiliary anode 18 may be selected from known oxygen-generating electrodes such as ferrite, iridium oxide, platinum and a valve metal (e.g., titanium, niobium, zirconium) cladded or plated with platinum.

The acidic aqueous solution which passes through the main electrolytic cell 21 and the auxiliary anode cell 22 may be fed in a direction parallel or counter to the direction of the aluminum plate 11 travelling. The relative flow rate of the acidic aqueous solution with respect to the aluminum plate is preferably from 10 to 5,000 cm/sec.

One or more AC power sources may be connected to one electrolytic apparatus. Also, two or more electrolytic apparatuses may be used, and the electrolysis conditions among respective apparatuses may be the same or different.

After the completion of electrolysis treatment, liquid cutting by nip rollers and washing by spraying are preferably performed so as not to carry over the treating solution to the next step.

In the case of using the above-described electrolytic apparatus, in proportion to the quantity of electricity passed through the acidic aqueous solution where the aluminum plate in the electrolytic apparatus undergoes an anode reaction, nitric acid and water are preferably added while adjusting their amounts added as well as the nitric acid and aluminum ion concentrations determined from, for example, (i) the electrical conductivity of the acidic aqueous solution, (ii) the ultrasonic wave propagation velocity and (iii) the temperature, so that the acidic aqueous solution in an amount equivalent to the volume of nitric acid and water added can be successively overflowed and discharged from the electrolytic apparatus and the concentration of the acidic aqueous solution can be thereby kept constant.

The nitric acid electrolysis and hydrochloric acid electrolysis are described in detail below.

### (Nitric Acid Electrolysis)

A honeycomb pit having an average opening diameter of 0.4 to 0.8 μm, preferably from 0.4 to 0.7 μm, can be formed by an electrochemical surface-roughening treatment using an electrolyte containing nitric acid. With an average opening diameter in this range, the surface area of the aluminum plate is increased, as a result, god adherence to the image recording layer and good press life are obtained. Also, the honeycomb pit formed by the nitric acid electrolysis is relatively shallow (average depth: 0.1 to 0.5 μm) and has low steepness, so that the on-press developability can be kept good.

The nitric acid concentration of the nitric acid-containing aqueous solution is preferably from 5 to 15 g/L, more preferably from 8 to 10 g/L, still more preferably from 8.5 to 9.5 g/L. With a nitric acid concentration in this range, the honeycomb pits formed by nitric acid electrolysis become uniform in the above-described range.

Also, the liquid temperature at the nitric acid electrolysis is preferably from 40 to 60° C., more preferably from 45 to 55° C. If the liquid temperature is less than 40° C., uniform honeycomb pits having a small diameter can be hardly obtained, whereas if it exceeds 60° C., uniform honeycomb pits become difficult to obtain.

As for the nitric acid-containing aqueous solution, those usually employed for the electrochemical surface-roughening treatment using a direct current or an alternating current may be used. For example, an aqueous nitric acid solution with a nitric acid concentration of 5 to 15 g/L, in which one or more nitric acid compounds such as aluminum nitrate, sodium nitrate and ammonium nitrate are added in a concentration from 0.01 g/L to saturation, may be used.

Above all, an aqueous solution containing nitric acid, an aluminum salt and a nitrate and being obtained by adding aluminum nitrate and ammonium nitrate to an aqueous nitric acid solution with a nitric acid concentration of 5 to 15 g/L such that the aluminum ion becomes from 1 to 15 g/L, preferably from 1 to 10 g/L, and the ammonium ion becomes from 10 to 300 ppm, is preferably used. Incidentally, the aluminum ion and ammonium ion are generated spontaneously in the course of performing the electrochemical surface-roughening treatment.

In the nitric acid-containing aqueous solution, a metal or the like contained in the aluminum alloy, such as iron, copper, manganese, nickel, titanium magnesium and silicon, may be dissolved.

### (Hydrochloric Acid Electrolysis)

Hydrochloric acid itself has a strong aluminum dissolving power and therefore, fine irregularities can be formed on the surface by adding only slight electrolysis. Such fine irregularities have an average opening diameter of 0.01 to 0.2 μm and are generated uniformly on the entire surface of the aluminum plate.

In the present invention, it is preferred to perform the above-described nitric acid electrolysis as a first electrochemical surface-roughening treatment and perform the hydrochloric acid electrolysis as a second electrochemical surface-roughening treatment.

Also, in the present invention, the aluminum plate is preferably subjected to a cathodic electrolysis treatment between the first and second electrochemical surface-roughening treatments. By this cathodic electrolysis treatment, smuts are produced on the aluminum plate surface and at the same time, a hydrogen gas is generated, enabling a more uniform electrolytic surface-roughening treatment. The cathodic electrolysis treatment is performed in an acidic solution with a quantity of cathodic electricity of preferably from 3 to 80 C/dm², more preferably from 5 to 30 C/dm². If the quantity of cathodic electricity is less than 3 C/dm², shortage of the amount of smuts attached may result, whereas if it exceeds 80 C/dm², the amount of smuts attached may become excess. Both are not preferred. The electrolytic solution may be same as or different from the solution used in the first and second electrolytic surface-roughening treatments.

### <Alkali Etching Treatment>

The alkali etching treatment is a treatment for bringing the aluminum plate into contact with an aqueous alkali solution to dissolve the surface layer.

The alkali etching treatment performed before the electrochemical surface-roughening treatment is performed, when a mechanical surface-roughening treatment is not applied, for the purpose of removing rolling oil, stain, natural oxide film or the like on the aluminum plate surface, and when a mechanical surface-roughening treatment is already performed, for the purpose of dissolving the edge portions of irregularities formed by the mechanical surface-roughening treatment and modifying the surface with steep irregularities into a surface with smooth undulation.

In the case of not performing a mechanical surface-roughening treatment before the alkali etching treatment, the etching amount is preferably from 0.1 to 10 g/m², more preferably from 1 to 5 g/m². If the etching amount is less than 0.1 g/m², the rolling oil, stain, natural oxide film or the like on the surface may remain and in turn, the subsequent electrolytic surface roughening treatment may fail in producing uniform pits but cause unevenness. On the other hand, when the etching amount is from 1 to 10 g/m², sufficient removal of the rolling oil, stain, natural oxidation film or the like on the surface of the aluminum plate can be attained. The etching amount exceeding the range above is economically disadvantageous.

In the case of performing a mechanical surface-roughening treatment before the alkali etching treatment, the etching amount is preferably from 3 to 20 g/m², more preferably from 5 to 15 g/m². If the etching amount is less than 3 g/m², irregularities formed by the mechanical surface-roughening treatment cannot be smoothed in some cases and the subsequent electrolysis treatment may fail in forming uniform pits or the performance in terms of stain may deteriorate at the printing, whereas if the etching amount exceeds 20 g/m², the irregularity structure may disappear.

The alkali etching treatment immediately after the electrochemical surface-roughening treatment is performed for the purpose of dissolving smuts formed in the acidic electrolytic solution or dissolving the edge portions of pits formed by the electrochemical surface-roughening treatment.

The pit formed in the electrochemical surface-roughening treatment varies depending on the kind of the electrolytic solution and in turn, the optimal etching amount varies, but the etching amount in the alkali etching treatment performed immediately after the electrochemical surface-roughening treatment is preferably from 0.01 to 10 g/m². In the case of using a nitric acid electrolytic solution, the etching amount must be set to be higher than in the case of using a hydrochloric acid electrolytic solution.

In the case where the electrochemical surface-roughening treatment is performed a plurality of times, an alkali etching treatment may be performed after each treatment, if desired.

Examples of the alkali used in the alkali solution include a caustic alkali and an alkali metal salt. Specific examples of the caustic alkali include sodium hydroxide and potassium hydroxide. Specific examples of the alkali metal salt include an alkali metal silicate such as sodium metasilicate, sodium silicate, potassium metasilicate and potassium silicate; an alkali metal carbonate such as sodium carbonate and potassium carbonate; an alkali metal aluminate such as sodium aluminate and potassium aluminate; an alkali metal aldonate such as sodium gluconate and potassium gluconate; and an alkali metal hydrogenphosphate such as sodium secondary phosphate, potassium secondary phosphate, sodium tertiary phosphate and potassium tertiary phosphate. Among these, an aqueous caustic alkali solution and a solution containing both a caustic alkali and an alkali metal aluminate are preferred because of high etching rate and low cost. Above all, an aqueous sodium hydroxide solution is preferred. The aqueous alkali solution may contain from 0.5 to 10 mass % of alloy components contained in the aluminum plate, as well as aluminum.

The concentration of the aqueous alkali solution may be determined according to the etching amount but is preferably from 1 to 50 mass %, more preferably from 10 to 35 mass %. In the case where an aluminum ion is dissolved in the aqueous alkali solution, the concentration of the aluminum ion is preferably from 0.01 to 10 mass %, more preferably from 3 to 8 mass %.

The temperature of the aqueous alkali solution is preferably from 20 to 90° C., and the treatment time is preferably from 1 to 120 seconds.

Examples of the method for bringing the aluminum plate into contact with the alkali solution include a method of passing the aluminum plate through a bath containing the alkali solution, a method of dipping the aluminum plate in a bath containing the alkali solution, and a method of spraying the alkali solution on the surface of the aluminum plate.

### <Desmutting Treatment>

In the case where the alkali etching treatment is performed before and/or after the electrochemical surface-roughening, a stain (smut) remaining on the surface of the aluminum plate is generally produced by the alkali etching treatment and therefore, it is preferred to perform, after the alkali etching treatment, a so-called desmutting treatment of dissolving such a smut in an acidic solution containing phosphoric acid, nitric acid, sulfuric acid, chromic acid, hydrochloric acid, fluorinated acid, hydrofluoric acid, hydrofluoboric acid or a mixed acid of two or more kinds of these acids.

The concentration of the acidic solution is preferably from 1 to 500 g/L. In the acidic solution, from 0.001 to 50 g/L of alloy components contained in the aluminum plate, as well as aluminum, may be dissolved.

The liquid temperature of the acidic solution is preferably from 20 to 95° C., more preferably from 30 to 70° C., and the treatment time is preferably from 1 to 120 seconds, more preferably 2 to 60 seconds.

In view of reduction in the amount of wastewater, wastewater from the acidic aqueous solution employed in the electrochemical surface-roughening treatment is preferably used as the desmutting solution (acidic solution).

After the completion of desmutting, liquid cutting by nip rollers and washing by spraying are preferably performed so as not to carry over the treating solution to the next step.

### <Anodization Treatment>

The aluminum plate subjected to these treatments as needed is then subjected to an anodization treatment to form an anodic oxide layer.

The anodization treatment may be performed by a method conventionally employed in this field. More specifically, a direct or alternating current is passed to the aluminum plate in an aqueous or non-aqueous solution containing a single acid or a combination of two or more acids, such as sulfuric acid, phosphoric acid, chromic acid, oxalic acid, sulfamic acid and benzenesulfonic acid, whereby an anodic oxide film can be formed on the surface of the aluminum plate.

The conditions for the anodization treatment variously differ according to the electrolytic solution used and cannot be indiscriminately specified, but suitable conditions are generally an electrolytic solution concentration of 1 to 80 mass %, a liquid temperature of 5 to 70° C., a current density of 0.5 to 60 A/dm², a voltage of 1 to 200 V and an electrolysis time of 1 to 1,000 seconds.

Among these anodization treatments, a method of performing an anodization treatment at a high current density in a sulfuric acid electrolytic solution described in British Patent 1,412,768, and a method of performing an anodization treatment using a phosphoric acid as an electrolysis bath described in U.S. Pat. No. 3,511,661 are preferred. Also, a multi-stage anodization treatment of performing an anodization treatment in sulfuric acid and further performing an anodization treatment in phosphoric acid may be applied.

In the present invention, the coverage of the anodic oxide film is, in view of less scratchability and press life, preferably 0.5 g/m² or more, more preferably 1.0 g/m² or more, still more preferably 2.0 g/m² or more. Also, considering that enormous energy is necessary for providing a thick layer, the coverage is preferably 100 g/m² or less, more preferably 10 g/m² or less, still more preferably not more than 6 g/m² or less.

On the surface of the anodic oxide film, fine recesses called micropores are formed in an evenly distributed manner. The density of micropores present in the anodic oxide film can be adjusted by appropriately selecting the treatment conditions.

### <Pore-Sealing Treatment>

In the present invention, the aluminum plate after forming the anodic oxide film as above may be subjected to a pore-sealing treatment for controlling the average pore diameter of micropores present in the anodic oxide film. This pore-sealing treatment makes small the pore diameter of micropores in the anodic oxide film, and the image recording layer can be prevented from intruding into the micropore at the production of a lithographic printing plate precursor, or the ink can be prevented from sliding into the micropore at the printing, so that a lithographic printing plate having excellent staining resistance and exerting excellent impression capacity can be obtained. Moreover, the amount of treated wastewater itself and the amount of sludge generated at the wastewater treatment are reduced. Also, the on-press developability of the obtained lithographic printing plate precursor is remarkably enhanced.

The pore-sealing treatment can reduce the residual film amount of the image recording layer after on-press development and in turn, can make hydrophilic the surface of the lithographic printing plate in the non-image area, so that excellent scumming resistance can be obtained.

Furthermore, this pore-sealing treatment can form fine irregularities on the surface of the lithographic printing plate support and the surface area of the lithographic printing plate support is thereby increased, so that adherence of the support to the image recording layer can be enhanced and in turn, a lithographic printing plate precursor excellent in the sensitivity and chemical resistance can be obtained.

In the present invention, a pore sealing ratio is used as an index for pore sealing by the pore-sealing treatment. Here, the pore sealing ratio indicates a ratio in which the surface area of the anodic oxide film is decreased, and is defined by the following formula. In the present invention, the sealing ratio is preferably 50% or more, more preferably 70% or more, still more preferably 90% or more. Incidentally, the sealing ratio, that is, the rate of decrease in the surface area, can be controlled by the treating conditions and, for example, by increasing the treating temperature or treatment time, the sealing ratio can be raised.

Sealing ratio (%)=[(surface area of anodic oxide film before pore-sealing treatment−surface area of anodic oxide film after pore-sealing treatment)/surface area of anodic oxide film before pore-sealing treatment]×100

The surface area of the anodic oxide film before or after the pore-sealing treatment can be measured using a simple BET-type surface area analyzer (for example, QUANTASORB, manufactured by Yuasa Ionics Inc.).

As for the pore-sealing treatment, a conventionally known method may be used, and examples thereof include a hydrate pore-sealing treatment, a metal salt pore-sealing treatment and an organic material pore-sealing treatment. Among these, a hydrate pore-sealing treatment and a meal salt pore-sealing treatment are preferred, and a pore-sealing treatment with water vapor is more preferred because of no effect of the water quality. These treatments are described below.

### (Hydrate Pore-Sealing Treatment)

Specific examples of the hydrate pore-sealing treatment include a method of dipping the aluminum plate having formed thereon an anodic oxide film in hot water.

The hot water may contain an inorganic salt (e.g., phosphate) or an organic salt.

The temperature of the hot water is preferably 80° C. or more, more preferably 95° C. or more, and is preferably 100° C. or less.

The time for which the aluminum plate is dipped in hot water is preferably 1 second or more, more preferably 3 seconds or more, and is preferably 100 seconds or less, more preferably 20 seconds or less.

Other specific examples of the hydrate pore-sealing treatment include a method of bringing water vapor under applied pressure or normal pressure into continuous or discontinuous contact with the anodic oxide film (hereinafter, simply referred to as a “water vapor pore-sealing treatment”).

The treating temperature for water vapor pore-sealing is preferably from 90 to 110° C., more preferably from 95 to 105° C. If the treating temperature is less than 90° C., a surface structure having irregularities at a pitch of 10 to 100 nm is difficult to satisfactorily form, whereas if it exceeds 110° C., the water vapor consumption becomes large and this is not profitable.

The treatment time for water vapor pore-sealing is preferably from 5 to 60 seconds, more preferably from 10 to 30 seconds.

As for such a water vapor pore-sealing treatment, it is particularly preferred to use the methods described in JP-A-6-1090, JP-A-5-179482 and JP-A-5-202496.

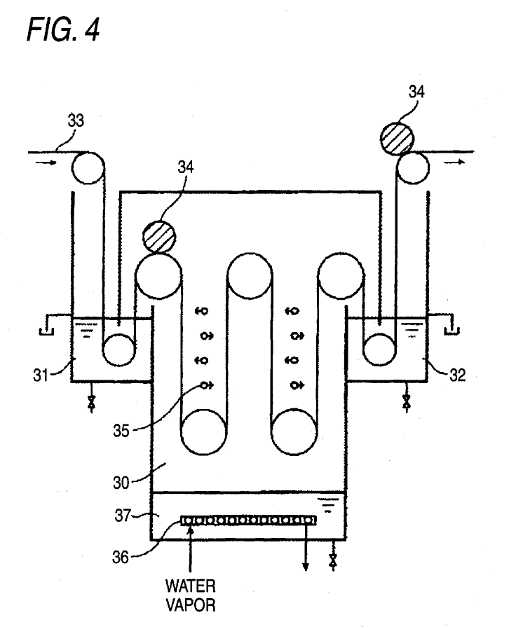

FIG. 4 is a schematic view of a water vapor pore-sealing treatment tank suitably used in the present invention. In the water vapor pore-sealing tank of FIG. 4, water seal tanks 31 and 32 containing hot water are provided before and after the treatment tank 30 and each prevents water vapor within the water vapor pore-sealing tank from leaking to the outside.

In the water vapor pore-sealing treatment tank, a nip roller 34 is preferably provided immediately after leaving the water seal tank 31 on the aluminum plate 33 inlet side to effect liquid cutting. This is preferred because the water film on the aluminum plate 33 surface becomes uniform, as a result, uniform temperature distribution is created in the width direction of the aluminum plate 33, enabling uniform pore-sealing treatment.

On the aluminum plate 33 after liquid cutting by the nip roller 34, water vapor generated from a boiler water tank 37 capable of being heated by a heat exchanger 36 is brown through a water vapor spray tube 35 inside of the treatment tank 30.

By performing such a water vapor pore-sealing treatment, a surface structure having irregularities at a pitch of 10 to 100 nm can be formed on the aluminum plate surface while sealing mircopores (sealing ratio: from 50 to 90%) formed in the anodic oxide film, as a result, the anchor effect of the aluminum plate (obtained lithographic printing plate support) surface to the image recording layer is increased and the press life is enhanced. It is particularly preferred to have irregularities at a pitch of 40 to 60 rn in the surface structure.

Incidentally, the surface structure having irregularities at a pitch of 10 to 100 nm may also be formed by performing a pore-sealing treatment of sealing micropores produced in the anodization treatment, in hot water or water vapor, but formation of irregularities by a water vapor pore-sealing treatment is preferred because of no effect of the water quality.

### Water Quality

Also, in the present invention, the boiler water that produces water vapor may contain an oxygen scavenger and an antiscaling agent. Examples of such a boiler water include a boiler water containing from 1 to 5 ppm of hydrazine as the oxygen scavenger and from 1 to 20 ppm of a sodium tripolyphosphate/NaOH mixed solution as the antiscaling agent.

### (Metal Salt Sealing Treatment)

The metal salt pore-sealing treatment is a pore-sealing treatment with an aqueous solution containing a metal salt. The pore-sealing treatment solution, pore-sealing treatment method, the concentration controlling method and the wastewater treatment, for use in the metal salt pore-sealing treatment, are described in detail in the following (1) to (4).

### (1) Pore-Sealing Treatment Solution

The metal salt for use in the metal salt sealing treatment is suitably a metal fluoride. Specific examples thereof include sodium fluoride, potassium fluoride, calcium fluoride, magnesium fluoride, sodium fluorozirconate, potassium fluorozirconate, sodium fluorotitanate, potassium fluorotitanate, ammonium fluorozirconate, ammonium fluorotitanate, potassium fluorotitanate, fluorozirconic acid, fluorotitanic acid, hexafluorosilicic acid, nickel fluoride, iron fluoride, fluorophosphoric acid and ammonium fluorophosphate. One of these may be used alone, or two or more kinds thereof may be used in combination. Above all, sodium fluorozirconate, sodium fluorotitanate, fluorozirconic acid and fluorotitanic acid are preferred.

The concentration of the metal salt in the metal salt-containing aqueous solution is preferably from 0.5 to 4.0 g/L, more preferably from 0.8 to 2.5 g/L, from the standpoint of sufficiently sealing the micropores in the anodic oxide film.

The metal salt-containing aqueous solution may contain a phosphate compound. When a phosphate compound is contained, a pore-sealing treatment at a lower temperature becomes possible and the hydrophilicity on the anodic oxide film surface is elevated, so that the on-press developability and scumming resistance can be enhanced.

Suitable examples of the phosphate compound include a phosphate of a metal such as alkali metal and alkaline earth metal.

Specific examples thereof include zinc phosphate, aluminum phosphate, ammonium phosphate, diammonium hydrogenphosphate, ammonium dihydrogenphosphate, monoammonium phosphate, monopotassium phosphate, monosodium phosphate, potassium dihydrogenphosphate, dipotassium hydrogenphosphate, calcium phosphate, sodium ammonium hydrogenphosphate, magnesium hydrogenphosphate, magnesium phosphate, ferrous phosphate, ferric phosphate, sodium dihydrogenphosphate, sodium phosphate, disodium hydrogen-phosphate, lead phosphate, diammonium phosphate, calcium dihydrogenphosphate, lithium phosphate, phosphotungstic acid, ammonium phosphotungstate, sodium phosphotungstate, ammonium phosphomolybdate, sodium phosphomolybdate, sodium phosphite, sodium tripolyphosphate and sodium pyrophosphate. One of these may be used alone, or two or more kinds thereof may be used in combination. Above all, sodium dihydrogenphosphate, disodium hydrogenphosphate, potassium dihydrogenphosphate and dipotassium hydrogenphosphate are preferred.

The concentration of the phosphate compound in the metal salt-containing aqueous solution is preferably from 1.0 g/L to less than 10.0 g/L, more preferably from 1.5 to 4 g/L, from the standpoint of enhancing the on-press developability and scumming resistance.

In the present invention, the combination of the metal salt and the phosphate compound is not particularly limited, but the meal salt-containing aqueous solution preferably contains at least sodium fluorozirconate and contains at least sodium dihydrogenphosphate as the phosphate compound.

The concentration of the metal salt is, as described above, preferably from 0.5 to 4.0 g/L, more preferably from 0.8 to 2.5 g/L. Also, the concentration of the phosphate compound is, as described above, preferably from 1.0 g/L to less than 10.0 g/L, more preferably from 1.5 to 4 g/L.

The concentration of the fluorine ion contained in such a pore-sealing treatment solution is preferably from 290 to 2,200 mg/L, more preferably form 460 to 1,400 mg/L. The fluorine ion concentration is measured by a fluoride ion electrode or by ion chromatography

The concentration of the phosphate ion contained in the pore-sealing treatment solution is preferably from 610 to 6,000 mg/L, more preferably from 920 to 2,400 mg/L. The phosphate (PO₄⁻²) ion concentration is measured by colorimetry or ion chromatography.

The temperature of the metal salt-containing aqueous solution is preferably 40° C. or more, more preferably 60° C. or more. If the temperature is less than 40° C., the pore-sealing property becomes bad, whereas if it exceeds 95° C., liquid evaporation in a large amount is caused and this is not practical.

The aqueous solution is preferably at a pH of 3 or more, more preferably at a pH of 3.2 or more, and is preferably at a pH of 5.0 or less, more preferably at a pH or 4.5 or less, still more preferably at a pH of 3.8 or less. If the pH is less than 3.0 or exceeds 5.0, the pore-sealing property becomes bad. It is preferred to always control the system during the pore-sealing treatment and adjust the pH by adding phosphoric acid or sodium hydroxide (NaOH).

### (2) Pore-Sealing Treatment Method

Suitable examples of the pore-sealing treatment method include vatting using the above-described pore-sealing treatment solution.

The vatting may be performed with well water or pure water (ion-exchanged water), but the liquid become clouded during vatting due to reaction of calcium or magnesium in water with fluorine ion or phosphate ion. Therefore, vatting with pure water (ion-exchanged water) is preferred. Water in which the metal salt and phosphate compound used for addition are dissolved is also preferably pure water (ion-exchanged water).

In the case where the metal salt (particularly, metal fluoride) and phosphate compound are mixed as powders, in order to achieve good dissociation of fluorine, a metal fluoride is preferably added earlier.

The pore-sealing treatment is preferably performed by a dipping or spraying method. A single method may be used alone once or a plurality of times, or two or more kinds of methods may be used in combination. The spraying method is preferred, because the back surface of the aluminum plate is not treated and this brings less fatigue of the solution and decrease in the amount of chemicals used.

During operation, sodium, fluorine and phosphoric acid in the eluted aluminum and solution react to produce sodium fluoroaluminate (Na₃AlF₆, cryolite) or aluminum phosphate and the solution becomes clouded. Therefore, the treatment is preferably performed while removing sodium fluoroaluminate (Na₃AlF₆, cryolite) or aluminum phosphate by filtration through a filter or by using a settling tank, and it is more preferred to perform the operation while always filtering the solution by using a filter. Since the filter is readily clogged, the operation is preferably performed using two or more filter systems by controlling the pressure and replacing the filter while backwashing the clogged filter to remove residual substances.

In the pore-sealing treatment solution, aluminum dissolves out, but the aluminum ion concentration is preferably controlled to be from 10 to 250 mg/L, more preferably from 100 to 200 mg/L.

For controlling the aluminum ion concentration to be from 10 to 250 mg/L, the concentration is adjusted by the renewed amount of the pore-sealing treatment solution (addition of new solution and disposal of solution after treatment).

Also, in the pore-sealing treatment solution, sulfate ion increases due to carry-over of sulfuric acid from the anodization treatment step as the pre-step of the pore-sealing treatment or dissolution of SO₄ contained in the anodic oxide film. The concentration of the sulfate ion is preferably from 10 to 200 mg/L, more preferably from 50 to 150 mg/L. If the concentration is less than 10 mg/L, this requires to increase the renewed amount of the solution and is not profitable, whereas if it exceeds 200 mg/L, the electric conductivity of the solution is affected and the concentration cannot be exactly measured.

### (3) Concentration Controlling Method

The method for controlling the concentrations of the metal salt and phosphate compound to the above-descried suitable ranges during operation is not particularly limited, but by previously preparing a concentrated solution having dissolved therein the metal salt and a concentrated solution having dissolved the phosphate compound, when either one concentration is deviates below the control value, either one of those solutions is added to correct the concentration. In the case where the concentration becomes high due to evaporation of water, the correction may be performed by a method of replenishing water. For example, a method where the amount of change from the initial concentration is empirically predicted according to the operation time elapsed and replenishment of the concentrated solution or water or adjustment of the displacement is performed at appropriate timing, may also be employed.

In the liquid concentration control when always controlling the liquid concentration of the pore-sealing treatment solution, the concentrations of the metal salt (particularly, metal fluoride) and phosphate compound in the pore-sealing treatment solution used are individually or simultaneously measured. Examples of the concentration measuring method include a concentration measuring method of calculating the concentration from the electrical conductivity of the pore-sealing solution and the fluorine ion concentration determined by an ultraviolet wave propagation velocity or a fluoride ion electrode, a concentration measuring method by a fluoride ion electrode and colorimetry of a phosphorus concentration, and an ion chromatography method. An ion chromatography method is most preferred.

In the method of measuring the concentration by ion chromatography, one measurement requires as long a time as 15 to 30 minutes and therefore, by preparing from 2 to 10 column systems for measurement, a liquid obtained by automatic sampling at regular intervals and automatic dilution to 200 to 2,000 times under the control of a personal computer is preferably measured by replacing the column. In this case, the concentration that can be measured only at intervals of 30 minutes when using one unit of a column can be measured at shorter intervals, and the change in the concentration of the solution can be timely measured. The solution of which concentration is measured is preferably filtered in advance through a filter having a pore size of 0.2 to 0.5 μm to remove floaters.

The concentration measurement is preferably performed by a method where a standard chart (table) is made up by preparing solutions where the metal salt (particularly, metal fluoride) concentration and the phosphate compound concentration are stepwise varied over a wide range, and measuring the fluorine concentration and the phosphoric acid concentration in each solution, and the measurement results of the solution in operation are compared with the preliminarily prepared standard chart (table) to calculate the current metal salt concentration and phosphate compound concentration of the pore-sealing solution.

### (4) Wastewater Treatment

The wastewater from the pore-sealing treatment is preferably discharged after once storing it in a wastewater tank and then applying a known wastewater treatment using calcium salt, aluminum sulfate, polymer coagulant, sodium hydroxide, sulfuric acid or the like, thereby reducing the fluorine concentration and phosphoric acid concentration in the wastewater below the regulation values.

The sludge generated in the wastewater treatment is preferably recycled as a building material such as cement raw material by mixing it, for example, with a waste abrasive generated in the mechanical surface-roughening treatment described in the specification of the present invention, or with aluminum hydroxide or the like generated in the neutralization treatment of washing water.

### (Organic Material Pore-Sealing Treatment)

The organic material pore-sealing treatment is a treatment of sealing pores by the coating or impregnation of an organic material such as fat or synthetic resin.

### <Hydrophilic Treatment>

By applying a hydrophilic treatment, the hydrophilicity of the aluminum plate (obtained lithographic printing plate support) is enhanced and the scumming resistance and on-press developability are improved.

Examples of the method for the hydrophilic treatment include a method of treating the aluminum plate with an alkali metal silicate, and a method of treating the aluminum plate with a polyvinylphosphonic acid. In particular, a method of performing a hydrophilic treatment in an aqueous alkali metal silicate solution at a pH of 12.5 to 13.5 is preferred, because the above-described effects are more excellent.

The hydrophilic treatment using an alkali metal silicate can be performed in accordance with methods and procedures described in U.S. Pat. Nos. 2,714,066 and 3,181,461.

The alkali metal silicate is not particularly limited, and examples thereof include sodium silicate, potassium silicate and lithium silicate. One of these alkali metal silicates may be used alone, or two or more kinds thereof may be used in combination. The aqueous solution of the alkali metal silicate may contain an appropriate amount of sodium hydroxide, potassium hydroxide, lithium hydroxide, or the like.

Also, the aqueous alkali metal silicate solution may contain an alkaline earth metal salt or a Group 4 (Group IVA) metal salt. Examples of the alkaline earth metal salt include a nitrate such as calcium nitrate, strontium nitrate, magnesium nitrate and barium nitrate, a sulfate, a hydrochloride, a phosphate, an acetate, an oxalate and a borate. Examples of the Group 4 (Group IVA) metal salt include titanium tetrachloride, titanium trichloride, potassium fluorotitanate, potassium titanium oxalate, titanium sulfate, titanium tetraiodide, zirconyl chloride, zirconium dioxide, zirconium oxychloride and zirconium tetrachloride. One of these alkaline earth metal salts and Group 4 (Group IVA) metal salts may be used alone, or two or more kinds thereof may be used in combination.

The alkali metal silicate treatment is performed by contacting an aqueous alkali metal silicate solution with the aluminum plate subjected to an anodization treatment, a pore-sealing treatment and other treatments performed, if desired. The method of bringing the aluminum plate into contact with the aqueous alkali metal silicate solution is not particularly limited, and examples thereof include a method of passing the aluminum plate through a tank containing the aqueous solution, a method of dipping the aluminum plate in a tank containing the aqueous solution, and a method of spraying the aqueous solution on the surface of the aluminum plate.

Various conditions for the alkali metal silicate treatment are not particularly limited, but the liquid temperature is preferably from 10 to 80° C., more preferably from 15 to 50° C., the treatment time is preferably from 1 to 100 seconds, more preferably from 5 to 20 seconds.

Specific suitable examples of the hydrophilic treatment using such an alkali metal silicate include a method of performing the treatment by dipping the aluminum plate in an aqueous solution containing from 1 to 5 mass % of No. 3 sodium silicate or sodium metasilicate (liquid temperature: 20 to 80° C.) for 1 to 20 seconds or by spraying the aqueous solution.

The amount of Si attached in the alkali metal silicate treatment can be measured by an X-ray fluorescence spectrometer. The amount of the Si atom attached to the surface of the lithographic printing plate support is preferably from 1 to 10 mg/m². When the amount of the Si atom attached to the support surface is within this range, both the developability and the press life can be satisfied in a very high level.

As for the amount of the alkali metal silicate attached to the surface of the lithographic printing plate support, a value measured using an X-ray fluorescence spectrometer (XRF) and calculated as the attached amount of Si atom (Si: mg/m²) according to a calibration method is used. The standard sample used for preparing the calibration curve is obtained by uniformly dropping an aqueous sodium silicate solution containing a known amount of Si atom on the aluminum plate within an area of 30 mmφ, and then drying it. The model of the X-ray fluorescence spectrometer and other conditions are not particularly limited. For example, the conditions in the X-ray fluorescence analysis of Si are set forth below.

X-Ray fluorescence spectrometer: RIX3000, manufactured by Rigaku Corp., X-ray tube: Rh, measuring spectrum: Si—Kα, tube voltage: 50 kV, tube current: 50 mA, slit: COARSE, spectral crystal: RS4, detector: F-PC, area analyzed: 30 mmφ, peak position (2θ): 144.75 deg., background (2θ): 140.70 deg. and 146.85 deg., and integrating time: 80 sec/sample.

On the other hand, the hydrophilic treatment using a polyvinylphosphonic acid is performed by a dipping or spraying method. The concentration of the aqueous polyvinylphosphonic acid solution is preferably 0.6 mass % or more, more preferably 0.8 mass % or more, and is preferably 5.0 mass % or less, more preferably 3.0 mass % or less. When the concentration of the polyvinylphosphonic acid is in this range, more excellent scumming resistance is obtained. Also, the liquid temperature of the aqueous polyvinylphosphonic acid solution is preferably from 50 to 90° C., and the treatment time is preferably from 1 tot 30 seconds. Furthermore, the aqueous polyvinylphosphonic acid solution readily decays and therefore, is preferably subjected to disinfection of miscellaneous bacteria by raising the temperature at 90° C. or more once per two or three days.

As for the polyvinylphosphonic acid, those disclosed in U.S. Pat. Nos. 3,276,868, 4,153,461 and 4,689,272 may be used.

After the polyvinylphosphonic acid treatment, a water washing treatment is preferably performed.

Such a hydrophilic treatment is preferably performed at a temperature of 20 to 100° C., more preferably from 20 to 60° C.

In the case of a method of dipping the aluminum plate in an aqueous alkali metal silicate solution at a pH or 12.5 to 13.5 or in an aqueous polyvinylphosphonic acid solution, the time for which the aluminum plate is dipped is preferably 1 second or more, more preferably 3 seconds or more, and is preferably 100 seconds or less, more preferably 20 seconds or less.

### [Anion Component and Method for Quantitative Determination Thereof]

In the present invention, the anion component content in the lithographic printing plate precursor is preferably 0.7 mmol/m² or less, more preferably 0.5 mmol/m² or less, and most preferably 0.3 mmol/m² or less. The reduction in the amount of the anion component is not an essential requirement, but in view of suppressing the corrosion of the aluminum substrate, the anion component content is preferably reduced to the range above.

The anion component in the lithographic printing plate precursor, as used in the present invention, indicates an anion component extracted from the image recording layer and if present, from the undercoat layer and protective layer, when dipping 30 cm² of the lithographic printing plate precursor in 10 ml of methanol, and an anion component present in an inorganic layered compound or an inorganic fine particle does not come under the anion component above.

The amount (mmol/m²) of the anion component is measured using LC/MS (liquid chromatography-mass spectrometry, 2695 Alliance, manufactured by Waters, eluent: ammonium acetate/water/methanol) or ion chromatography (manufactured by Tosoh Corp., eluent: anion standard eluent).

More specifically, in the case of a hexafluorophosphate anion, after extracting 30 cm² of each lithographic printing plate precursor with 10 ml of methanol, the molecular weight (m/e=145.02) is monitored by LC/MS and the content (mmol/m²) is calculated using a separately prepared calibration curve.

As to the means for maintaining good the on-press developability even when the anion component is decreased, for example, addition of a nonionic compound such as ethylene glycol may be considered.

Also, as to the means for maintaining good the sensitivity even when the anion component is decreased, for example, addition of a nonionic initiator (described in JP-A-2006-255967) may be considered.

### [Image Recording Layer]

The image recording layer for use in the present invention is an image recording layer capable of forming an image by, after exposure, supplying a printing ink and a fountain solution on a printing press and thereby removing the unexposed area. The on-press developable image forming mechanism contained in the image recording layer typically includes (1) an embodiment containing (A) an infrared absorbent, (B) a radical polymerization initiator and (C) a polymerizable compound, where the image part is cured by utilizing a polymerization reaction, and (2) an embodiment containing (A) an infrared absorbent and (D) a hydrophobing precursor, where a hydrophobic region (image part) is formed by utilizing thermal fusion bonding or thermal reaction of the hydrophobing precursor. A mixture of these two embodiments may also be employed. For example, (D) a hydrophobing precursor may be contained in (1) the polymerization-type image recording layer, or a polymerizable compound or the like may be contained in (2) the hydrophobing precursor type. Above all, a photopolymerization-type embodiment containing (A) an infrared absorbent, (B) a radial polymerization initiator and (C) a polymerizable compound is preferred. The components which can be contained in the image recording layer are described in sequence.

### <(A) Infrared Absorbent>

In the case of forming an image on the lithographic printing plate precursor of the present invention by using a laser of emitting an infrared ray at 760 to 1,200 nm as the light source, an infrared absorbent is preferably contained in the image recording layer.

The infrared absorbent has a function of converting the absorbed infrared ray into heat and a function of being excited by an infrared ray and effecting electron transfer and/or energy transfer to the radical polymerization initiator described later. The infrared absorbent for use in the present invention is a dye or pigment having an absorption maximum at a wavelength of 760 to 1,200 nm.

As for the dye, commercially available dyes and known dyes described in publications such as Senryo Binran (Handbook of Dyes) (compiled by The Synthetic Organic Chemistry, Japan (1970)) may be used. Specific examples thereof include a dye such as azo dye, metal complex salt azo dye, pyrazolone azo dye, naphthoquinone dye, anthraquinone dye, phthalocyanine dye, carbonium dye, quinoneimine dye, methine dye, cyanine dye, squarylium dye, pyrylium salt and metal thiolate complex.

Preferred examples of the dye include cyanine dyes described in JP-A-58-125246, JP-A-59-84356 and JP-A-60-78787, methine dyes described in JP-A-58-173696, JP-A-58-181690 and JP-A-58-194595, naphthoquinone dyes described in JP-A-58-112793, JP-A-58-224793, JP-A-59-48187, JP-A-59-73996, JP-A-60-52940 and JP-A-60-63744, squarylium dyes described in JP-A-58-112792, and cyanine dyes described in British Patent 434,875.

Also, near infrared absorbing sensitizers described in U.S. Pat. No. 5,156,938 may be suitably used. Furthermore, substituted arylbenzo(thio)pyrylium salts described in U.S. Pat. No. 3,881,924, trimethinethiapyrylium salts described in JP-A-57-142645 (corresponding to U.S. Pat. No. 4,327,169), pyrylium-based compounds described in JP-A-58-181051, JP-A-58-220143, JP-A-59-41363, JP-A-59-84248, JP-59-84249, JP-A-59-146063 and JP-A-59-146061, cyanine dyes described in JP-A-59-216146, pentamethinethiapyrylium salts described in U.S. Pat. No. 4,283,475, and pyrylium compounds described in JP-B-5-13514 and JP-B-5-19702 may also be preferably used. Other preferred examples of the dye include near infrared absorbing dyes represented by formulae (1) and (II) of U.S. Pat. No. 4,756,993.

Also, other preferred examples of the infrared absorbing dye for use in the present invention include specific indolenine cyanine dyes described in JP-A-2002-278057, which are illustrated below.

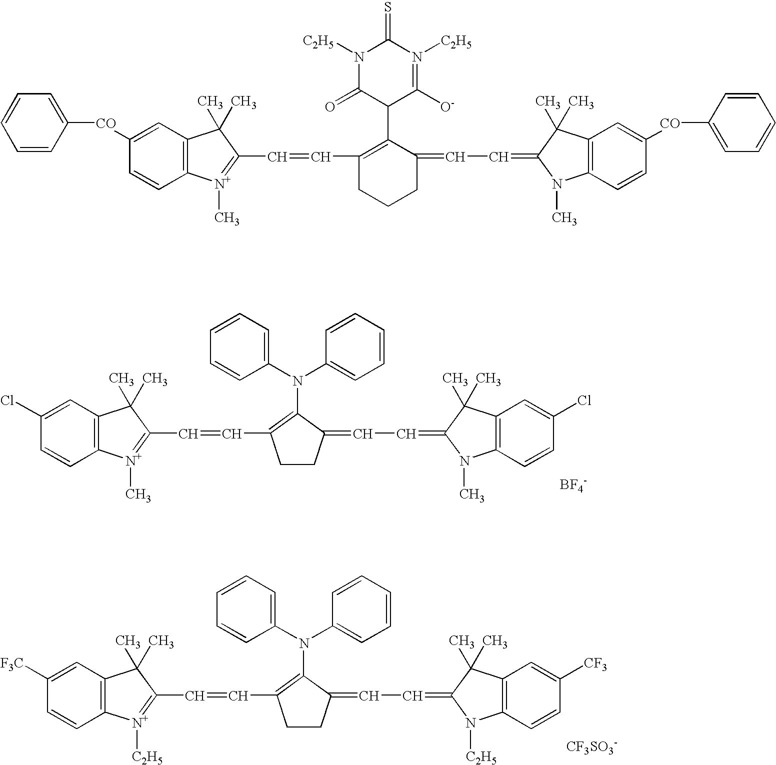

Among these dyes, preferred are a cyanine dye, a squarylium dye, a pyrylium salt, a nickel thiolate complex and an indolenine cyanine dye, more preferred are a cyanine dye and an indolenine cyanine dye, still more preferred is, for example, a cyanine dye represented by the following formula (1):

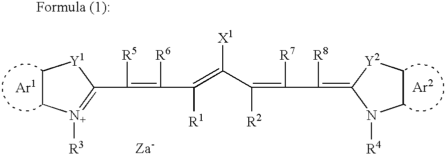

In formula (1), X¹ represents a hydrogen atom, a halogen atom, —NPh₂, X²-L¹ or a group shown below, wherein X² represents an oxygen atom, a nitrogen atom or a sulfur atom, and L¹ represents a hydrocarbon group having a carbon number of 1 to 12, an aromatic ring having a heteroatom, or a hydrocarbon group having a carbon number of 1 to 12 and containing a heteroatom. Incidentally, the heteroatom as used here indicates a nitrogen atom, a sulfur atom, an oxygen atom, a halogen atom or a selenium atom. R^{a} represents a substituent selected from a hydrogen atom, an alkyl group, an aryl group, a substituted or unsubstituted amino group and a halogen atom, and Xₐ⁻ has the same definition as Za⁻ described later.

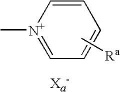

R¹ and R² each independently represents a hydrocarbon group having a carbon number of 1 to 12. In view of storage stability of the coating solution for the image recording layer, R¹ and R² each is preferably a hydrocarbon group having a carbon number of 2 or more. It is more preferred that R¹ and R² combine together to form a 5- or 6-membered ring.

Ar¹ and Ar² may be the same or different and each represents an aromatic hydrocarbon group which may have a substituent. Preferred examples of the aromatic hydrocarbon group include a benzene ring and a naphthalene ring. Preferred examples of the substituent include a hydrocarbon group having a carbon number of 12 or less, a halogen atom and an alkoxy group having a carbon number of 12 or less, with a hydrocarbon group having a carbon number of 12 or less and an alkoxy group having a carbon number of 12 or less being most preferred. Y¹ and Y² may be the same or different and each represents a sulfur atom or a dialkylmethylene group having a carbon number of 12 or less. R³ and R⁴ may be the same or different and each represents a hydrocarbon group having a carbon number of 20 or less, which may have a substituent. Preferred examples of the substituent include an alkoxy group having a carbon number of 12 or less, a carboxyl group and a sulfo group, with an alkoxy group having a carbon number of 12 or less being most preferred. R⁵, R⁶, R⁷ and R⁸ may be the same or different and each represents a hydrogen atom or a hydrocarbon group having a carbon number of 12 or less and in view of availability of the raw material, is preferably a hydrogen atom. Za⁻ represents a counter anion, but when the cyanine dye represented by formula (1) has an anionic substituent in its structure and neutralization of electric charge is not necessary, Za⁻ is not present. In view of storage stability of the coating solution for the recording layer, Zd⁻ is preferably halogen ion, perchlorate ion, tetrafluoroborate ion, hexafluorophosphate ion or sulfonate ion, more preferably perchlorate ion, tetrafluoroborate ion, hexafluorophosphate ion or arylsulfonate ion.

Specific examples of the cyanine dye represented by formula (1), which can be suitably used in the present invention, include those described in paragraphs [0017] to [0019] of JP-A-2001-133969.

Other particularly preferred examples include specific indolenine cyanine dyes described in JP-A-2002-278057 supra.

As for the pigment used in the present invention, commercially available pigments and pigments described in Color Index (C.I.) Binran (C.I. Handbook), Saishin Ganryo Binran (Handbook of Latest Pigments), compiled by Nippon Ganryo Gijutsu Kyokai (1977), Saishin Ganrvo Ovo Gijutsu (Latest Pigment Application Technology), CMC Shuppan (1986), and Insatsu Ink Giiutsu (Printing Ink Technology), CMC Shuppan (1984) can be used.

The kind of the pigment includes black pigment, yellow pigment, orange pigment, brown pigment, red pigment, violet pigment, blue pigment, green pigment, fluorescent pigment, metal powder pigment and polymer-bound dye. Specific examples of the pigment which can be used include an insoluble azo pigment, an azo lake pigment, a condensed azo pigment, a chelate azo pigment, a phthalocyanine-based pigment, an anthraquinone-based pigment, a perylene or perynone-based pigment, a thioindigo-based pigment, a quinacridone-based pigment, a dioxazine-based pigment, an isoindolinone-based pigment, a quinophthalone-based pigment, a dyed lake pigment, an azine pigment, a nitroso pigment, a nitro pigment, a natural pigment, a fluorescent pigment, an inorganic pigment and carbon black. Among these pigments, carbon black is preferred.

These pigments may or may not be surface-treated before use. Examples of the method for surface treatment include a method of coating the surface with resin or wax, a method of attaching a surfactant, and a method of bonding a reactive substance (for example, a silane coupling agent, an epoxy compound or an isocyanate) to the pigment surface. These surface-treating methods are described in Kinzoku Sekken no Seishitsu to Oyo (Properties and Application of Metal Soap), Saiwai Shobo, Insatsu Ink Gijutsu (Printing Ink Technology), CMC Shuppan (1984), and Saishin Ganyo Oyo Gijutsu (Latest Pigment Application Technology), CMC Shuppan (1986).

The particle diameter of the pigment is preferably from 0.01 to 10 μm, more preferably from 0.05 to 1 μm, still more preferably from 0.1 to 1 μm. Within this range, good stability of the pigment dispersion in the coating solution for the image recording layer and good uniformity of the image recording layer can be obtained.

As for the method of dispersing the pigment, a known dispersion technique employed in the production of ink, toner or the like may be used. Examples of the dispersing machine include an ultrasonic disperser, a sand mill, an attritor, a pearl mill, a super-mill, a ball mill, an impeller, a disperser, a KD mill, a colloid mill, a dynatron, a three-roll mill and a pressure kneader. These are described in detail in Saishin Ganryo Ovo Gijutsu (Latest Pigment Application Technology), CMC Shuppan (1986).

The infrared absorbent may be added together with other components in the same layer or may be added to another image recording layer provided separately, but the infrared absorbent is added such that when a lithographic printing plate precursor is produced, the absorbancy of the image recording layer at a maximum absorption wavelength in the wavelength range of 760 to 1,200 nm becomes from 0.3 to 1.2, preferably from 0.4 to 1.1, as measured by a reflection measuring method. Within this range, a uniform polymerization reaction proceeds in the depth direction of the image recording layer, and the image area can have good film strength and good adherence to the support.

The absorbancy of the image recording layer can be adjusted by the amount of the infrared absorbent added to the image recording layer and the thickness of the image recording layer. The absorbancy can be measured by an ordinary method. Examples of the measuring method include a method where an image recording layer having a thickness appropriately selected in the range giving a dry coated amount necessary as a lithographic printing plate is formed on a reflective support such as aluminum and the reflection density is measured by an optical densitometer, and a method of measuring the absorbancy by a spectrophotometer according to a reflection method using an integrating sphere.

In the present invention, the content of the infrared absorbent (A) in the image recording layer is, in terms of the specific added amount, preferably from 0.1 to 10.0 mass %, more preferably from 0.5 to 5.0 mass %, based on the entire solid content of the image recording layer.

### <(B) Radical Polymerization Initiator>

The radical polymerization initiator (B) for use in the present invention indicates a compound capable of generating a radical by the effect of light or heat energy or both and thereby initiating or accelerating the polymerization of the polymerizable compound (C). Examples of the radical polymerization initiator usable in the present invention include a known thermal polymerization initiator, a compound having a bond of small bond-dissociation energy, and a photopolymerization initiator.

Examples of the radical polymerization initiator for use in the present invention include (a) an organic halide, (b) a carbonyl compound, (c) an azo-based polymerization initiator, (d) an organic peroxide, (e) a metallocene compound, (f) an azide compound, (g) a hexaarylbiimidazole compound, (h) an organic borate compound, (i) a disulfone compound, (j) an oxime ester compound and (k) an onium salt compound.

Specific examples of the organic halide (a) include the compounds described in Wakabayashi et al., Bull. Chem. Soc. Japan, 42, 2924 (1969), U.S. Pat. No. 3,905,815, JP-B-46-4605, JP-A-48-36281, JP-A-55-32070, JP-A-60-239736, JP-A-61-169835, JP-A-61-169837, JP-A-62-58241, JP-A-62-212401, JP-A-63-70243, JP-A-63-298339, and M. P. Hutt, Journal of Heterocyclic Chemistry, 1, No. 3 (1970). In particular, an oxazole compound substituted by a trihalomethyl group, and an s-triazine compound are preferred.

An s-triazine derivative having bonded thereto at least one mono-, di- or trihalogen-substituted methyl group and an oxadiazole derivative are more preferred. Specific examples thereof include 2,4,6-tris(monochloromethyl)-s-triazine, 2,4,6-tris(dichloromethyl)-s-triazine, 2,4,6-tris(trichloromethyl)-s-triazine, 2-methyl-4,6-bis(trichloromethyl)-s-triazine, 2-n-propyl-4,6-bis(trichloromethyl)-s-triazine, 2-(α,α,β-trichloroethyl)-4,6-bis(trichloromethyl)-s-triazine, 2-phenyl-4,6-bis(trichloromethyl)-s-triazine, 2-(p-methoxyphenyl)-4,6-bis(trichloromethyl)-s-triazine, 2-(3,4-epoxyphenyl)-4,6-bis(trichloromethyl)-s-triazine, 2-(p-chlorophenyl)-4,6-bis(trichloromethyl)-s-triazine, 2-(p-bromophenyl)-4,6-bis(trichloromethyl)-s-triazine, 2-(p-fluorophenyl)-4,6-bis(trichloromethyl)-s-triazine, 2-(p-trifluoromethylphenyl)-4,6-bis(trichloromethyl)-s-triazine, 2-(2,6-dichlorophenyl)-4,6-bis(trichloromethyl)-s-triazine, 2-(2,6-difluorophenyl)-4,6-bis(trichloromethyl)-s-triazine, 2-(2,6-dibromophenyl)-4,6-bis(trichloromethyl)-s-triazine, 2-(4-biphenylyl)-4,6-bis(trichloromethyl)-s-triazine, 2-(4′-chloro-4-biphenylyl)-4,6-bis(trichloromethyl)-s-triazine, 2-(p-cyanophenyl)-4,6-bis(trichloromethyl)-s-triazine, 2-(p-acetylphenyl)-4,6-bis(trichloromethyl)-s-triazine, 2-(p-ethoxycarbonylphenyl)-4,6-bis(trichloromethyl)-s-triazine, 2-(p-phenoxycarbonylphenyl)-4,6-bis(trichloromethyl)-s-triazine, 2-(p-methylsulfonyl-phenyl)-4,6-bis(trichloromethyl)-s-triazine, 2-(p-dimethylsulfoniumphenyl)-4,6-bis(trichloromethyl)-s-triazine•tetrafluoroborate, 2-(2,4-difluorophenyl)-4,6-bis(trichloromethyl)-s-triazine, 2-(p-diethoxyphosphorylphenyl)-4,6-bis(trichloromethyl)-s-triazine, 2-[4-(4-hydroxyphenylcarbonylamino)phenyl]-4,6-bis(trichloromethyl)-s-triazine, 2-[4-(p-methoxyphenyl)-1,3-butadienyl]-4,6-bis(trichloromethyl)-s-triazine, 2-styryl-4,6-bis(trichloromethyl)-s-triazine, 2-(p-methoxystyryl)-4,6-bis(trichloromethyl)-s-triazine, 2-(p-i-propyloxystyryl)-4,6-bis(trichloromethyl)-s-triazine, 2-(p-tolyl)-4,6-bis(trichloromethyl)-s-triazine, 2-(4-methoxynaphthyl)-4,6-bis(trichloromethyl)-s-triazine, 2-phenylthio-4,6-bis(trichloromethyl)-s-triazine, 2-benzylthio-4,6-bis(trichloromethyl)-s-triazine, 2,4,6-tris(dibromomethyl)-s-triazine, 2,4,6-tris(tribromomethyl)-s-triazine, 2-methyl-4,6-bis(tribromomethyl)-s-triazine, 2-methoxy-4,6-bis(tribromomethyl)-s-triazine, 2-(o-methoxystyryl)-5-trichloromethyl-1,3,4-oxadiazole, 2-(3,4-epoxystyryl)-5-trichloromethyl-1,3,4-oxadiazole, 2-[1-phenyl-2-(4-methoxyphenyl)vinyl]-5-trichloromethyl-1,3,4-oxadiazole, 2-(p-hydroxystyryl)-5-trichloromethyl-1,3,4-oxadiazole, 2-(3,4-dihydroxystyryl)-5-trichloromethyl-1,3,4-oxadiazole and 2-(p-tert-butoxystyryl)-5-trichloromethyl-1,3,4-oxadiazole.

Examples of the carbonyl compound (b) include a benzophenone derivative such as benzophenone, Michler's ketone, 2-methylbenzophenone, 3-methylbenzophenone, 4-methylbenzophenone, 2-chlorobenzophenone, 4-bromobenzo-phenone and 2-carboxybenzophenone, an acetophenone derivative such as 2,2-dimethoxy-2-phenylacetophenone, 2,2-diethoxyacetophenone, 1-hydroxycyclohexyl phenyl ketone, α-hydroxy-2-methylphenylpropanone, 1-hydroxy-1-methylethyl-(p-isopropylphenyl)ketone, 1-hydroxy-1-(p-dodecylphenyl)ketone, 2-methyl-(4′-(methylthio)phenyl)-2-morpholino-1-propanone and 1,1,1-trichloromethyl-(p-butylphenyl)ketone, a thioxanthone derivative such as thioxanthone, 2-ethylthioxanthone, 2-isopropylthioxanthone, 2-chlorothioxanthone, 2,4-dimethylthioxanthone, 2,4-diethylthioxanthone and 2,4-diisopropylthioxanthone, and a benzoic acid ester derivative such as ethyl p-dimethylaminobenzoate and ethyl p-diethylaminobenzoate.

Examples of the azo compound (c) which can be used include azo compounds described in JP-A-8-108621.

Examples of the organic peroxide (d) include trimethylcyclohexanone peroxide, acetylacetone peroxide, 1,1-bis(tert-butylperoxy)-3,3,5-trimethylcyclohexane, 1,1-bis(tert-butylperoxy)cyclohexane, 2,2-bis(tert-butylperoxy)butane, tert-butyl hydroperoxide, cumene hydroperoxide, diisopropylbenzene hydroperoxide, 2,5-dimethylhexane-2,5-dihydroperoxide, 1,1,3,3-tetramethylbutyl hydroperoxide, tert-butylcumyl peroxide, dicumyl peroxide, 2,5-dimethyl-2,5-di(tert-butylperoxy)hexane, 2,5-oxanoyl peroxide, succinic peroxide, benzoyl peroxide, 2,4-dichlorobenzoyl peroxide, diisopropyl peroxydicarbonate, di-2-ethylhexyl peroxydicarbonate, di-2-ethoxyethyl peroxydicarbonate, dimethoxyisopropyl peroxycarbonate, di(3-methyl-3-methoxybutyl) peroxydicarbonate, tert-butyl peroxyacetate, tert-butyl peroxypivalate, tert-butyl peroxyneodecanoate, tert-butyl peroxyoctanoate, tert-butyl peroxylaurate, tertiary carbonate, 3,3′,4,4′-tetra(tert-butylperoxycarbonyl)benzophenone, 3,3′,4,4′-tetra(tert-hexylperoxycarbonyl)benzophenone, 3,3′,4,4′-tetra(p-isopropylcumylperoxycarbonyl)benzophenone, carbonyl di(tert-butylperoxydihydrogendiphthalate) and carbonyl di(tert-hexylperoxydihydrogendiphthalate).

Examples of the metallocene compound (e) include various titanocene compounds described in JP-A-59-152396, JP-A-61-151197, JP-A-63-41484, JP-A-2-249, JP-A-2-4705 and JP-A-5-83588, such as dicyclopentadienyl-Ti-bisphenyl, dicyclopentadienyl-Ti-bis-2,6-difluorophen-1-yl, dicyclopentadienyl-Ti-bis-2,4-difluorophen-1-yl, dicyclopentadienyl-Ti-bis-2,4,6-trifluorophen-1-yl, dicyclopentadienyl-Ti-bis-2,3,5,6-tetrafluorophen-1-yl, dicyclopentadienyl-Ti-bis-2,3,4,5,6-pentafluorophen-1-yl, dimethylcyclopentadienyl-Ti-bis-2,6-difluorophen-1-yl, dimethylcyclopentadienyl-Ti-bis-2,4,6-trifluorophen-1-yl, dimethylcyclopentadienyl-Ti-bis-2,3,5,6-tetrafluorophen-1-yl, dimethylcyclopentadienyl-Ti-bis-2,3,4,5,6-pentafluorophen-1-yl and dicyclopentadienyl-Ti-bis-2,6-difluoro-3-(pyrrol-1-yl)phen-1-yl, and iron-arene complexes described in JP-A-1-304453 and JP-A-1-152109.

Examples of the azide compound (f) include 2,6-bis(4-azidobenzylidene)-4-methylcyclohexanone.

Examples of the hexaarylbiimidazole compound (g) include various compounds described in JP-B-6-29285 and U.S. Pat. Nos. 3,479,185, 4,311,783 and 4,622,286, such as 2,2′-bis(o-chlorophenyl)-4,4′,5,5′-tetraphenylbiimidazole, 2,2′-bis(o-bromophenyl)-4,4′,5,5′-tetraphenylbiimidazole, 2,2′-bis(o,p-dichlorophenyl)-4,4′,5,5′-tetraphenylbimidazole, 2,2′-bis(o-chlorophenyl)-4,4′,5,5′-tetra(m-methoxyphenyl)-biimidazole, 2,2′-bis(o,o′-dichlorophenyl)-4,4′,5,5′-tetraphenylbiimidazole, 2,2′-bis(o-nitrophenyl)-4,4′,5,5′-tetraphenylbiimidazole, 2,2′-bis(o-methylphenyl)-4,4′,5,5′-tetraphenylbiimidazole and 2,2′-bis(o-trifluorophenyl)-4,4′,5,5′-tetraphenylbiimidazole.

Examples of the organic borate compound (h) include organic borate salts described in JP-A-62-143044, JP-A-62-150242, JP-A-9-188685, JP-A-9-188686, JP-A-9-188710, JP-A-2000-131837, JP-A-2002-107916, Japanese Patent 2764769, JP-A-2002-116539 and Martin Kunz, Rad Tech '98. Proceeding April 19-22, 1998, Chicago; organoboron sulfonium complexes and organoboron oxosulfonium complexes described in JP-A-6-157623, JP-A-6-175564 and JP-A-6-175561; organoboron iodonium complexes described in JP-A-6-175554 and JP-A-6-175553; organoboron phosphonium complexes described in JP-A-9-188710; and organoboron transition metal coordination complexes described in JP-A-6-348011, JP-A-7-128785, JP-A-7-140589, JP-A-7-306527 and JP-A-7-292014.

Examples of the disulfone compound (i) include compounds described in JP-A-61-166544 and JP-A-2003-328465.

Examples of the oxime ester compound (j) include compounds described in J.C.S. Perkin II, 1653-1660 (1979), J.C.S. Perkin II, 156-162 (1979), Journal of Photopolymer Science and Technology, 202-232 (1995), JP-A-2000-66385 and JP-A-2000-80068. Specific examples thereof include the compounds shown by the following structural formulae.

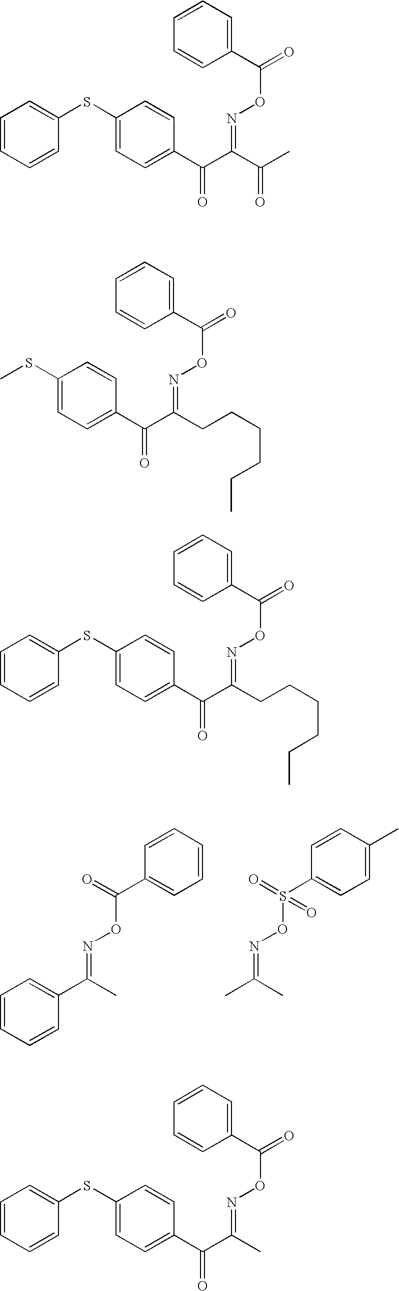

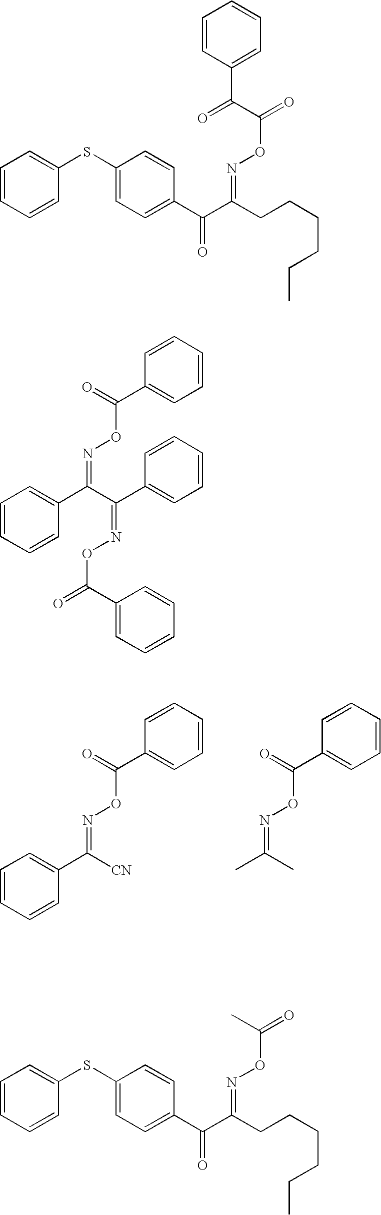

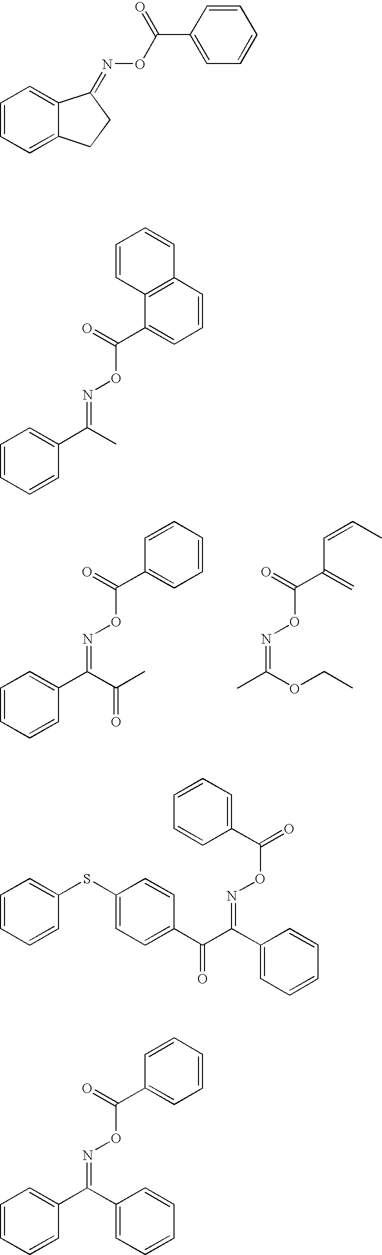

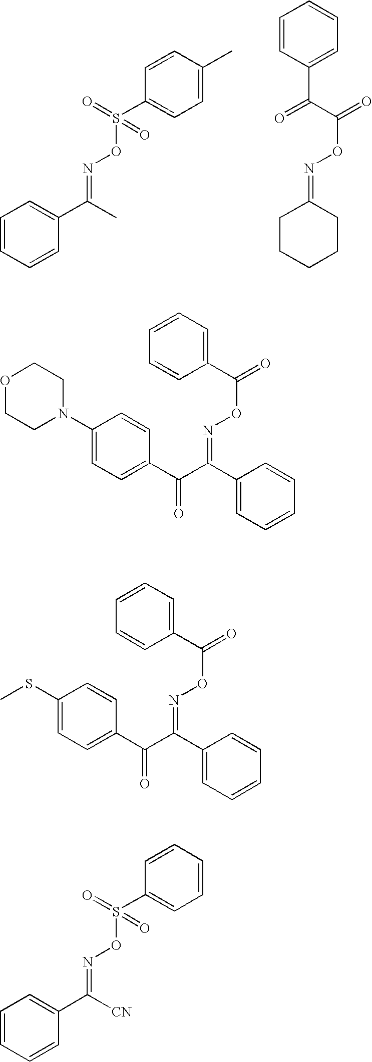

Examples of the onium salt compound (k) include onium salts such as diazonium salts described in S. I. Schlesinger, Photogr. Sci. Eng., 18, 387 (1974) and T. S. Bal et al., Polymer, 21, 423 (1980), ammonium salts described in U.S. Pat. No. 4,069,055 and JP-A-4-365049, phosphonium salts described in U.S. Pat. Nos. 4,069,055 and 4,069,056, iodonium salts described in European Patent 104,143, U.S. Pat. Nos. 339,049 and 410,201, JP-A-2-150848 and JP-A-2-296514, sulfonium salts described in European Patents 370,693, 390,214, 233,567, 297,443 and 297,442, U.S. Pat. Nos. 4,933,377, 161,811, 410,201, 339,049, 4,760,013, 4,734,444 and 2,833,827, and German Patents 2,904,626, 3,604,580 and 3,604,581, selenonium salts described in J. V. Crivello et al., Macromolecules, 10 (6), 1307 (1977) and J. V. Crivello et al., J. Polymer Sci., Polymer Chem. Ed., 17, 1047 (1979), and arsonium salts described in C. S. Wen et al., Teh. Proc. Conf. Rad. Curing ASIA, p. 478, Tokyo, Oct. (1988).

Above all, an oxime ester compound, a diazonium salt, an iodonium salt and a sulfonium salt are preferred in view of reactivity and stability. In the present invention, such an onium salt acts as an ionic radical polymerization initiator but not as an acid generator.

The onium salt suitably used in the present invention is an onium salt represented by any one of the following formulae (RI-I) to (RI-III):

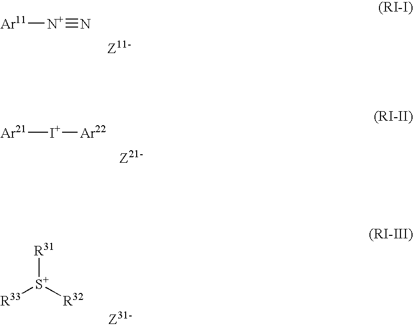

In formula (RI-I), Ar¹¹ represents an aryl group having a carbon number of 20 or less, which may have from 1 to 6 substituents, and preferred examples of the substituent include an alkyl group having a carbon number of 1 to 12, an alkenyl group having a carbon number of 1 to 12, an alkynyl group having a carbon number of 1 to 12, an aryl group having a carbon number of 1 to 12, an alkoxy group having a carbon number of 1 to 12, an aryloxy group having a carbon number of 1 to 12, a halogen atom, an alkylamino group having a carbon number of 1 to 12, a dialkylamino group having a carbon number of 1 to 12, an alkylamido or arylamido group having a carbon number of 1 to 12, a carbonyl group, a carboxyl group, a cyano group, a sulfonyl group, a thioalkyl group having a carbon number of 1 to 12, and a thioaryl group having a carbon number of 1 to 12. Z¹¹⁻ represents a monovalent anion and is a halogen ion, a perchlorate ion, a hexafluorophosphate ion, a tetrafluoroborate ion, a sulfonate ion, a sulfinate ion, a thiosulfonate ion or a sulfate ion. In view of stability and visibility of the print-out image, the anion is preferably a perchlorate ion, a hexafluorophosphate ion, a tetrafluoroborate ion, a sulfonate ion or a sulfinate ion.

In formula (RI-II), Ar²¹ and Ar²² each independently represents an aryl group having a carbon number of 20 or less, which may have from 1 to 6 substituents, and preferred examples of the substituent include an alkyl group having a carbon number of 1 to 12, an alkenyl group having a carbon number of 1 to 12, an alkynyl group having a carbon number of 1 to 12, an aryl group having a carbon number of 1 to 12, an alkoxy group having a carbon number of 1 to 12, an aryloxy group having a carbon number of 1 to 12, a halogen atom, an alkylamino group having a carbon number of 1 to 12, a dialkylamino group having a carbon number of 1 to 12, an alkylamido or arylamido group having a carbon number of 1 to 12, a carbonyl group, a carboxyl group, a cyano group, a sulfonyl group, a thioalkyl group having a carbon number of 1 to 12, and a thioaryl group having a carbon number of 1 to 12. Z²¹⁻ represents a monovalent anion and is a halogen ion, a perchlorate ion, a hexafluorophosphate ion, a tetrafluoroborate ion, a sulfonate ion, a sulfinate ion, a thiosulfonate ion or a sulfate ion. In view of stability and visibility of the print-out image, the anion is preferably a perchlorate ion, a hexafluorophosphate ion, a tetrafluoroborate ion, a sulfonate ion, a sulfinate ion or a carboxylate ion.

In formula (RI-III), R³¹, R³² and R³³ each independently represents an aryl, alkyl, alkenyl or alkynyl group having a carbon number of 20 or less, which may have from 1 to 6 substituents, and in view of reactivity and stability, is preferably an aryl group. Preferred examples of the substituent include an alkyl group having a carbon number of 1 to 12, an alkenyl group having a carbon number of 1 to 12, an alkynyl group having a carbon number of 1 to 12, an aryl group having a carbon number of 1 to 12, an alkoxy group having a carbon number of 1 to 12, an aryloxy group having a carbon number of 1 to 12, a halogen atom, an alkylamino group having a carbon number of 1 to 12, a dialkylamino group having a carbon number of 1 to 12, an alkylamido or arylamido group having a carbon number of 1 to 12, a carbonyl group, a carboxyl group, a cyano group, a sulfonyl group, a thioalkyl group having a carbon number of 1 to 12, and a thioaryl group having a carbon number of 1 to 12. Z³¹⁻ represents a monovalent anion and is a halogen ion, a perchlorate ion, a hexafluorophosphate ion, a tetrafluoroborate ion, a sulfonate ion, a sulfinate ion, a thiosulfonate ion, a sulfate ion or a carboxylate ion. In view of stability and visibility of the print-out image, the anion is preferably a perchlorate ion, a hexafluorophosphate ion, a tetrafluoroborate ion, a sulfonate ion, a sulfinate ion or a carboxylate ion, more preferably a carboxylate ion described in JP-A-2001-343742, still more preferably a carboxylate ion described in JP-A-2002-148790.

Examples of the onium salt compound suitably used as the radical polymerization initiator in the present invention are set forth below, but the present invention is not limited thereto.

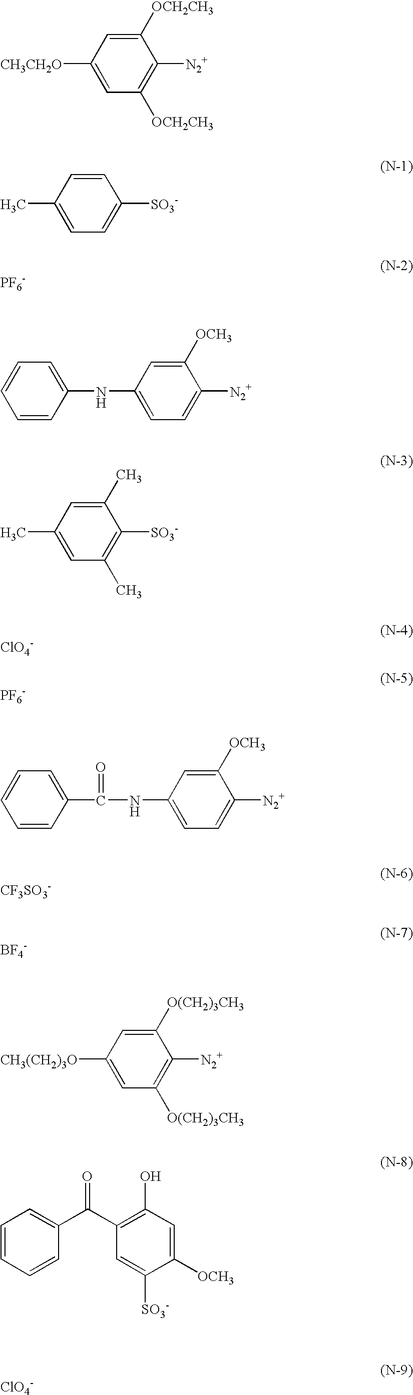

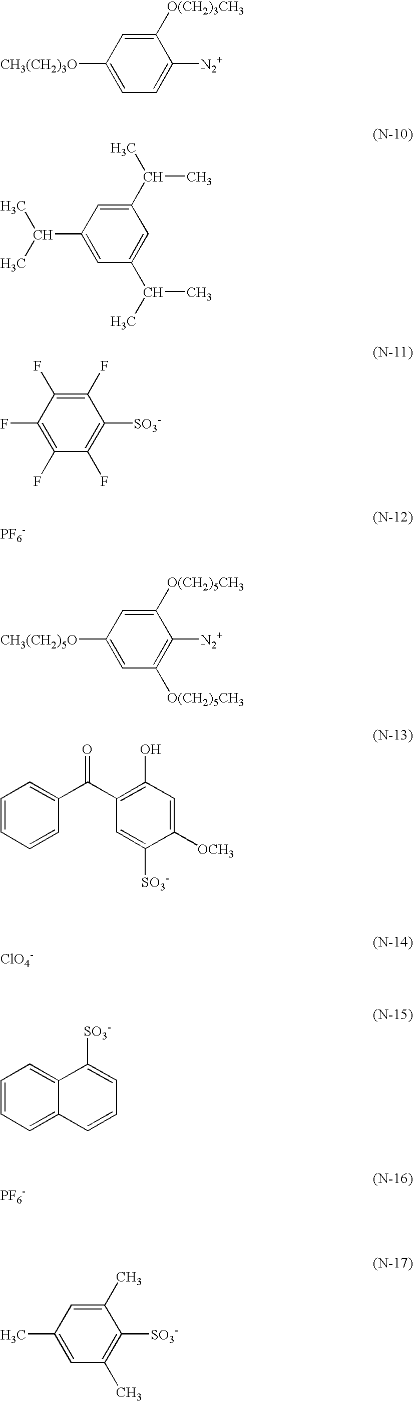

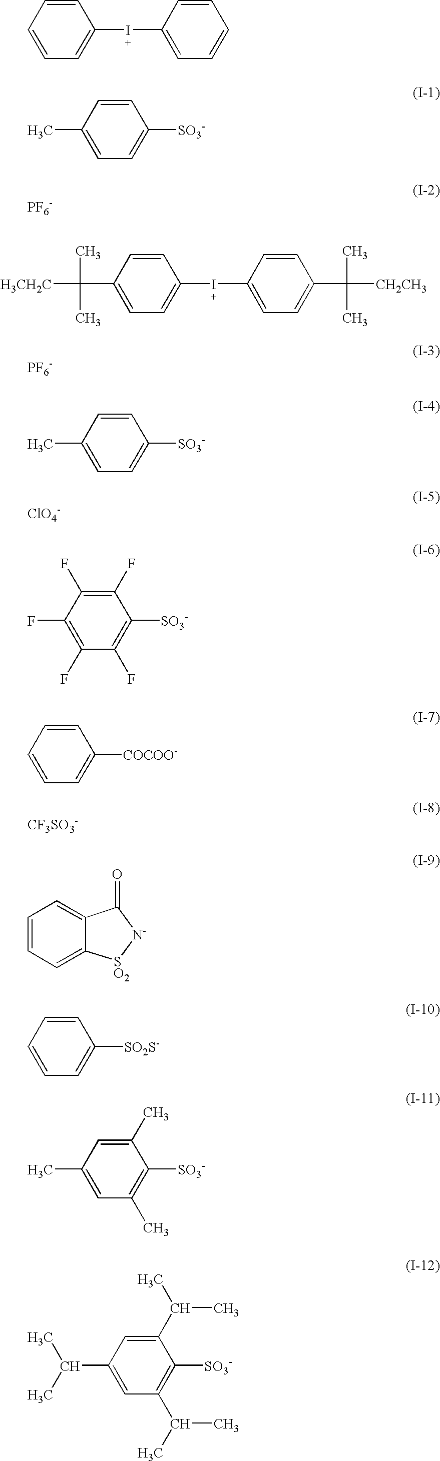

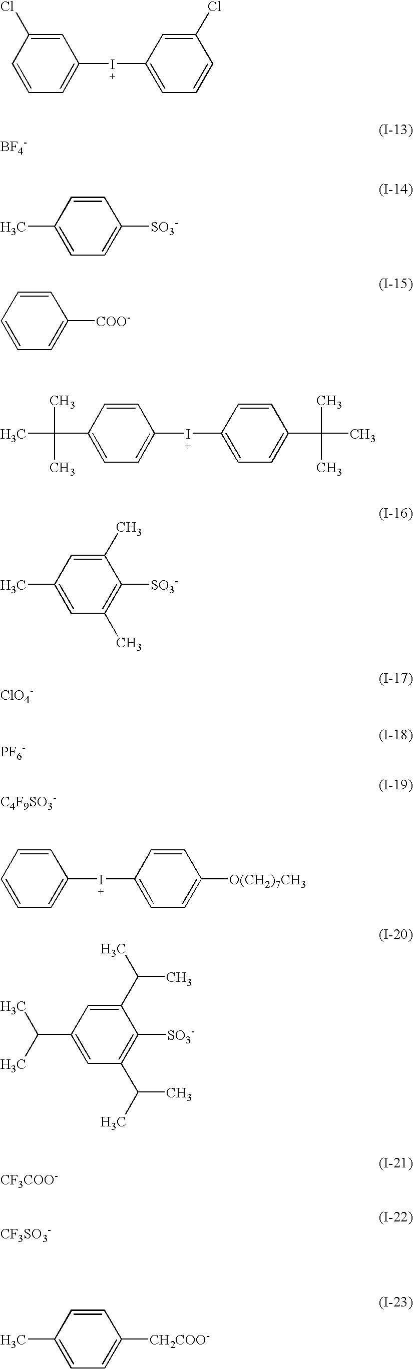

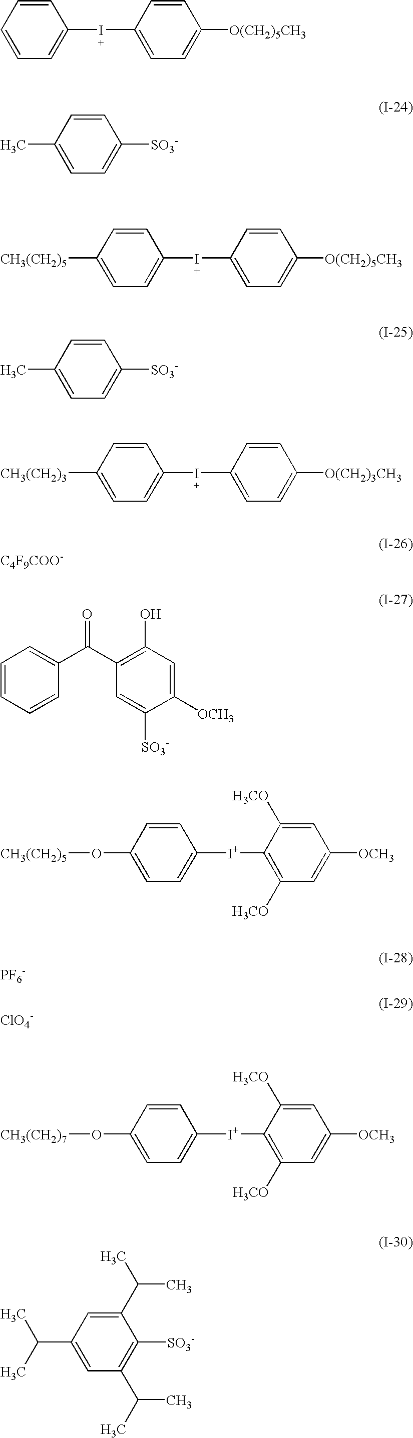

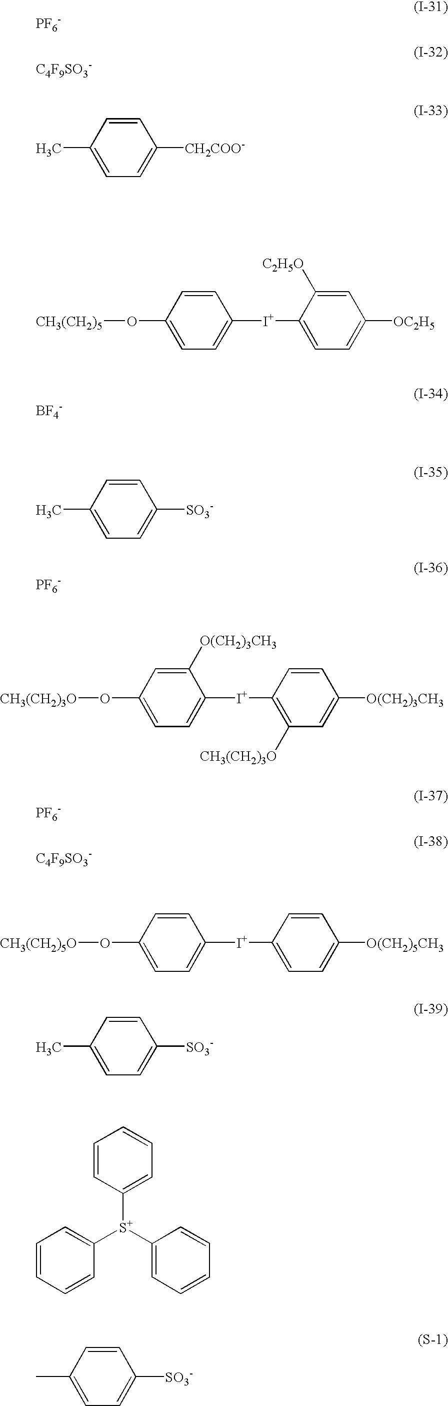

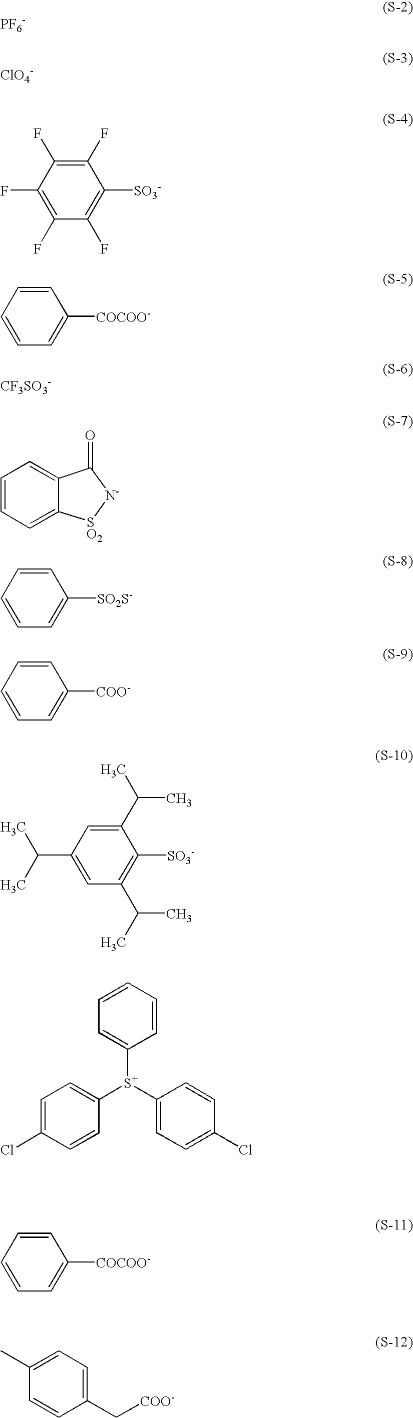

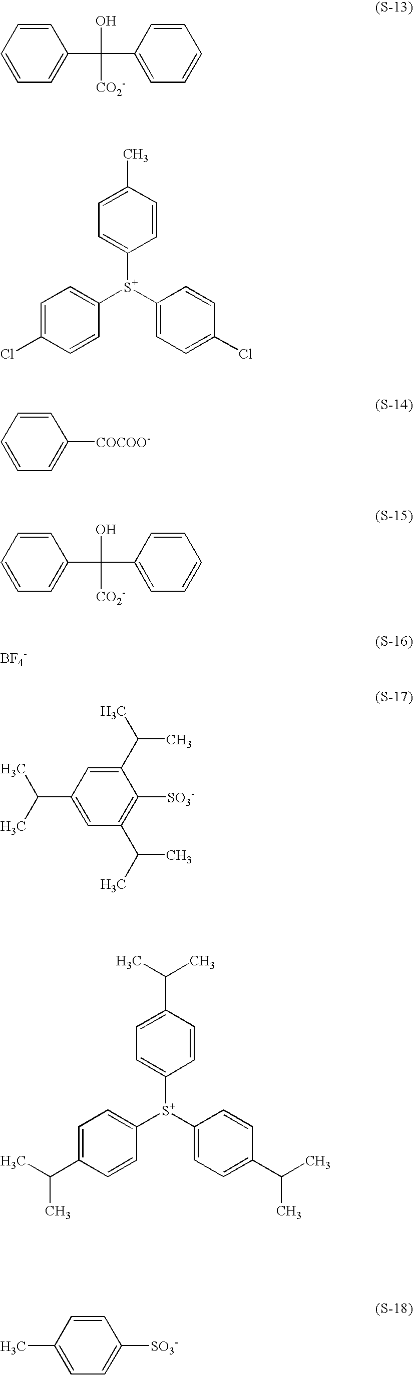

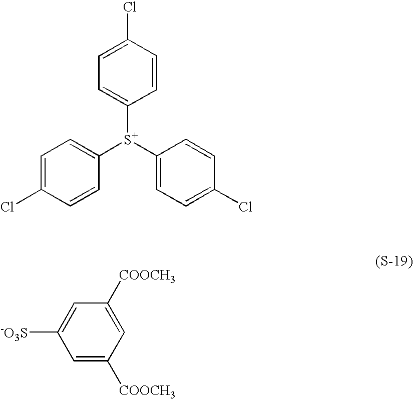

The polymerization initiator (B) is not limited to those described above, but above all, in view of reactivity and stability, (a) an organic halide, particularly a triazine-based initiator, (j) an oxime ester compound, and (k) an onium salt compound including a diazonium salt, an iodonium salt and a sulfonium salt are more preferred. Out of these radical polymerization initiators, from the standpoint of enhancing the visibility of the print-out image by the combination with an infrared absorbent, an onium salt having, as the counter ion, an inorganic anion such as PF₆⁻ or BF₄⁻ is preferred. Furthermore, the onium salt is preferably diaryl iodonium because of excellent color formation.

One of these radical polymerization initiators (B) may be used alone, or two or more thereof may be used in combination.

The radical polymerization initiator (B) may be added in a ratio of preferably 0.1 to 50 mass %, more preferably from 0.5 to 30 mass %, still more preferably from 0.8 to 20 mass %, based on all solid contents constituting the image recording layer. Within this range, good sensitivity and good scumming resistance of the non-image part at the printing can be obtained.

The radical polymerization initiator (B) may be added together with other components in the same layer or may be added to another image recording layer separately provided or a layer adjacent thereto.

### <(C) Polymerizable Compound>

The polymerizable compound (C) which can be used in the present invention is an addition-polymerizable compound having at least one ethylenically unsaturated double bond and is selected from compounds having at least one, preferably two or more, terminal ethylenically unsaturated bonds. Such compounds are widely known in this industrial field and these known compounds can be used in the present invention without any particular limitation. These compounds have a chemical mode such as monomer, prepolymer (that is, dimer, trimer or oligomer) or a mixture or (co)polymer thereof.

Examples of the monomer and its copolymer include an unsaturated carboxylic acid (e.g., acrylic acid, methacrylic acid, itaconic acid, crotonic acid, isocrotonic acid, maleic acid), and esters and amides thereof. Among these, preferred are esters of an unsaturated carboxylic acid with an aliphatic polyhydric alcohol compound, and amides of an unsaturated carboxylic acid with an aliphatic polyvalent amine compound. Also, an addition reaction product of unsaturated carboxylic acid esters or amides having a nucleophilic substituent such as hydroxyl group, amino group or mercapto group with monofunctional or polyfunctional isocyanates or epoxies, and a dehydrating condensation reaction product with a monofunctional or polyfunctional carboxylic acid, may be suitably used. Furthermore, an addition reaction product of unsaturated carboxylic acid esters or amides having an electrophilic substituent such as isocyanate group or epoxy group with monofunctional or polyfunctional alcohols, amines or thiols, and a displacement reaction product of unsaturated carboxylic acid esters or amides having a desorptive substituent such as halogen group or tosyloxy group with monofunctional or polyfunctional alcohols, amines or thiols, may also be suitably used. In addition, compounds where the unsaturated carboxylic acid of the above-described compounds is replaced by an unsaturated phosphonic acid, styrene, vinyl ether or the like, may also be used.

Specific examples of the ester monomer of an aliphatic polyhydric alcohol compound with an unsaturated carboxylic acid include the followings. Examples of the acrylic acid ester include ethylene glycol diacrylate, triethylene glycol diacrylate, 1,3-butanediol diacrylate, tetramethylene glycol diacrylate, propylene glycol diacrylate, neopentyl glycol diacrylate, trimethylolpropane triacrylate, trimethylolpropane tri(acryloyloxypropyl)ether, trimethylolethane triacrylate, hexanediol diacrylate, 1,4-cyclohexanediol diacrylate, tetraethylene glycol diacrylate, pentaerythritol diacrylate, pentaerythritol triacrylate, pentaerythritol tetraacrylate, dipentaerythritol diacrylate, dipentaerythritol hexaacrylate, sorbitol triacrylate, sorbitol tetraacrylate, sorbitol pentaacrylate, sorbitol hexaacrylate, tri(acryloyloxyethyl)isocyanurate and polyester acrylate oligomer.

Examples of the methacrylic acid ester include tetramethylene glycol dimethacrylate, triethylene glycol dimethacrylate, neopentyl glycol dimethacrylate, trimethylolpropane trimethacrylate, trimethylolethane trimethacrylate, ethylene glycol dimethacrylate, 1,3-butanediol dimethacrylate, hexanediol dimethacrylate, pentaerythritol dimethacrylate, pentaerythritol trimethacrylate, pentaerythritol tetramethacrylate, dipentaerythritol dimethacrylate, dipentaerythritol hexamethacrylate, sorbitol trimethacrylate, sorbitol tetramethacrylate, bis[p-(3-methacryloxy-2-hydroxypropoxy)-phenyl]dimethylmethane and bis[p-(methacryloxyethoxy)phenyl]dimethylmethane.

Examples of the itaconic acid ester include ethylene glycol diitaconate, propylene glycol diitaconate, 1,3-butanediol diitaconate, 1,4-butanediol diitaconate, tetramethylene glycol diitaconate, pentaerythritol diitaconate and sorbitol tetraitaconate.

Examples of the crotonic acid ester include ethylene glycol dicrotonate, tetramethylene glycol dicrotonate, pentaerythritol dicrotonate and sorbitol tetradicrotonate.

Examples of the isocrotonic acid ester include ethylene glycol diisocrotonate, pentaerythritol diisocrotonate and sorbitol tetraisocrotonate.

Examples of the maleic acid ester include ethylene glycol dimaleate, triethylene glycol dimaleate, pentaerythritol dimaleate and sorbitol tetramaleate.

Other suitable examples of the ester include aliphatic alcohol-based esters described in JP-B-51-47334 and JP-A-57-196231, those having an aromatic skeleton described in JP-A-59-5240, JP-A-59-5241 and JP-A-2-226149, and those containing an amino group described in JP-A-1-165613. Such ester monomers may also be used as a mixture.

Specific examples of the amide monomer of an aliphatic polyvalent amine compound with an unsaturated carboxylic acid include methylenebis-acrylamide, methylenebis-methacrylamide, 1,6-hexamethylenebis-acrylamide, 1,6-hexamethylenebis-methacrylamide, diethylenetriaminetrisacrylamide, xylylenebisacrylamide and xylylenebismethacrylamide. Other preferred examples of the amide-type monomer include those having a cyclohexylene structure described in JP-B-54-21726.

A urethane-based addition-polymerizable compound produced using an addition reaction of an isocyanate with a hydroxyl group is also preferred, and specific examples thereof include a vinyl urethane compound having two or more polymerizable vinyl groups within one molecule described in JP-B-48-41708, which is obtained by adding a vinyl monomer having a hydroxyl group represented by the following formula (2) to a polyisocyanate compound having two or more isocyanate groups within one molecule:

CH₂═C(R⁴)COOCH₂CH(R⁵)OH (2)

(wherein R⁴ and R⁵ each represents H or CH₃).

Also, urethane acrylates described in JP-A-51-37193, JP-B-2-32293 and JP-B-2-16765, and urethane compounds having an ethylene oxide-type skeleton described in JP-B-58-49860, JP-B-56-17654, JP-B-62-39417 and JP-B-62-39418 may be suitably used. Furthermore, when an addition-polymerizable compound having an amino or sulfide structure within the molecule described in JP-A-63-277653, JP-A-63-260909 and JP-A-1-105238 is used, a photopolymerizable composition very excellent in the photosensitization speed can be obtained.

Other examples include a polyfunctional acrylate or methacrylate such as polyester acrylates described in JP-A-48-64183, JP-B-49-43191 and JP-B-52-30490 and epoxy acrylates obtained by reacting polyester acrylates and an epoxy resin with an acrylic or methacrylic acid. In addition, specific unsaturated compounds described in JP-B-46-43946, JP-B-1-40337 and JP-B-1-40336, and a vinyl phosphonic acid-based compound described in JP-A-2-25493 may also be used. In some cases, a structure containing a perfluoroalkyl group described in JP-A-61-22048 is suitably used. Furthermore, those described as a photocurable monomer or oligomer in Adhesion, Vol. 20, No. 7, pp. 300-308 (1984) may also be used.

Details of the use method of these addition-polymerizable compounds, such as structure, single or combination use and amount added, can be freely selected in accordance with the performance design of the final lithographic printing plate precursor, for example, from the following standpoints.

In view of sensitivity, a structure having a large unsaturated group content per molecule is preferred and in most cases, a bifunctional or greater functional compound is preferred. For increasing the strength of the image part, namely, the cured film, a trifunctional or greater functional compound is preferred. Also, a method of controlling both the sensitivity and the strength by using a combination of compounds differing in the functional number and in the polymerizable group (for example, an acrylic acid ester, a methacrylic acid ester, a styrene-based compound or a vinyl ether-based compound) is effective.

The selection and use method of the addition-polymerizable compound are important factors also for the compatibility and dispersibility with other components (e.g., binder polymer, radical polymerization initiator, colorant) in the image recording layer. For example, the compatibility may be improved in some cases by using a low purity compound or using two or more compounds in combination. Also, a specific structure may be selected for the purpose of improving the adherence to the substrate, protective layer described later, or the like.

In the present invention, the polymerizable compound (C) is preferably used in an amount of 5 to 80 mass %, more preferably from 25 to 75 mass %, based on nonvolatile components in the image recording layer.

Other than these, as for the use method of the addition-polymerizable compound, an appropriate structure, formulation or amount added may be freely selected by taking into account the degree of polymerization inhibition due to oxygen, resolution, fogging, change in refractive index, surface tackiness and the like. Depending on the case, such a layer structure or a coating method as undercoat and overcoat may also be employed.

The image recording layer for use in the present invention may contain the following components, if desired.

### <(D) Hydrophobic Precursor>

The hydrophobic precursor for use in the invention includes a fine particle capable of converting the image recording layer to be hydrophobic when heated. The fine particle is preferably at least one particle selected from a hydrophobic thermoplastic polymer fine particle and a thermally reactive polymer fine particle.

Suitable examples of the hydrophobic thermoplastic polymer fine particle for use in the image recording layer include hydrophobic thermoplastic polymer fine particles described in Research Disclosure, No. 33303 (January, 1992), JP-A-9-123387, JP-A-9-131850, JP-A-9-171249, JP-A-9-171250 and European Patent 931,647.

Specific examples of the polymer constituting the polymer fine particle include a homopolymer or copolymer of a monomer such as ethylene, styrene, vinyl chloride, methyl acrylate, ethyl acrylate, methyl methacrylate, ethyl methacrylate, vinylidene chloride, acrylonitrile or vinyl carbazole, and a mixture thereof. Among these, polystyrene and polymethyl methacrylate are more preferred.

The average particle diameter of the hydrophobic thermoplastic polymer fine particle for use in the invention is preferably from 0.01 to 2.0 μm.

The synthesis method of the hydrophobic thermoplastic polymer fine particle having the above-described particle diameter, which is usable as the hydrophobic precursor, includes an emulsion polymerization method and a suspension polymerization method and further includes a method of dissolving the above-described compound in a water-insoluble organic solvent, mixing and emulsifying the solution with an aqueous solution containing a dispersant, and solidifying the emulsion into a fine particle shape while volatizing the organic solvent under heating (a dissolution dispersion method).

The thermally reactive polymer fine particle usable as the hydrophobic precursor in the present invention includes a thermosetting polymer fine particle and a polymer fine particle having a thermally reactive group.

Examples of the thermosetting polymer include a resin having a phenolic skeleton, a urea resin (for example, a resin obtained by resinifying a urea derivative such as urea or methoxymethylated urea, with aldehydes such as formaldehyde), a melamine resin (for example, a resin obtained by resinifying melamine or its derivative with aldehydes such as formaldehyde), an alkyd resin, an unsaturated polyester resin, a polyurethane resin and an epoxy resin. Above all, a resin having a phenolic skeleton, a melamine resin, a urea resin and an epoxy resin are preferred.

Preferred examples of the resin having a phenolic skeleton include a phenolic resin obtained by resinifying phenol or cresol with aldehydes such as formaldehyde, a hydroxystyrene resin, and a polymer or copolymer of a methacrylamide, acrylamide, methacrylate or acrylate having a phenolic skeleton, such as N-(p-hydroxyphenyl)-methacrylamide or p-hydroxyphenyl methacrylate.

The average particle diameter of the thermosetting polymer fine particle for use in the invention is preferably from 0.01 to 2.0 μm.

Such a thermosetting polymer fine particle may be easily obtained by a known dissolution dispersion method but may also be produced by synthesizing the thermosetting polymer to take a fine particle shape. The production method of the thermosetting polymer fine particle is not limited thereto, and a known method may be appropriately employed.

As for the thermally reactive group in the polymer fine particle having a thermally reactive group for use in the invention, a functional group performing any reaction may be used as long as a chemical bond is formed, but suitable examples thereof include an ethylenically unsaturated group that performs a radical polymerization reaction, such as acryloyl group, methacryloyl group, vinyl group and allyl group; a cationic polymerizable group such as vinyl group and vinyloxy group; a functional group having an isocyanate group, a block form thereof, an epoxy group or a vinyloxy group, that performs an addition reaction, and a reaction partner active hydrogen atom, such as amino group, hydroxy group and carboxyl group; a functional group having a carboxyl group that performs a condensation reaction, and a reaction partner hydroxyl group or amino group; and a functional group having an acid anhydride that performs a ring-opening addition reaction, and a reaction partner amino group or hydroxyl group.

The functional group may be introduced into the polymer fine particle at the polymerization or may be introduced by utilizing a polymer reaction after the polymerization.

In the case of introducing the functional group at the polymerization, emulsion polymerization or suspension polymerization of a monomer having the above-described functional group is preferred. Specific examples of the monomer having the above-described functional group include, but are not limited to, allyl methacrylate, allyl acrylate, vinyl methacrylate, vinyl acrylate, 2-(vinyloxy)ethyl methacrylate, p-vinyloxystyrene, p-{2-(vinyloxy)ethyl}styrene, glycidyl methacrylate, glycidyl acrylate, 2-isocyanatoethyl methacrylate or a block isocyanate thereof with an alcohol or the like, 2-isocyanatoethyl acrylate or a block isocyanate thereof with an alcohol or the like, 2-aminoethyl methacrylate, 2-aminoethyl acrylate, 2-hydroxyethyl methacrylate, 2-hydroxyethyl acrylate, acrylic acid, methacrylic acid, maleic anhydride, a bifunctional acrylate, and a bifunctional methacrylate.

In the present invention, a copolymer of such a monomer with a thermally reactive group-free monomer copolymerizable with the monomer may also be used. Examples of the thermally reactive group-free copolymerizable monomer include a styrene, an alkyl acrylate, an alkyl methacrylate, an acrylonitrile and a vinyl acetate, but the thermally reactive group-free monomer is not limited thereto.

Examples of the polymer reaction used in the case of introducing the thermally reactive group after the polymerization include a polymer reaction described in International Publication No. 96/34316.

The polymer fine particle having a thermally reactive group is preferably a polymer fine particle causing coalescence of polymer fine particles with each other by the effect of heat, more preferably a polymer fine particle having a hydrophilic surface and being dispersible in water. The contact angle (water drop-in-air) of a film formed by coating only the polymer fine particle and drying the coating at a temperature not higher than the coagulation temperature is preferably lower than the contact angle (water drop-in-air) of a film formed by drying the coating at a temperature not lower than the coagulation temperature. The polymer fine particle surface may be made to have such hydrophilicity by adsorbing a hydrophilic polymer or oligomer such as polyvinyl alcohol or polyethylene glycol, or a hydrophilic low-molecular compound, to the polymer fine particle surface. However, the method for hydrophilizing the surface is not limited thereto.

The coagulation temperature of the polymer fine particle having a thermally reactive group is preferably 70° C. or more, and in consideration of stability with aging, more preferably 100° C. or more. The average particle diameter of the polymer fine particle is preferably from 0.01 to 2.0 μm, more preferably from 0.05 to 2.0 μm, and most preferably from 0.1 to 1.0 μm. Within this range, good resolution and good stability with aging can be obtained.

The content of the hydrophobic precursor is preferably from 5 to 90 mass % in terms of the solid content concentration. By the addition in this range, the strength of the image part can be enhanced.

### <(E) Binder Polymer>

In the image recording layer of the present invention, a binder polymer may be used for enhancing the film strength of the image recording layer. As for the binder polymer which can be used in the present invention, conventionally known binder polymers may be used without limitation, and a polymer having a film property is preferred. Examples of such a binder polymer include acrylic resin, polyvinyl acetal resin, polyurethane resin, polyurea resin, polyimide resin, polyamide resin, epoxy resin, methacrylic resin, polystyrene-based resin, novolak-type phenol-based resin, polyester resin, synthetic rubber and natural rubber.

The binder polymer may have a crosslinking property so as to enhance the film strength in the image part. The crosslinking property may be imparted to the binder polymer by introducing a crosslinking functional group such as ethylenically unsaturated bond into the main or side chain of the polymer. The crosslinking functional group may be introduced by copolymerization.

Examples of the polymer having an ethylenically unsaturated bond in the main chain of the molecule include poly-1,4-butadiene and poly-1,4-isoprene.

Examples of the polymer having an ethylenically unsaturated bond in the side chain of the molecule include a polymer which is a polymer of an acrylic or methacrylic acid ester or amide and in which the ester or amide residue (R in —COOR or CONHR) has an ethylenically unsaturated bond.

Examples of the residue (R above) having an ethylenically unsaturated bond include —(CH₂)ₙCR¹═CR³, —(CH₂O)ₙCH₂CR¹═CR²R³, —(CH₂CH₂O)ₙCH₂CR¹═CR²R³, —(CH₂)ₙNH—CO—O—CH₂CR¹═CR²R³, —(CH₂)ₙ—O—CO—CR¹═CR²R³ and (CH₂CH₂O)₂—X (wherein R¹ to R³ each represents a hydrogen atom, a halogen atom or an alkyl, aryl, alkoxy or aryloxy group having a carbon number of 1 to 20, R¹ and R² or R³ may combine together to form a ring, n represents an integer of 1 to 10, and X represents a dicyclopentadienyl residue).

Specific examples of the ester residue include —CH₂CH═CH₂ (described in JP-B-7-21633), —CH₂CH₂O—CH₂CH═CH₂, —CH₂C(CH₃)═CH₂, —CH₂CH═CH—C₆H₅, —CH₂CH₂OCOCH═CH—C₆H₅, —CH₂CH₂—NHCOO—CH₂CH═CH₂ and CH₂CH₂O—X (wherein X represents a dicyclopentadienyl residue).

Specific examples of the amide residue include —CH₂CH═CH₂, —CH₂CH₂—Y (wherein Y represents a cyclohexene residue) and —CH₂CH₂—OCO—CH═CH₂.

In the binder polymer having a crosslinking property, for example, a free radical (a polymerization initiating radical or a radical grown in the process of polymerization of a polymerizable compound) is added to the crosslinking functional group to cause an addition-polymerization between polymers directly or through a polymerization chain of the polymerizable compound, as a result, crosslinking is formed between polymer molecules and curing is thereby effected. Otherwise, an atom (for example, a hydrogen atom on the carbon atom adjacent to the functional crosslinking group) in the polymer is withdrawn by a free radical to produce a polymer radical and the polymer radicals combine together to form a crosslinking between polymer molecules, thereby effecting curing.

The content of the crosslinking group (the content of the radical-polymerizable unsaturated double bond determined by iodine titration) in the binder polymer is preferably from 0.1 to 10.0 mmol, more preferably from 1.0 to 7.0 mmol, most preferably from 2.0 to 5.5 mmol, per g of the binder polymer. Within this range, good sensitivity and good storage stability can be obtained.

Also, from the standpoint of enhancing the on-press developability, the binder polymer preferably has high solubility or dispersibility in an ink and/or a fountain solution. For increasing the solubility or dispersibility in an ink, the binder polymer is preferably lipophilic, whereas for increasing the solubility or dispersibility in a fountain solution, the binder polymer is preferably hydrophilic. Accordingly, in the present invention, it is also effective to use a lipophilic binder polymer and a hydrophilic binder polymer in combination.

Examples of the hydrophilic binder polymer which can be suitably used include those having a hydrophilic group such as hydroxy group, carboxyl group, carboxylate group, hydroxyethyl group, polyoxyethyl group, hydroxypropyl group, polyoxypropyl group, amino group, aminoethyl group, aminopropyl group, ammonium group, amide group, carboxymethyl group, sulfo group and phosphoric acid group.

Specific examples thereof include gum arabic, casein, gelatin, a starch derivative, carboxymethyl cellulose and a sodium salt thereof, cellulose acetate, sodium alginate, vinyl acetate-maleic acid copolymers, styrene-maleic acid copolymers, polyacrylic acids and salts thereof, polymethacrylic acids and salts thereof, a homopolymer or copolymer of hydroxyethyl methacrylate, a homopolymer or copolymer of hydroxyethyl acrylate, a homopolymer or copolymer of hydroxypropyl methacrylate, a homopolymer or copolymer of hydroxypropyl acrylate, a homopolymer or copolymer of hydroxybutyl methacrylate, a homopolymer or copolymer of hydroxybutyl acrylate, polyethylene glycols, hydroxypropylene polymers, polyvinyl alcohols, a hydrolyzed polyvinyl acetate having a hydrolysis degree of 60 mol % or more, preferably 80 mol % or more, polyvinyl formal, polyvinyl butyral, polyvinylpyrrolidone, a homopolymer or copolymer of acrylamide, a homopolymer or copolymer of methacrylamide, a homopolymer or copolymer of N-methylolacrylamide, polyvinylpyrrolidone, an alcohol-soluble nylon, and a polyether of 2,2-bis-(4-hydroxyphenyl)-propane with epichlorohydrin.

The binder polymer preferably has a mass average molar mass of 5,000 or more, more preferably from 10,000 to 300,000, and the number average molar mass thereof is preferably 1,000 or more, more preferably from 2,000 to 250,000. The polydispersity (mass average molar mass/number average molar mass) is preferably from 1.1 to 10.

The binder polymer is available as a commercial product or may be synthesized by a conventionally know method.

The binder polymer content is from 5 to 90 mass %, preferably from 5 to 80 mass %, more preferably from 10 to 70 mass %, based on the entire solid content of the image recording layer. Within this range, good strength of the image part and good image-forming property can be obtained.

Also, in the present invention, the polymerizable compound (C) and the binder polymer (E) are preferably used in amounts of giving a mass ratio of 0.4/1 to 1.8/1, more preferably from 0.7/1 to 1.5/1. Within this range, the effect of enhancing the on-press developability while maintaining the press life, which is the effect of the present invention, can be remarkably brought out.

<Microcapsule and/or Microgel>

From the standpoint of obtaining good on-press developability, the image recording layer for use in the present invention preferably takes an embodiment containing a microcapsule and/or a microgel. This is an embodiment of enclosing the constituent components (A) to (C) of the image recording layer and other constituent components described later in a microcapsule or a microgel.

The microcapsule for use in the present invention is a microcapsule having enclosed therein all or a part of the constituent components (components (A) to (C) above) of the image recording layer as described, for example, in JP-A-2001-277740 and JP-A-2001-277742. Incidentally, the constituent components of the image recording layer may be incorporated also into the outside of the microcapsule. Furthermore, in a preferred embodiment of the image recording layer containing a microcapsule, the hydrophobic constituent components are enclosed in the microcapsule and the hydrophilic constituent components are incorporated into the outside of the microcapsule.

On the other hand, in the present invention, the image recording layer may take an embodiment containing a crosslinked resin particle, that is, a microgel. The microgel may contain a part of the components (A) to (C) in the inside and/or the surface thereof. In particular, an embodiment of the microgel having the polymerizable compound (C) on the surface thereof and thereby becoming a reactive microgel is preferred.

As regards the method for microencapsulating or microgelling the constituent components of the image recording layer, a conventionally known method may be applied.

Examples of the method for producing a microcapsule include, but are not limited to, a method utilizing coacervation described in U.S. Pat. Nos. 2,800,457 and 2,800,458, a method by an interfacial polymerization process described in U.S. Pat. No. 3,287,154, JP-B-38-19574 and JP-B-42-446, a method by precipitation of a polymer described in U.S. Pat. Nos. 3,418,250 and 3,660,304, a method using an isocyanate polyol wall material described in U.S. Pat. No. 3,796,669, a method using an isocyanate wall material described in U.S. Pat. No. 3,914,511, a method using a urea-formaldehyde or urea-formaldehyde-resorcinol wall-forming material described in U.S. Pat. Nos. 4,001,140, 4,087,376 and 4,089,802, a method using a wall material such as melamine-formaldehyde resin or hydroxy cellulose described in U.S. Pat. No. 4,025,445, an in situ method by a monomer polymerization described in JP-B-36-9163 and JP-A-51-9079, a spray drying method described in British Patent 930,422 and U.S. Pat. No. 3,111,407, and an electrolytic dispersion cooling method described in British Patents 952,807 and 967,074.

The microcapsule wall for use in the present invention is preferably a microcapsule being three-dimensionally crosslinked structure and having a property of swelling with a solvent. From this standpoint, the wall material of the microcapsule is preferably a polyurea, a polyurethane, a polyester, a polycarbonate, a polyamide or a mixture thereof, more preferably a polyurea or a polyurethane. Also, a compound having a crosslinking functional group such as ethylenically unsaturated bond introducible into the binder polymer may be introduced into the microcapsule wall.

On the other hand, the method for preparing a microgel may utilize the granulation by an interfacial polymerization described in JP-B-38-19574 and JP-B-42-446 or the granulation by dispersion polymerization in a non-aqueous system described in JP-A-5-61214. However, the present invention is not limited to these methods.

As for the method utilizing interfacial polymerization, known production methods of a microcapsule can be applied.

The microgel for use in the invention is preferably a microgel granulated by interfacial polymerization and three-dimensionally crosslinked. From this point of view, the material used is preferably a polyurea, a polyurethane, a polyester, a polycarbonate, a polyamide or a mixture thereof, more preferably a polyurea or a polyurethane.

The average particle diameter of the microcapsule or microgel is preferably from 0.01 to 3.0 μm, more preferably from 0.05 to 2.0 μm, still more preferably from 0.10 to 1.0 μm. Within this range, good resolution and good stability with aging can be obtained.

### <Other Components>

The image recording layer for use in the present invention may further contain other components, if desired. These other components constituting the image recording layer for use in the present invention are described below.

### (1) Surfactant

In the present invention, a surfactant may be used in the image recording layer so as to accelerate the coated surface state.

The surfactant includes, for example, a nonionic surfactant, an anionic surfactant, a cationic surfactant, an amphoteric surfactant and a fluorine-containing surfactant. Above all, a fluorine-containing surfactant is preferred.

The fluorine-containing surfactant includes a fluorine-containing surfactant containing a perfluoroalkyl group within the molecule. Examples of such a fluorine-containing surfactant include an anionic type such as perfluoroalkylcarboxylate, perfluoroalkylsulfonate and perfluoroalkylphosphoric ester; an amphoteric type such as perfluoroalkylbetaine; a cationic type such as perfluoroalkyltrimethylammonium salt; and a nonionic type such as perfluoroalkylamine oxide, perfluoroalkyl ethylene oxide adduct, oligomer containing a perfluoroalkyl group and a hydrophilic group, oligomer containing a perfluoroalkyl group and a lipophilic group, oligomer containing a perfluoroalkyl group, a hydrophilic group and a lipophilic group, and urethane containing a perfluoroalkyl group and a lipophilic group. Other suitable examples include fluorine-containing surfactants described in JP-A-62-170950, JP-A-62-226143 and JP-A-60-168144.

One surfactant may be used alone, or two or more kinds of surfactants may be used in combination.

The surfactant content is preferably from 0.001 to 10 mass %, more preferably from 0.01 to 5 mass %, based on the entire solid content of the image recording layer.

### (2) Colorant

In the present invention, a dye having large absorption in the visible light region can be used as a colorant for the image. Specific examples thereof include Oil Yellow #101, Oil Yellow #103, Oil Pink #312, Oil Green BG, Oil Blue BOS, Oil Blue #603, Oil Black BY, Oil Black BS, Oil Black T-505 (all produced by Orient Chemical Industry Co., Ltd.), Victoria Pure Blue, Crystal Violet (CI42555), Methyl Violet (CI42535), Ethyl Violet, Rhodamine B (CI145170B), Malachite Green (CI42000), Methylene Blue (CI52015), and dyes described in JP-A-62-293247. Also, a pigment such as phthalocyanine-based pigment, azo-based pigment, carbon black and titanium oxide may be suitably used.

The colorant is preferably added because the image part and the non-image part can be clearly distinguished after image formation.

The amount of the colorant added is from 0.01 to 10 mass % based on the entire solid content of the image recording material.

### (3) Printing-Out Agent

In the image recording layer of the present invention, a compound capable of discoloring by the effect of an acid or a radical can be added so as to produce a print-out image.

As for such a compound, various coloring matters such as diphenylmethane type, triphenylmethane type, thiazine type, oxazine type, xanthene type, anthraquinone type, iminoquinone type, azo type and azomethine type may be effectively used.

Specific examples thereof include dyes such as Brilliant Green, Ethyl Violet, Methyl Green, Crystal Violet, Basic Fuchsine, Methyl Violet 2B, Quinaldine Red, Rose Bengale, Metanil Yellow, Thymolsulfophthalein, Xylenol Blue, Methyl Orange, Paramethyl Red, Congo Red, Benzopurpurine 4B, α-Naphthyl Red, Nile Blue 2B, Nile Blue A, Methyl Violet, Malachite Green, Parafuchsine, Victoria Pure Blue BOH [produced by Hodogaya Chemical Co., Ltd.], Oil Blue #603 [produced by Orient Chemical Industry Co., Ltd.], Oil Pink #312 [produced by Orient Chemical Industry Co., Ltd.], Oil Red 5B [produced by Orient Chemical Industry Co., Ltd.], Oil Scarlet #308 [produced by Orient Chemical Industry Co., Ltd.], Oil Red OG [produced by Orient Chemical Industry Co., Ltd.], Oil Red RR [produced by Orient Chemical Industry Co., Ltd.], Oil Green #502 [produced by Orient Chemical Industry Co., Ltd.], Spiron Red BEH Special [produced by Hodogaya Chemical Co., Ltd.], m-Cresol Purple, Cresol Red, Rhodamine B, Rhodamine 6G, Sulforhodamine B, Auramine, 4-p-diethyl-aminophenyliminonaphthoquinone, 2-carboxyanilino-4-p-diethylaminophenyliminonaphthoquinone, 2-carboxystearylamino-4-p-N,N-bis(hydroxyethyl)aminophenyliminonaphthoquinone, 1-phenyl-3-methyl-4-p-diethylaminophenylimino-5-pyrazolone and 1-p-naphthyl-4-p-diethylaminophenylimino-5-pyrazolone, and leuco dyes such as p,p′,p″-hexamethyl-triaminotriphenyl methane (Leuco Crystal Violet) and Pergascript Blue SRB (produced by Ciba Geigy).

Other suitable examples include leuco dyes known as a material for heat-sensitive or pressure-sensitive paper. Specific examples thereof include Crystal Violet Lactone, Malachite Green Lactone, Benzoyl Leuco Methylene Blue, 2-(N-phenyl-N-methylamino)-6-(N-p-tolyl-N-ethyl)aminofluorane, 2-anilino-3-methyl-6-(N-ethyl-p-toluidino)fluorane, 3,6-dimethoxyfluorane, 3-(N,N-diethylamino)-5-methyl-7-(N,N-dibenzylamino)fluorane, 3-(N-cyclohexyl-N-methylamino)-6-methyl-7-anilinofluorane, 3-(N,N-diethylamino)-6-methyl-7-anilinofluorane, 3-(N,N-diethylamino)-6-methyl-7-xylidinofluorane, 3-(N,N-diethylamino)-6-methyl-7-chlorofluorane, 3-(N,N-diethylamino)-6-methoxy-7-aminofluorane, 3-(N,N-diethylamino)-7-(4-chloroanilino)fluorane, 3-(N,N-diethylamino)-7-chlorofluorane, 3-(N,N-diethylamino)-7-benzylaminofluorane, 3-(N,N-diethylamino)-7,8-benzofluorane, 3-(N,N-dibutylamino)-6-methyl-7-anilinofluorane, 3-(N,N-dibutylamino)-6-methyl-7-xylidinofluorane, 3-piperidino-6-methyl-7-anilinofluorane, 3-pyrrolidino-6-methyl-7-anilinofluorane, 3,3-bis(1-ethyl-2-methylindol-3-yl)phthalide, 3,3-bis(1-n-butyl-2-methylindol-3-yl)phthalide, 3,3-bis(p-dimethylaminophenyl)-6-dimethylaminophthalide, 3-(4-diethylamino-2-ethoxyphenyl)-3-(1-ethyl-2-methylindol-3-yl)-4-phthalide and 3-(4-diethylaminophenyl)-3-(1-ethyl-2-methylindol-3-yl)phthalide.

The dye capable of discoloring by the effect of an acid or a radical is preferably added in a ratio of 0.01 to 10 mass % based on the solid content of the image recording layer.

### (4) Polymerization Inhibitor

In the image recording layer of the present invention, a small amount of a thermal polymerization inhibitor is preferably added so as to prevent unnecessary thermal polymerization of the polymerizable compound (C) during preparation or storage of the image recording layer.

Suitable examples of the thermal polymerization inhibitor include hydroquinone, p-methoxyphenol, di-tert-butyl-p-cresol, pyrogallol, tert-butyl catechol, benzoquinone, 4,4′-thiobis(3-methyl-6-tert-butylphenol), 2,2′-methylenebis(4-methyl-6-tert-butylphenol) and N-nitroso-N-phenylhydroxylamine aluminum salt.

The amount of the thermal polymerization inhibitor added is preferably from about 0.01 to about 5 mass % based on the entire solid content of the image recording layer.

### (5) Higher Fatty Acid Derivative, etc.

In the image recording layer of the present invention, for example, a higher fatty acid derivative such as behenic acid or behenic acid amide may be added and unevenly distributed to the surface of the image recording layer in the process of drying after coating so as to prevent polymerization inhibition by oxygen.

The amount of the higher fatty acid derivative added is preferably from about 0.1 to about 10 mass % based on the entire solid content of the image recording layer.

### (6) Plasticizer

The image recording layer for use in the present invention may contain a plasticizer so as to enhance the on-press developability.

Suitable examples of the plasticizer include phthalic acid esters such as dimethyl phthalate, diethyl phthalate, dibutyl phthalate, diisobutyl phthalate, diocyl phthalate, octyl capryl phthalate, dicyclohexyl phthalate, ditridecyl phthalate, butyl benzyl phthalate, diisodecyl phthalate and diallyl phthalate; glycol esters such as dimethyl glycol phthalate, ethyl phthalylethyl glycolate, methyl phthalylethyl glycolate, butyl phthalylbutyl glycolate and triethylene glycol dicaprylic acid ester; phosphoric acid esters such as tricresyl phosphate and triphenyl phosphate; aliphatic dibasic acid esters such as diisobutyl adipate, dioctyl adipate, dimethyl sebacate, dibutyl sebacate, dioctyl azelate and dibutyl maleate; polyglycidyl methacrylate, triethyl citrate, glycerin triacetyl ester and butyl laurate.

The plasticizer content is preferably about 30 mass % or less based on the entire solid content of the image recording layer.

### (7) Inorganic Fine Particle

The image recording layer for use in the present invention may contain an inorganic fine particle so as to increase the cured film strength and enhance the on-press developability.

Suitable examples of the inorganic fine particle include silica, alumina, magnesium oxide, titanium oxide, magnesium carbonate, calcium alginate and a mixture thereof. Such an inorganic fine particle can be used, for example, for strengthening the film or roughening the surface to intensify the interfacial adhesion.

The inorganic fine particle preferably has an average particle diameter of 5 nm to 10 μm, more preferably from 0.5 to 3 μm. Within this range, the inorganic particle is stably dispersed in the image recording layer and this enables maintaining sufficiently high film strength of the image recording layer and forming a non-image part with excellent hydrophilicity and less occurrence of staining at printing.

Such an inorganic fine particle is easily available on the market as a colloidal silica dispersion or the like.

The content of the inorganic fine particle is preferably 40 mass % or less, more preferably 30 mass % or less, based on the entire solid content of the image recording layer.

### (8) Hydrophilic Low-Molecular Compound

The image recording layer for use in the present invention may contain a hydrophilic low-molecular compound in addition to the betaine having a specific structure of the present invention, because the on-press developability can be enhanced without deteriorating the press life.

Examples of the hydrophilic low-molecular compound include, as the water-soluble organic compound, glycols and ether or ester derivatives thereof, such as ethylene glycol, diethylene glycol, triethylene glycol, propylene glycol, dipropylene glycol and tripropylene glycol; polyhydroxys such as glycerin, pentaerythritol and tris(2-hydroxyethyl)isocyanurate; organic amines and salts thereof, such as triethanolamine, diethanolamine and monoethanolamine; organic sulfonic acids and salts thereof, such as alkylsulfonic acid, toluenesulfonic acid and benzenesulfonic acid; organic sulfamic acids and salts thereof, such as alkylsulfamic acid; organic sulfuric acids and salts thereof, such as alkylsulfuric acid and alkyl ether sulfuric acid; organic phosphonic acids and salts thereof, such as phenylphosphonic acid; and organic carboxylic acids and salts thereof, such as tartaric acid, oxalic acid, citric acid, malic acid, lactic acid, gluconic acid and amino acids.

Among these, an organic sulfonic acid, an organic sulfamic acid, and an organic sulfate such as sodium or lithium salt of an organic sulfinuric acid, are preferred Specific examples of the organic sulfonate include sodium n-butylsulfonate, sodium isobutylsulfonate, sodium sec-butylsulfonate, sodium tert-butylsulfonate, sodium n-pentylsulfonate, sodium 1-ethylpropylsulfonate, sodium n-hexylsulfonate, sodium 1,2-dimethylpropylsulfonate, sodium 2-ethylbutylsulfonate, sodium 2-ethylhexylsulfonate, sodium cyclohexylsulfonate, sodium n-heptylsulfonate, sodium n-octylsulfonate, sodium tert-octylsulfonate, sodium n-nonylsulfonate, sodium allylsulfonate, sodium 2-methylallylsulfonate, sodium 4-[2-(2-butyloxy-ethoxy)ethoxy]butane-1-sulfonate, sodium 4-[2-(2-hexyloxy-ethoxy)ethoxy]butane-1-sulfonate, sodium 4-{2-[2-(2-ethyl)hexyloxy-ethoxy]ethoxy}butane-1-sulfonate, sodium 4-[2-(2-decyloxy-ethoxy)ethoxy]butane-1-sulfonate, sodium 4-{2-[2-(2-butyloxy-ethoxy)ethoxy]ethoxy}butane-1-sulfonate, sodium 4-[2-{2-[2-(2-ethyl)hexyloxy-ethoxy]ethoxy}ethoxy]butane-1-sulfonate, sodium benzenesulfonate, sodium p-toluenesulfonate, sodium p-hydroxybenzenesulfonate, sodium p-styrenesulfonate, sodium isophthalic acid dimethyl-5-sulfonate, disodium 1,3-benzenedisulfonate, trisodium 1,3,5-benzenetrisulfonate, sodium p-chlorobenzenesulfonate, sodium 3,4-dichlorobenzenesulfonate, sodium 1-naphthylsulfonate, sodium 2-naphthylsulfonate, sodium 4-hydroxynaphthylsulfonate, disodium 1,5-naphthalenedisulfonate, disodium 2,6-naphthalenedisulfonate, trisodium 1,3,6-naphthalenetrisulfonate, and lithium salt compounds where sodium of these compounds is exchanged with lithium.

Specific examples of the organic sulfamate include sodium n-butylsulfamate, sodium isobutylsulfamate, sodium tert-butylsulfamate, sodium n-pentylsulfamate, sodium 1-ethylpropylsulfamate, sodium n-hexylsulfamate, sodium 1,2-dimethylpropylsulfamate, sodium 2-ethylbutylsulfamate, sodium cyclohexylsulfamate, and lithium salt compounds where sodium of these compounds is exchanged with lithium.

Such a compound has almost no surface activity action because of the hydrophobic moiety having a small structure and can be clearly distinguished from the above-described surfactant that allows good use of a long-chain alkylsulfonate, a long-chain alkylbenzenesulfonate or the like.

The organic sulfate which is particularly preferred is a compound represented by the following formula (3):

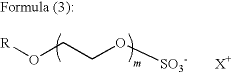

In formula (3), R represents an alkyl group, an alkenyl group, an alkynyl group, an aryl group or a heterocyclic group, m represents an integer of 1 to 4, and X represents sodium, potassium or lithium.

R is preferably a linear, branched or cyclic alkyl group having a carbon number of 1 to 12, an alkenyl group having a carbon number of 1 to 12, an alkynyl group having a carbon number of 1 to 12, or an aryl group having a carbon number of 20 or less. These groups each may further has a substituent and in this case, examples of the substituent which can be introduced include a linear, branched or cyclic alkyl group having a carbon number of 1 to 12, an alkenyl group having a carbon number of 1 to 12, an alkynyl group having a carbon number of 1 to 12, a halogen atom, and an aryl group having a carbon number of 20 or less.

Preferred examples of the compound represented by formula (3) include sodium oxyethylene-2-ethylhexyl ether sulfate, sodium dioxyethylene-2-ethylhexyl ether sulfate, potassium dioxyethylene-2-ethylhexyl ether sulfate, lithium dioxyethylene-2-ethylhexyl ether sulfate, sodium trioxyethylene-2-ethylhexyl ether sulfate, sodium tetraoxyethylene-2-ethylhexyl ether sulfate, sodium dioxyethylene-hexyl ether sulfate, sodium dioxyethylene-octyl ether sulfate, and sodium dioxyethylene-lauryl ether sulfate. Among these, sodium dioxyethylene-2-ethylhexyl ether sulfate, potassium dioxyethylene-2-ethylhexyl ether sulfate and lithium dioxyethylene-2-ethylhexyl ether sulfate are most preferred.

The amount of the hydrophilic low-molecular compound added to the image recording layer is preferably from 0.5 to 20 mass %, more preferably from 1 to 10 mass %, still more preferably from 2 to 8 mass %, based on the entire solid content of the image recording layer. Within this range, good on-press developability and good press life are obtained.

One of these compounds may be used alone, or two or more kinds thereof may be mixed and used.

### (9) Ink Receptivity Agent

In the case of incorporating an inorganic layered compound into the protective layer described later, an ink receptivity agent such as phosphonium compound, nitrogen-containing low-molecular compound or ammonium group-containing polymer may be used in the image recording layer for enhancing the inking property. Also, different kinds of ink receptivity agents may be used in combination.

Such a compound functions as a surface coating (ink receptivity agent) of the inorganic layered compound and prevents the inking property from being reduced during printing due to the inorganic layered compound.

Suitable phosphonium compounds include the compounds represented by the following formula (4) described in JP-A-2006-297907 and represented by the following formula (5) described in JP-A-2007-50660.

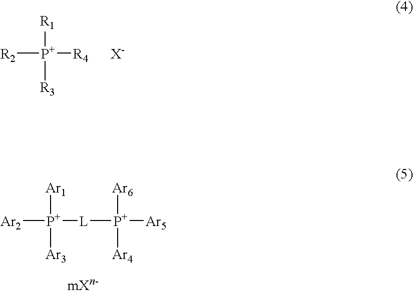

In formula (4), R₁ to R₄ each independently represents an alkyl group, an alkenyl group, an alkynyl group, a cycloalkyl group, an alkoxy group, an aryl group, an aryloxy group, an alkylthio group, a heterocyclic group, each of which may have a substituent, or a hydrogen atom, at least two members out of R₁ to R₄ may combine to form a ring, and X⁻ represents a counter anion.

In formula (5), Ar₁ to Ar₆ each independently represents an aryl group or a heterocyclic group, L represents a divalent linking group, Xⁿ⁻ represents a n-valent counter anion, n represents an integer of 1 to 3, and m represents a number satisfying n×m=2. Suitable examples of the aryl group include a phenyl group, a naphthyl group, a tolyl group, a xylyl group, a fluorophenyl group, a chlorophenyl group, a bromophenyl group, a methoxyphenyl group, an ethoxyphenyl group, a dimethoxyphenyl group, a methoxycarbonylphenyl group and a dimethylaminophenyl group. Examples of the heterocyclic group include a pyridyl group, a quinolyl group, a pyrimidinyl group, a thienyl group and a furyl group. L represents a divalent linking group, and the number of carbon atoms in the linking group is preferably from 6 to 15, more preferably from 6 to 12. Xⁿ⁻ represents a n-valent counter anion, and preferred examples thereof include a halogen anion such as Cl⁻, Br⁻ and I⁻, a sulfonate anion, a carboxylate anion, a sulfuric acid ester anion, PF₆⁻, BF₄⁻, a perchlorate anion, a sulfate anion and a phosphate anion. Among these, a halogen anion such as Cl⁻, Br⁻ and I⁻, a sulfonate anion and a carboxylate anion are preferred.

Specific examples of the phosphonium compound represented by formula (4) or (5) are set forth below.

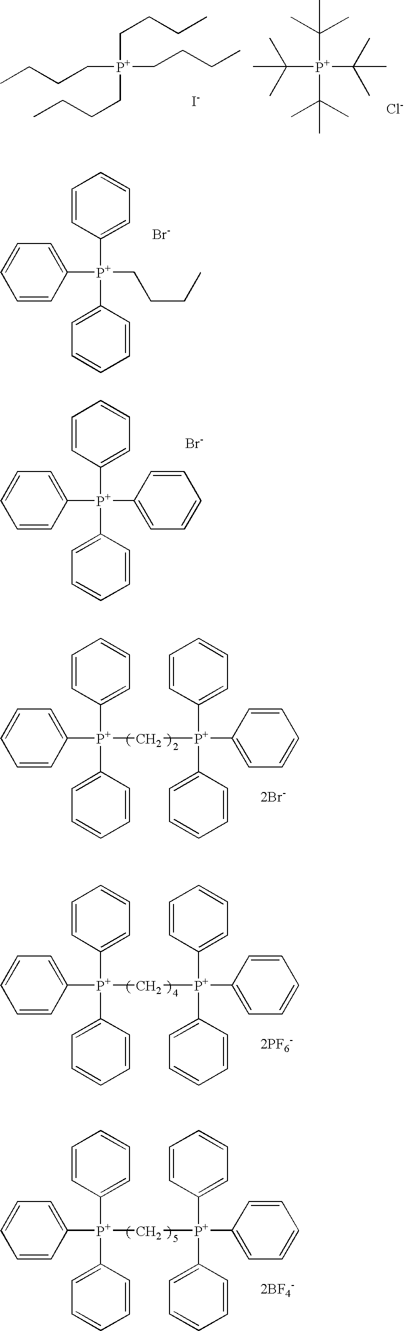

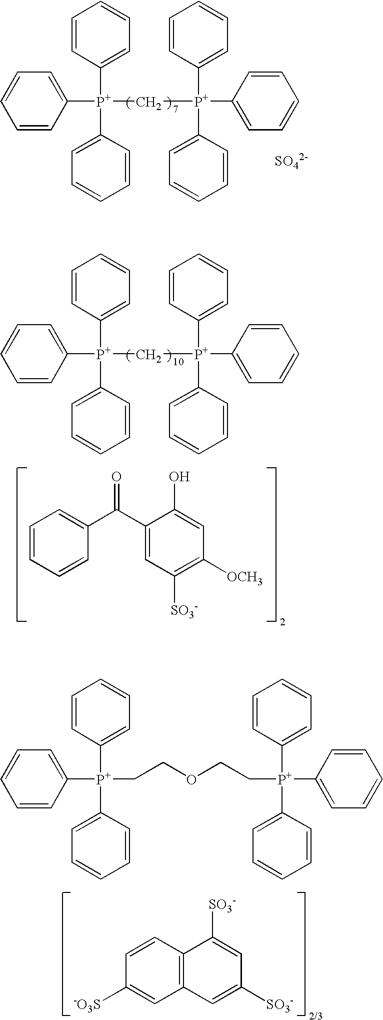

Other than the phosphonium compound, suitable examples of the ink receptivity agent for use in the present invention include the following nitrogen-containing low-molecular compound. The nitrogen-containing low-molecular compound is preferably a compound having a structure of the following formula (6).

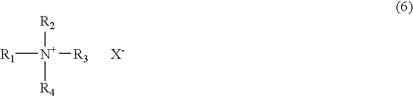

In the formula, R₁ to R₄ each independently represents a substituted or unsubstituted alkyl group, a substituted or unsubstituted alkenyl group, a substituted or unsubstituted alkynyl group, a substituted or unsubstituted cycloalkyl group, a substituted or unsubstituted alkoxy group, a substituted or unsubstituted aryl group, a substituted or unsubstituted aralkyl group, a substituted or unsubstituted heterocyclic group, or a hydrogen atom. At least two members out of R₁ to R₄ may combine to form a ring. X⁻ is an anion and represents PF₆⁻, BF₄⁻ or an organic sulfonate anion having a substituent selected from an alkyl group, an alkenyl group, an alkynyl group, a cycloalkyl group, an alkoxy group, an aryl group, an aralkyl group and a heterocyclic group.

That is, the nitrogen-containing low-molecular compound for use in the present invention includes amine salts where at least one of R₁ to R₄ is a hydrogen atom, and quaternary ammonium salts where all of R₁ to R₄ are not a hydrogen atom. The compound may have a structure of imidazolinium salts represented by the following formula (7), benzimidazolinium salts represented by the following formula (8), pyridinium salts represented by the following formulas (9), or quinolinium salts represented by the following formula (10).

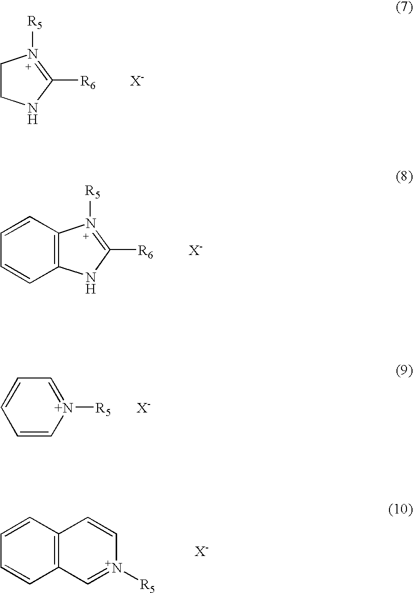

In the formulae, R₅ and R₆ each represents a substituted or unsubstituted alkyl group, a substituted or unsubstituted alkenyl group, a substituted or unsubstituted alkynyl group, a substituted or unsubstituted a cycloalkyl group, a substituted or unsubstituted alkoxy group, a substituted or unsubstituted aryl group, a substituted or unsubstituted aralkyl group, a substituted or unsubstituted heterocyclic group or a hydrogen atom, and X⁻ is an anion and has the same meaning as X⁻ in formula (6).

Among these, quaternary ammonium salts and pyridinium salts are preferred. Specific examples thereof are set forth below.

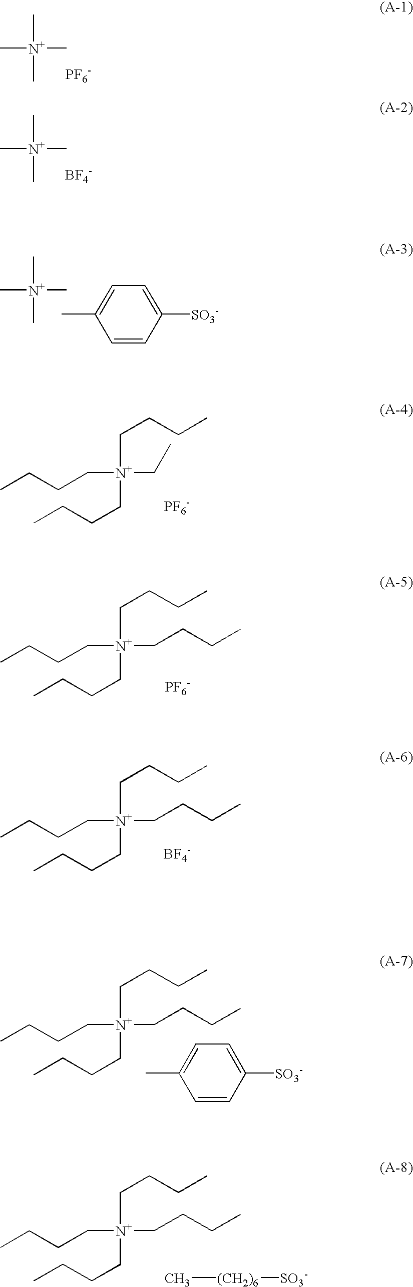

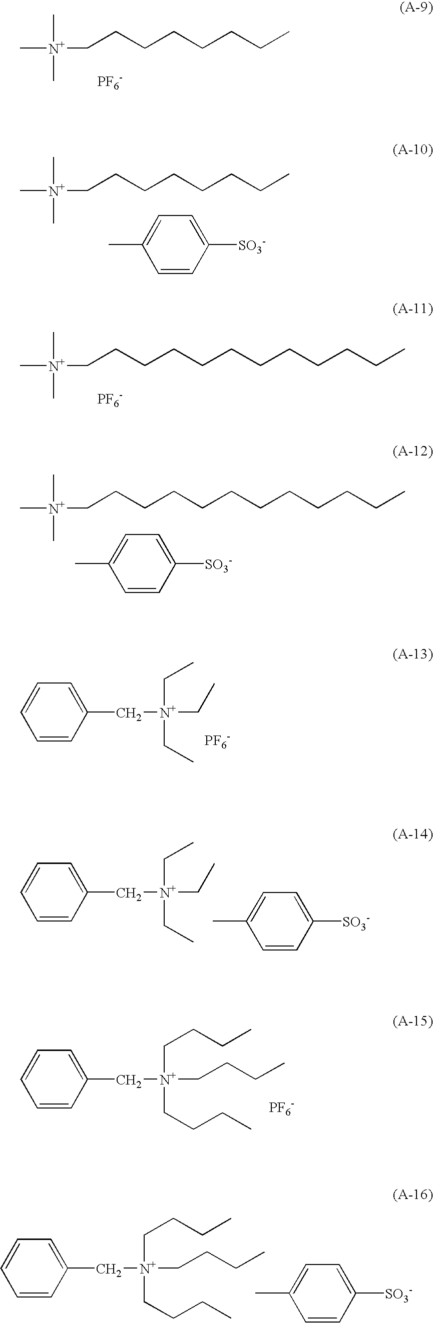

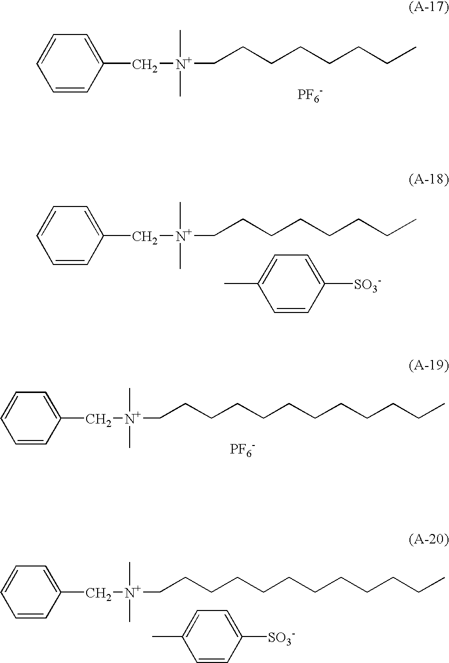

The amount of the phosphonium compound or nitrogen-containing low-molecular compound added to the image recording layer is preferably from 0.01 to 20 mass %, more preferably from 0.05 to 10 mass %, and most preferably from 0.1 to 5 mass %, based on the solid content of the image recording layer. Within this range, good inking property during printing is obtained.

As regards the ink receptivity agent for use in the present invention, the following ammonium group-containing polymer is also suitable. The ammonium group-containing polymer may be any polymer as long as it has an ammonium group in its structure, but a polymer containing structures of the following formulae (11) and (12) as the repeating unit is preferred.

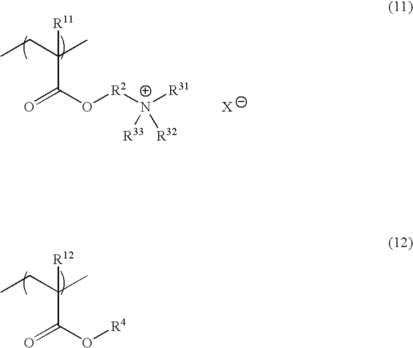

(wherein R¹¹ and R¹² each independently represents a hydrogen atom or a methyl group; R² represents a divalent linking group such as alkylene group which may have a substituent or alkyleneoxy group which may have a substituent; R³¹, R³² and R³³ each independently represents an alkyl group having a carbon number of 1 to 10 or an aralkyl group; X⁻ represents an organic or inorganic anion such as F⁻, Cl⁻, Br⁻, I⁻, benzenesulfonate anion which may have a substituent, methylsulfate anion, ethylsulfate anion, propylsulfate anion, butylsulfate anion which may be branched, amylsulfate anion which may be branched, PF₆⁻, BF₄⁻ or B(C₆F₅)₄⁻; R⁴ represents an alkyl group having a carbon number of 1 to 21, an aralkyl group, an aryl group, —(C₂H₄O)ₙ—R⁵ or (C₃H₆O)ₙ—R⁵; R⁵ represents a hydrogen atom, a methyl group or an ethyl group; and n represents 1 or 2).

The ammonium salt-containing polymer contains at least one structural unit represented by formula (11) and at least one structural unit represented by formula (12), and two or more kinds of structures may be contained for either one structural unit or two or more kinds of structures may be contained for both structural units. The ratio between two structural units is not limited but is preferably from 5:95 to 80:20. Also, this polymer may contain other copolymerization components within the range ensuring the effects of the present invention.

The viscosity of the ammonium salt-containing polymer is, in terms of the value of reduced specific viscosity (unit: cSt/g/ml) determined by the following measuring method, preferably from 5 to 120, more preferably from 10 to 110, still more preferably from 15 to 100.

### <Measuring Method of Reduced Specific Viscosity>

A 30 mass % polymer solution (3.33 g (1 g as a solid)) is weighed in a 20 ml-volume measuring flask and diluted with N-methylpyrrolidone. This solution is charged into a Ubbelohde reduced viscosity tube (viscosimeter constant=0.010 cSt/s) and after measuring the time for which the solution flows down at 30° C., the reduced specific viscosity is calculated in accordance with a fixed rule (“kinetic viscosity”=“viscosimeter constant”×“time (sec) for which liquid flows through capillary”).

The content of the ammonium salt-containing polymer is preferably from 0.0005 to 30.0 mass %, more preferably from 0.001 to 20.0 mass %, and most preferably from 0.002 to 15.0 mass %, based on the entire solid content of the image recording layer. Within this range, good inking property is obtained.

Specific examples of the ammonium salt-containing polymer are set forth below.

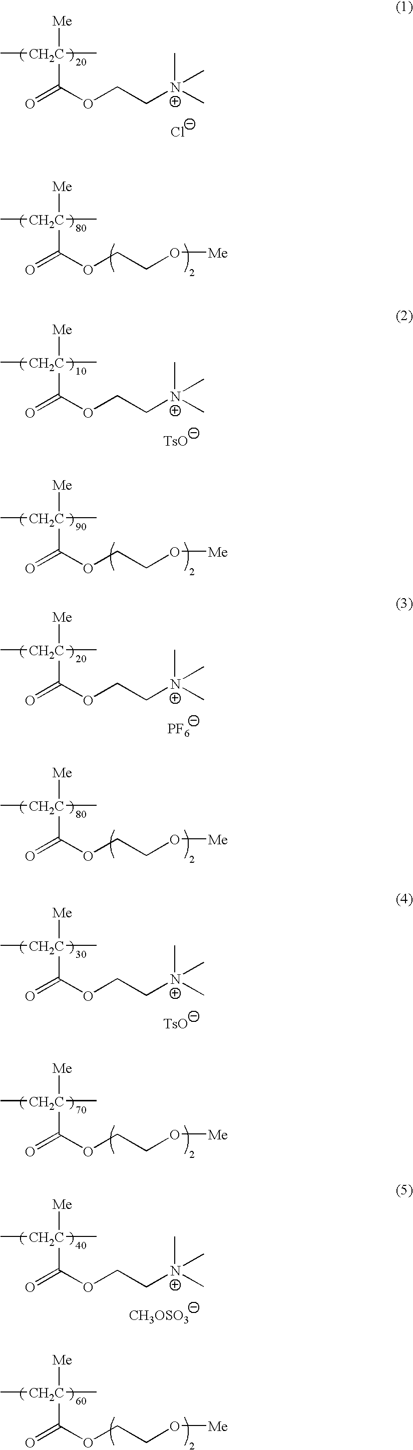

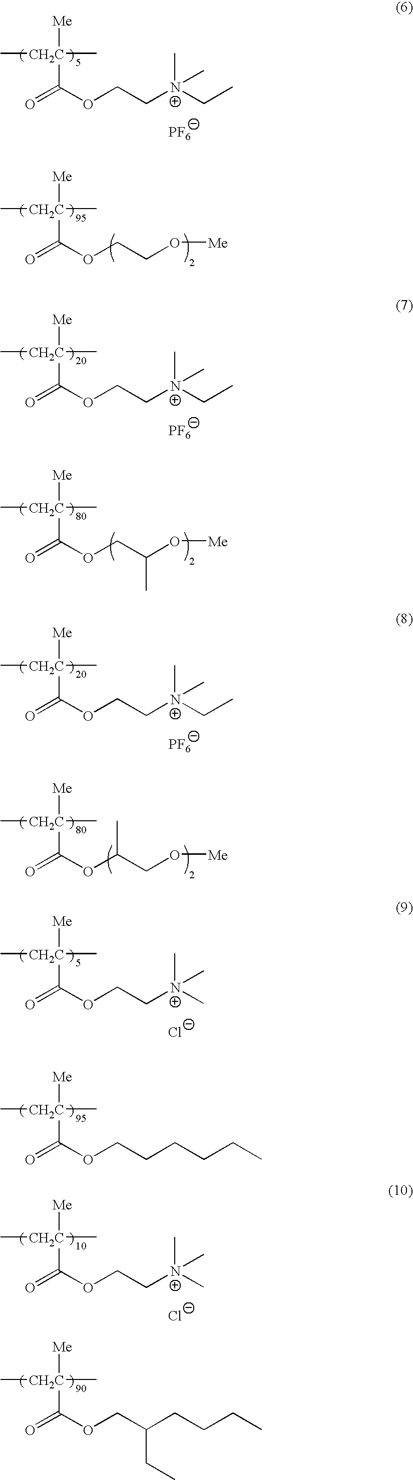

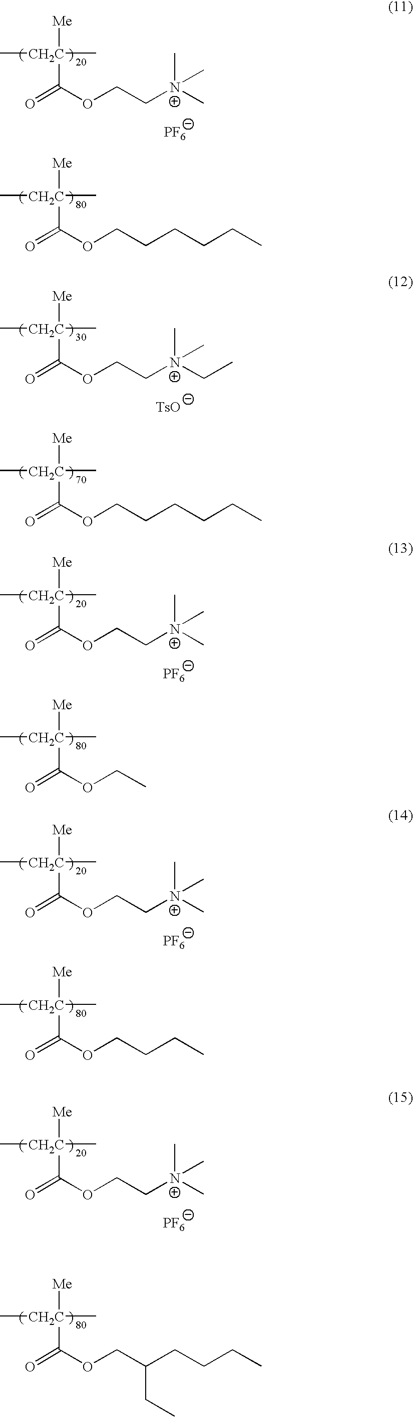

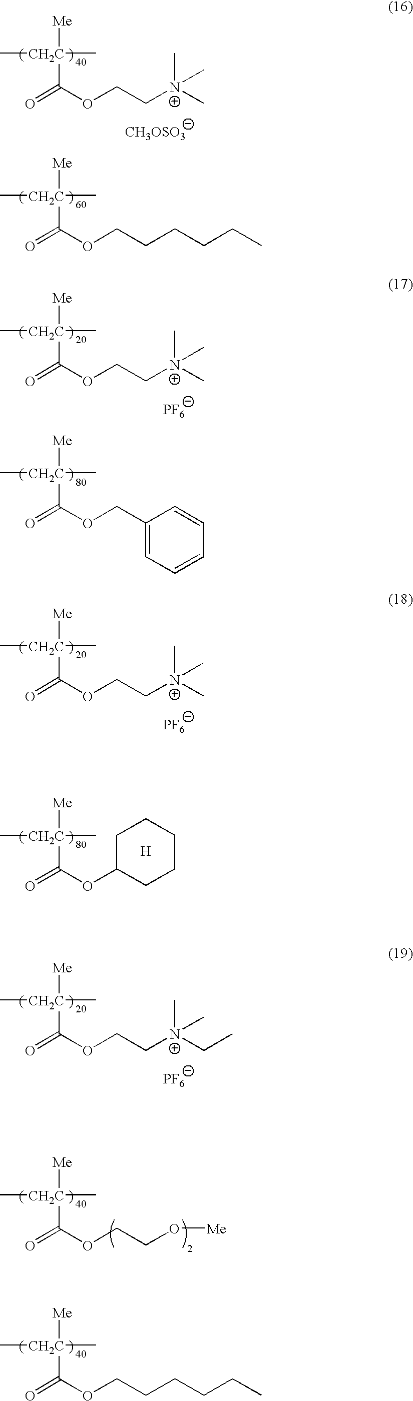

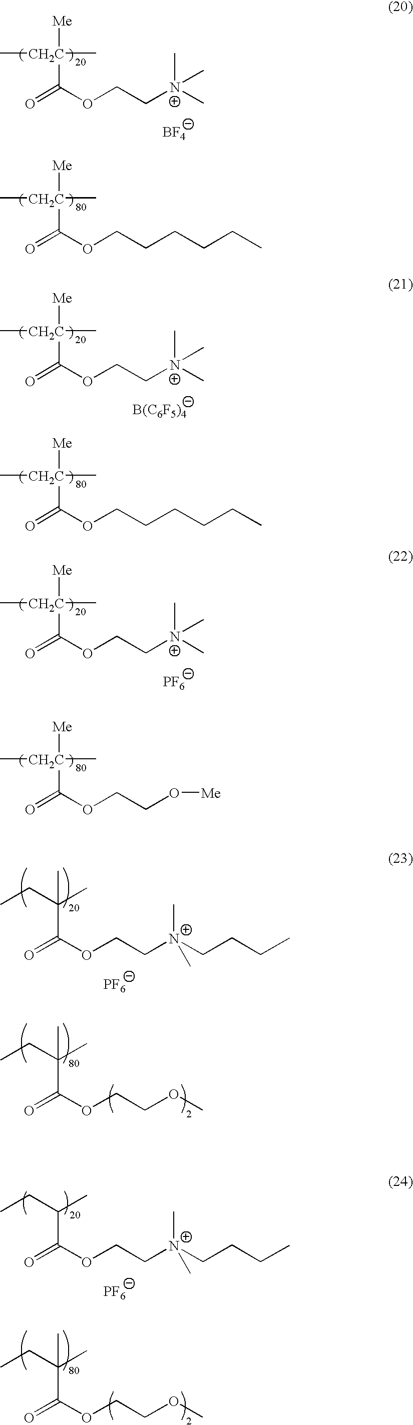

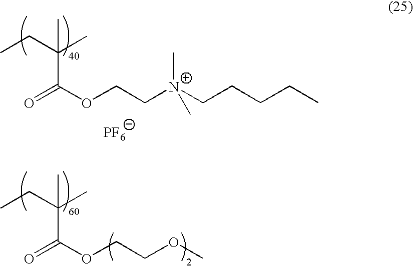

### (10) Betaine Compound

The image recording layer for use in the present invention may contain a betaine compound represented by the following formula (13) or (14):

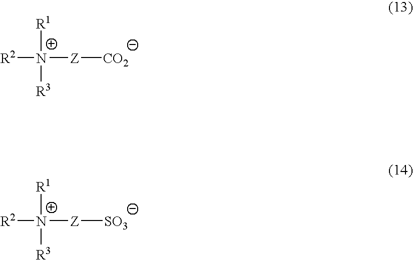

R¹ to R³ each independently represents an alkyl group having a carbon number of 1 to 5, an alkenyl group, an alkynyl group, a cycloalkyl group or an aryl group and may be substituted by a hydroxyl group or an amino group. Z represents an alkylene group having a carbon number of 1 to 4 and may be substituted by a hydroxyl group. At least two members out of R¹ to R³ and Z may combine to form a heterocyclic ring.

By virtue of containing such a compound in the image recording layer, the on-press developability can be enhanced without deteriorating the press life. Above all, a compound where R¹ to R³ each is an alkyl group having a carbon number of 1 to 3 or two members out of R¹ to R³ and Z combine to form a 5- or 6-membered heterocyclic ring is preferred, and a compound having a quaternary ammonium skeleton where R¹ to R³ are a methyl group or an ethyl group, or having a pyrrolidine, piperidine, pyridine or imidazoline skeleton where two members out of R¹ to R³ and Z combine to form a ring, is more preferred.

Specific examples of the compound of formula (13) are illustrated below, but the present invention is not limited thereto.

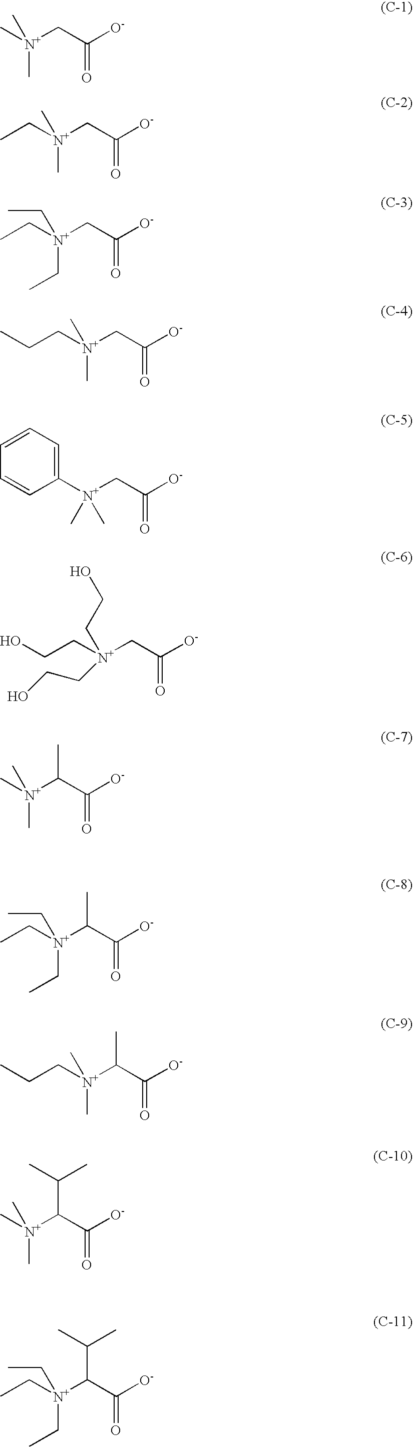

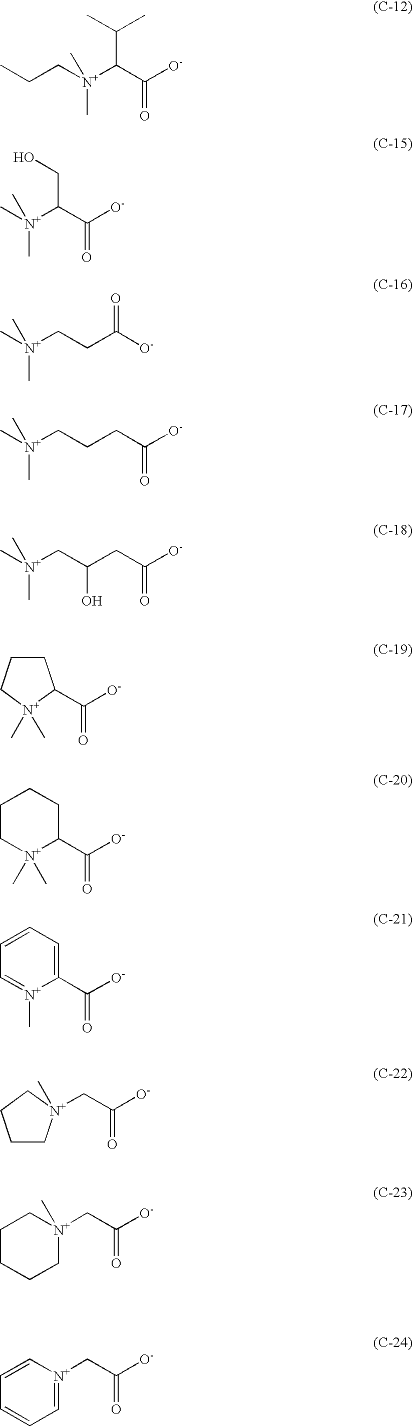

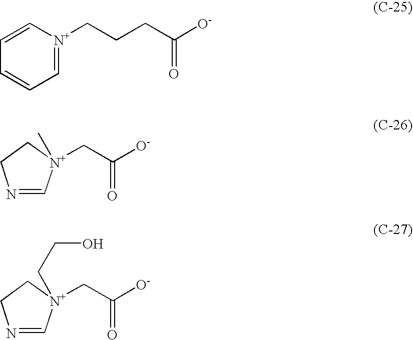

Specific examples of the compound of formula (14) are illustrated below, but the present invention is not limited thereto.

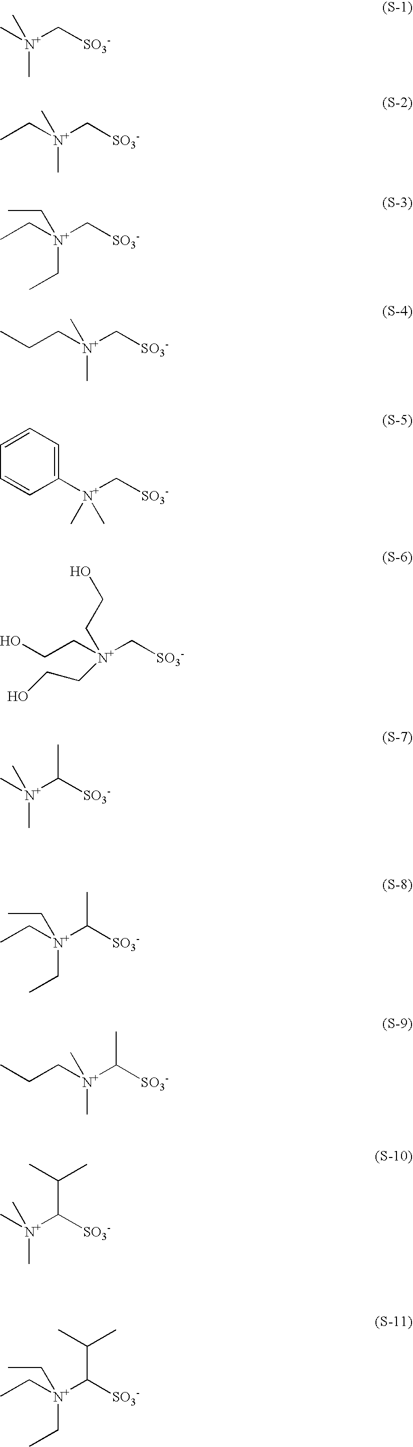

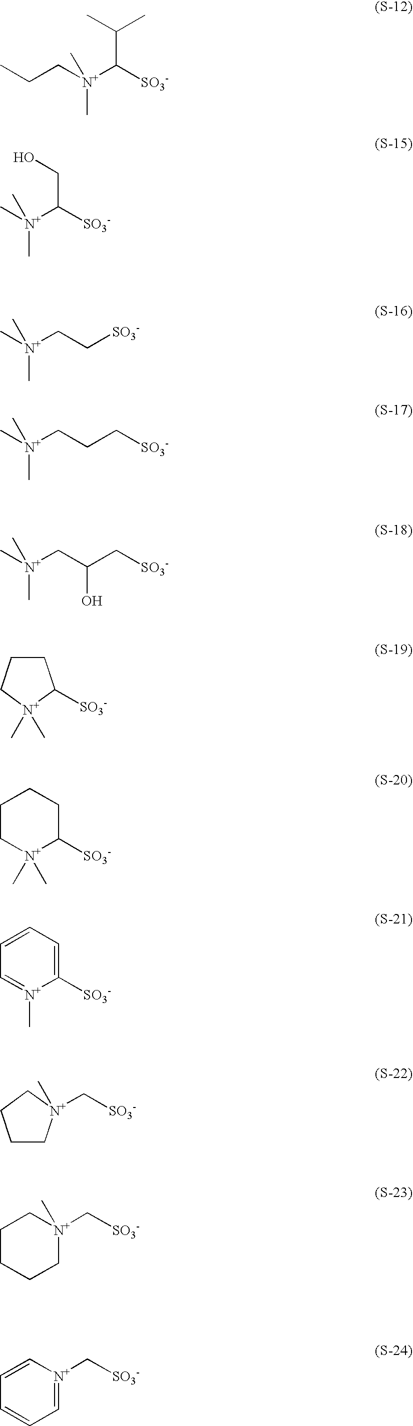

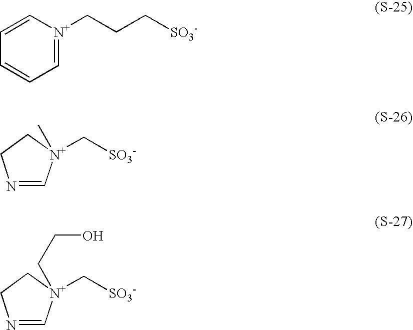

Such a compound has almost no surface activity action because of the hydrophobic moiety having a small structure and therefore, does not allow a fountain solution to penetrate into the exposed area (image part) of the image recording layer and reduce the hydrophobicity or film strength of the image part, so that ink receptivity of the image recording layer or press life can be successfully maintained.

The amount of the compound represented by formula (13) or (14) added to the image recording layer is preferably from 0.1 to 10 mass %, more preferably from 0.2 to 5 mass %, still more preferably from 0.4 to 2 mass %. Within this range, good on-press developability and good press life can be obtained.

One of these compounds may be used alone, or two ore more kinds thereof may be mixed and used.

### <Formation of Image Recording Layer>

The image recording layer of the present invention is formed by dispersing or dissolving the above-described necessary components in a solvent to prepare a coating solution, applying the coating solution on a support, and drying the coating.

Examples of the solvent used here include, but are not limited to, ethylene dichloride, cyclohexanone, methyl ethyl ketone, methanol, ethanol, propanol, ethylene glycol monomethyl ether, 1-methoxy-2-propanol, 2-methoxyethyl acetate, 1-methoxy-2-propyl acetate, dimethoxyethane, methyl lactate, ethyl lactate, N,N-dimethylacetamide, N,N-dimethylformamide, tetramethylurea, N-methylpyrrolidone, dimethylsulfoxide, sulfolane, γ-butyl lactone, toluene and water. One of these solvents may be used alone, or several kinds thereof are mixed and used. The solid content concentration of the coating solution is preferably from 1 to 50 mass %.

The image recording layer for use in the present invention may also be formed as an image recording layer having a multilayer structure by dispersing or dissolving the same or different components described above in the same or different solvents to prepare a plurality of coating solutions and repeating the coating and drying a plurality of times.

The coated amount (solid content) of the image recording layer obtained on the support after coating and drying varies depending on the use but, in general, is preferably from 0.3 to 3.0 g/m². Within this range, good sensitivity and good film properties of the image recording layer can be obtained.

For the coating, various methods may be used and examples thereof include bar coater coating, rotary coating, spray coating, curtain coating, dip coating, air knife coating, blade coating and roll coating.

### [Undercoat Layer]

In the lithographic printing plate precursor, an undercoat layer (sometimes called an “intermediate layer”) is provided, if desired, between the image recording layer and the support. By virtue of the undercoat layer, the image recording layer in the unexposed part becomes easy to separate from the support and therefore, the developability is enhanced. Also, in the case of infrared laser exposure, the undercoat layer functions as a heat insulating layer and heat generated upon exposure is not allowed to diffuse into the support but is efficiently utilized, so that high sensitivity can be advantageously achieved. The components and the like for use in the undercoat layer of the present invention are descried below.

Specific suitable examples of the compound for the undercoat layer include a silane coupling agent having an addition-polymerizable ethylenic double bond reactive group described in JP-A-10-282679, and a phosphorus compound having an ethylenic double bond reactive group described in JP-A-2-304441.

A most preferred compound for the undercoat layer includes a polymer resin having an adsorptive group, a hydrophilic group and a crosslinking group. This polymer resin is preferably obtained by copolymerizing a monomer having an adsorptive group, a monomer having a hydrophilic group, and a monomer having a crosslinking group

The polymer resin for undercoat layer preferably has an adsorptive group to the hydrophilic support surface. The presence or absence of adsorptivity to the hydrophilic support surface can be judged, for example, by the following method.

A test compound is dissolved in a solvent capable of easily dissolving the compound to prepare a coating solution, and the coating solution is coated and dried on a support such that the coated amount after drying becomes 30 mg/m². Thereafter, the support coated with the test compound is thoroughly washed with a solvent capable of easily dissolving the compound and after measuring the residual amount of the test compound that is not removed by washing, the amount adsorbed to the support is calculated. Here, in the measurement of the residual amount, the amount of the residual compound may be directly determined or the residual amount may be calculated after quantitatively determining the test compound dissolved in the washing solution. The quantitative determination of the compound may be performed, for example, by fluorescent X-ray measurement, reflection spectral absorbance measurement or liquid chromatography measurement. The compound having adsorptivity to the support is a compound which remains in an amount of 1 mg/m² or more even when the above-described washing treatment is performed.

The adsorptive group to the hydrophilic support surface is a functional group capable of causing chemical bonding (for example, ionic bonding, hydrogen bonding, coordination bonding, or bonding by intermolecular force) with a substance (e.g., metal, metal oxide) or a functional group (e.g., hydroxy group), which is present on the hydrophilic support surface. The adsorptive group is preferably an acid group or a cationic group.

The acid group preferably has an acid dissociation constant (pKa) of 7 or less. Examples of the acid group include a phenolic hydroxyl group, a carboxyl group, —SO₃H, —OSO₃H, —PO₃H₂, —OPO₃H₂, —CONHSO₂—, —SO₂NHSO₂ and —COCH₂COCH₃. Among these, —OPO₃H₂ and PO₃H₂ are preferred. Also, these acid groups may be in the form of a metal salt.

The cationic group is preferably an onium group. Examples of the onium group include an ammonium group, a phosphonium group, an arsonium group, a stibonium group, an oxonium group, a sulfonium group, a selenonium group, a stannonium group and an iodonium group. Among these, an ammonium group, a phosphonium group and a sulfonium group are preferred, an ammonium group and a phosphonium group are more preferred, and an ammonium group is most preferred.

Particularly preferred examples of the monomer having an adsorptive group, which is used in the synthesis of a polymer resin suitable as the compound for the undercoat layer, include compounds represented by the following formulae (U1) and (U2).

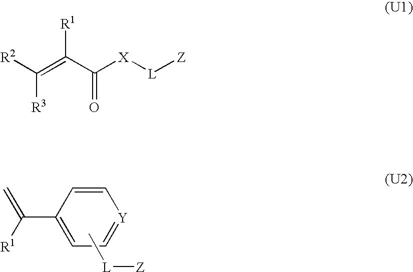

In formulae (U1) and (U2), R¹, R² and R³ each independently represents a hydrogen atom, a halogen atom or an alkyl group having a carbon number of 1 to 6.

R¹, R² and R³ each is independently preferably a hydrogen atom or an alkyl group having a carbon number of 1 to 6, more preferably a hydrogen atom or an alkyl group having a carbon number of 1 to 3, and most preferably a hydrogen atom or a methyl group. In particular, R² and R³ each is preferably a hydrogen atom.

Z is a functional group adsorbing to the surface of the hydrophilic support, and the adsorptive functional group is as described above.

In formulae (U1) and (U2), L represents a single bond or a divalent linking group.

L is preferably a divalent aliphatic group (e.g., alkylene, substituted alkylene, alkenylene, substituted alkenylene, alkynylene, substituted alkynylene), a divalent aromatic group (e.g., arylene, substituted arylene), a divalent heterocyclic group, or a combination of such a group with an oxygen atom (—O—), a sulfur atom (—S—), an imino (—NH—), a substituted imino (—NR—, wherein R is an aliphatic group, an aromatic group or a heterocyclic group) or a carbonyl (—CO—).

The divalent aliphatic group may have a cyclic structure or a branched structure. The number of carbon atoms in the divalent aliphatic group is preferably from 1 to 20, more preferably from 1 to 15, and most preferably from 1 to 10. Also, the divalent aliphatic group is preferably a saturated aliphatic group rather than an unsaturated aliphatic group. The divalent aliphatic group may have a substituent, and examples of the substituent include a halogen atom, a hydroxy group, an aromatic group and a heterocyclic group.

The number of carbon atoms in the divalent aromatic group is preferably from 6 to 20, more preferably from 6 to 15, and most preferably from 6 to 10. The divalent aromatic group may have a substituent, and examples of the substituent include a halogen atom, a hydroxy group, an aromatic group and a heterocyclic group.

The divalent heterocyclic group preferably contains a 5-membered or 6-membered ring as the heterocyclic ring. Also, another heterocyclic ring, an aliphatic ring or an aromatic ring may be condensed to the heterocyclic ring. The divalent heterocyclic group may have a substituent. Examples of the substituent include a halogen atom, a hydroxy group, an oxo group (═O), a thioxo group (═S), an imino group (═NH), a substituted imino group (═N—R, wherein R is an aliphatic group, an aromatic group or a heterocyclic group), an aliphatic group, an aromatic group and a heterocyclic group.

In the present invention, L is preferably a divalent linking group containing a plurality of polyoxyalkylene structures. The polyoxyalkylene structure is preferably a polyoxyethylene structure. In other words, L preferably contains —(OCH₂CH₂)ₙ— (wherein n is an integer of 2 or more).

In Formula (U1), X represents an oxygen atom (—O—) or an imino group (—NH—). X is preferably an oxygen atom.

In Formula (U2), Y represents a carbon atom or a nitrogen atom. When Y is a nitrogen atom and L is bound on Y to form a quaternary pyridinium group, the quaternary pyridinium group itself is adsorptive. In this case, the functional group of Z is not essential, and Z may be a hydrogen atom.

Representative examples of the compounds of formulae (U1) and (U2) are set forth below.

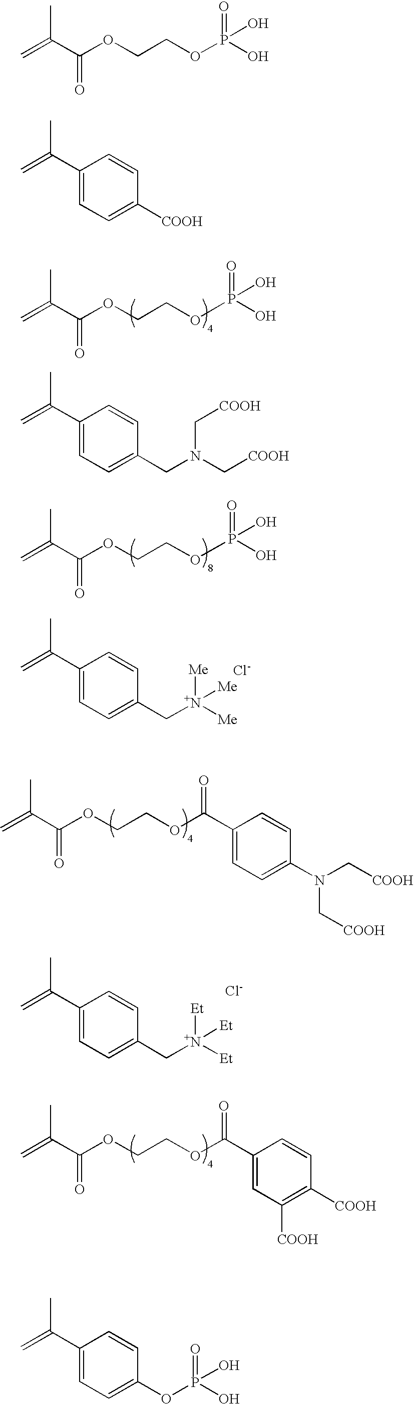

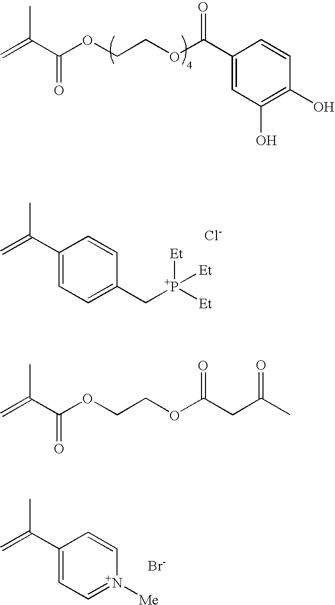

The polymer resin suitable as the compound for the undercoat layer preferably has a hydrophilic group. Suitable examples of the hydrophilic group include a hydroxy group, a carboxyl group, a carboxylate group, a hydroxyethyl group, a polyoxyethyl group, a hydroxypropyl group, a polyoxypropyl group, an amino group, an aminoethyl group, an aminopropyl group, an ammonium group, an amido group, a carboxymethyl group, a sulfo group and a phosphoric acid group. Among these, a sulfo group exhibiting high hydrophilicity is preferred.

Specific examples of the monomer having a sulfo group include sodium salts and amine salts of methallyloxybenzenesulfonic acid, allyloxybenzenesulfonic acid, allylsulforic acid, vinylsulfonic acid, p-styrenesulfonic acid, methallylsulfonic acid, acrylamide tert-butylsulfonic acid, 2-acrylamido-2-methylpropanesulfonic acid and (3-acryloyloxypropyl)butylsulfonic acid. Among them, sodium 2-acrylamido-2-methylpropanesulfonate is preferred in view of hydrophilic performance and handling of synthesis.

Such a monomer is appropriately used in synthesizing a polymer resin suitable as the compound for the undercoat layer.

The polymer resin for the undercoat layer used in the present invention preferably has a crosslinking group. By virtue of the crosslinking group, adherence to the image part is enhanced. In order to impart crosslinking property to the polymer resin for the undercoat layer, this may be attained by introducing a crosslinking functional group such as ethylenically unsaturated bond into the side chain of the polymer, or by forming a salt structure with a compound containing an ethylenically unsaturated bond and a substituent having an opposite charge to the charge of the polar substituent on the polymer resin.

Examples of the polymer having an ethylenically unsaturated bond in the side chain of the molecule include a polymer which is a polymer of acrylic or methacrylic acid ester or amide and in which the ester or amide residue (R in —COOR or CONHR) has an ethylenically unsaturated bond.

Examples of the residue (R above) having an ethylenically unsaturated bond include —(CH₂)ₙCR^{1═CR}²R³, —(CH₂O)ₙCH₂CR¹═CR²R³, —(CH₂CH₂O)ₙCH₂CR¹═CR²R³, —(CH₂)ₙNH—CO—O—CH₂CR¹═CR²R³, —(CH₂)ₙ—O—CO—CR¹═CR²R³ and (CH₂CH₂O)₂—X (wherein R¹ to R³ each represents a hydrogen atom, a halogen atom or an alkyl, aryl, alkoxy or aryloxy group having a carbon number of 1 to 20, R¹ and R² or R³ may combine together to form a ring, n represents an integer of 1 to 10, and X represents a dicyclopentadienyl residue).

Specific examples of the ester residue include —CH₂CH═CH₂ (described in JP-B-7-21633), —CH₂CH₂O—CH₂CH═CH₂, —CH₂C(CH₃)═CH₂, —CH₂CH═CH—C₆H₅, —CH₂CH₂OCOCH═CH—C₆H₅, —CH₂CH₂—NHCOO—CH₂CH═CH₂ and CH₂CH₂O—X (wherein X represents a dicyclopentadienyl residue).

Specific examples of the amide residue include —CH₂CH═CH₂, —CH₂CH₂O—Y (wherein Y represents a cyclohexene residue) and —CH₂CH₂OCO—CH═CH₂.

The monomer having a crosslinking group of the polymer resin for the undercoat layer is preferably the above-described acrylic or methacrylic acid ester or amide having a crosslinking group.

The content of the crosslinking group (content of radical-polymerizable unsaturated double bond determined by iodine titration) in the polymer resin for the undercoat layer is preferably from 0.1 to 10.0 mmol, more preferably from 1.0 to 7.0 mmol, and most preferably from 2.0 to 5.5 mmol, per g of the polymer resin. Within this range, both good sensitivity and good scumming resistance can be established, and good storage stability can be obtained.

The mass average molar mass of the polymer resin for the undercoat layer is preferably 5,000 or more, more preferably from 10,000 to 300,000, and the number average molar mass is preferably 1,000 or more, more preferably from 2,000 to 250,000. The polydispersity (mass average molar mass/number average molar mass) is preferably from 1.1 to 10.

The polymer resin for the undercoat layer may be any polymer such as random polymer, block polymer or graft polymer, but is preferably a random polymer.

One of polymer resins for undercoating may be used alone, or two or more kinds thereof may be mixed and used.

For preventing staining with aging as a stock plate, the undercoat layer for use in the present invention may contain a secondary or tertiary amine or a polymerization inhibitor. Examples of the secondary or tertiary amine include imidazole, 4-dimethylaminopyridine, 4-dimethylaminobenzaldehyde, tris(2-hydroxy-1-methyl)amine, 1,4-diazabicyclo[2,2,2]octane (DABCO), 1,5,7-triazabicyclo[4,4,0]dec-5-ene, 1,8-diazabicyclo[5,4,0]undec-7-ene, 1,10-phenanthroline, 1,8-bis(dimethylamino)naphthalene, 4,4′-bis(dimethylamino)biphenyl, diphenylamine, 1,3-diphenylguanidine, 4-phenylpyridine and N,N′-ethylenebis(2,2,5,5-tetramethylpyrrolidine).

The polymerization inhibitor includes known thermal polymerization inhibitors. Above all, the polymerization inhibitor is preferably a compound selected from the group consisting of phenol-based hydroxy group-containing compounds, quinone compounds, N-oxide compounds, piperidine-1-oxyl free radical compounds, pyrrolidine-1-oxyl free radical compounds, N-nitrosophenylhydroxylamines, diazonium compounds, cationic dyes, sulfide group-containing compounds, nitro group-containing compounds, and transition metal compounds such as FeCl₃ and CuCl₂. Among these compounds, quinone compounds are preferred. Specific examples of the quinone compounds include 1,4-benzoquinone, 2,3,5,6-tetrahydroxy-1,4-benzoquinone, 2,5-dihydroxy-1,4-benzoquinone, chloranil, 2,3-dichloro-5,6-dicyano-1,4-benzoquinone, naphthoquinone, 2-fluoro-1,4-naphthoquinone, 2-hydroxyethyl-1,4-naphthoquinone, anthraquinone, 1,2,4-trihydroxyanthraquinone and 2,6-dihydroxyanthraquinone.

The amount of such a compound added to the undercoat layer is preferably from 10 to 90 mass %, more preferably from 20 tO 80 mass %, and most preferably from 30 to 70 mass %, based on the constituent components of the undercoat layer.

A compound containing an amino group or a functional group having polymerization inhibiting ability and a group interacting with the aluminum support surface may also be used as the compound effective for prevention of staining. Examples of the group interacting with the aluminum support surface include a trialkoxysilyl group, an onium salt, and an acid group selected from a phenolic hydroxyl group, a carboxyl group, —SO₃H, —OSO₃H, —PO₃H₂, —OPO₃H₂, —CONHSO₂, —SO₂NHSO₂— and COCH₂CO—, or a metal salt thereof.

Examples of the compound containing an amino group and a group interacting with the aluminum support surface include a salt of 1,4-diazabicyclo[2,2,2]octane with an acid, a compound having at least one 4-aza-1-azoniabicyclo[2,2,2]octane structure (for example, 1-methyl-4-aza-1-azoniabicylco[2,2,2]octane=p-toluenesulfonate), an ethylenediaminetetraacetic acid, a hydroxyethylethylenediaminetriacetic acid, a dihydroxyethylethylenediaminediacetic acid, a 1,3-propanediaminetetraacetic acid, a diethylenetriaminepentaacetic acid, a triethylenetetraminehexaacetic acid and a hydroxyethyliminodiacetic acid. Examples of the compound containing a group having polymerization inhibiting ability and a group interacting with the aluminum support surface include 2-trimethoxysilylpropylthio-1,4-benzoquinone, 2,5-bis(trimethoxysilylpropylthio)-1,4-benzoquinone, 2-carboxyanthraquinone and 2-trimethylammonioanthraquinone=chloride.

The coating solution for the undercoat layer is obtained by dissolving the above-described polymer resin for undercoating and necessary additives in an organic solvent (e.g., methanol, ethanol, acetone, methyl ethyl ketone) and/or water. The coating solution for the undercoat layer may contain an ultraviolet absorbent.

As for the method of coating the coating solution for the undercoat layer on a support, various known methods may be used. Examples thereof include bar coater coating, rotary coating, spray coating, curtain coating, dip coating, air knife coating, blade coating and roll coating.

The coated amount (solid content) of the undercoat layer is preferably from 0.1 to 100 mg/m², more preferably from 1 to 30 mg/m².

### [Protective Layer]

The lithographic printing plate precursor of the invention preferably comprises a protective layer (overcoat layer) on the image recording layer.

The protective layer has a function of blocking oxygen to prevent an image formation inhibiting reaction and also has a function of preventing, for example, scratching in the image recording layer or ablation at the exposure with a high illuminance laser.

Components and the like constituting the protective layer are described below.

Usually, exposure of a lithographic printing plate is performed in the air. The image forming reaction occurred in the image recording layer upon exposure may be inhibited by a low molecular weight compound such as oxygen or basic substance present in the air. The protective layer prevents the low molecular weight compound such as oxygen or basic substance from intermixing into the image recording layer and as a result, suppresses the reaction of inhibiting image formation in the air. Accordingly, the property required of the protective layer is low permeability to the low molecular compound such as oxygen. Furthermore, the protective layer is required to have good transparency to light used for exposure and excellent adherence to the image recording layer and be easily removable in the on-press development process after exposure. The protective layer having such properties is described, for example, in U.S. Pat. No. 3,458,311 and JP-B-55-49729.

As for the material used in the protective layer, both a water-soluble polymer and a water-insoluble polymer may be appropriately selected and used. Specific examples thereof include a water-soluble polymer such as polyvinyl alcohol, modified polyvinyl alcohol, polyvinylpyrrolidone, polyvinylimidazole, polyacrylic acid, polyacrylamide, partially saponified polyvinyl acetate, ethylene-vinyl alcohol copolymer, water-soluble cellulose derivative, gelatin, starch derivative and gum arabic; and a polymer such as polyvinylidene chloride, poly(meth)acrylonitrile, polysulfone, polyvinyl chloride, polyethylene, polycarbonate, polystyrene, polyamide and cellophane.

Two or more kinds of these materials may be used in combination, if desired.

Out of these materials, the relatively useful material includes a water-soluble polymer compound with excellent crystallinity. Specific suitable examples thereof include polyvinyl alcohol, polyvinylpyrrolidone, polyvinylimidazole, a water-soluble acrylic resin such as polyacrylic acid, gelatin and gum arabic. Among these, in view of being coatable by using water as a solvent and easily removable with a fountain solution at the printing, polyvinyl alcohol, polyvinylpyrrolidone and polyvinylimidazole are preferred. Above all, polyvinyl alcohol (PVA) provides best results in terms of fundamental properties such as oxygen blocking and removability in development.

The polyvinyl alcohol usable in the protective layer may be partially substituted by an ester, an ether or an acetal as long as it contains a substantial amount of an unsubstituted vinyl alcohol unit having necessary water solubility. Also, the polyvinyl alcohol may partially contain other copolymerization components. Examples of such a polyvinyl alcohol which can be preferably used include polyvinyl alcohols having various polymerization degrees and having various hydrophilic modified sites at random, such as anion-modified site modified with an anion (e.g., carboxyl, sulfo), cation-modified site modified with a cation (e.g., amino, ammonium), silanol-modified site and thiol-modified site; and polyvinyl alcohols having various polymerization degrees and having various modified sites at the polymer chain terminal, such as anion-modified site described above, cation modified site described above, silanol-modified site, thiol-modified site, alkoxy-modified site, sulfide-modified site, ester-modified site modified with an ester of vinyl alcohol and various organic acids, ester-modified site modified with an ester of the above-described anion-modified site and alcohols, and epoxy-modified site.

The suitable modified polyvinyl alcohol includes a compound being hydrolyzed in a ratio of 71 to 100 mol % and having a polymerization degree of 300 to 2,400. Specific examples thereof include PVA-105, PVA-110, PVA-117, PVA-117H, PVA-120, PVA-124, PVA-124H, PVA-CS, PVA-CST, PVA-HC, PVA-203, PVA-204, PVA-205, PVA-210, PVA-217, PVA-220, PVA-224, PVA-217EE, PVA-217E, PVA-220E, PVA-224E, PVA-405, PVA-420, PVA-613 and L-8, produced by Kuraray Co., Ltd.

Other examples of the modified polyvinyl alcohol include KL-318, KL-118, KM-618, KM-118 and SK-5102 each having an anion-modified site; C-318, C-118 and CM-318 each having a cation-modified site; M-205 and M-115 each having a terminal thiol-modified site; MP-103, MP-203, MP-102 and MP-202 each having a terminal sulfide-modified site; HL-12E and HL-1203 each having an ester-modified site with a higher fatty acid at the terminal; and R-1130, R-2105 and R-2130 each having other reactive silane-modified site.

The protective layer preferably also contains an inorganic layered compound, that is, a compound which is an inorganic compound having a layered structure and has a tabular shape. By using such an inorganic layered compound in combination, the oxygen blocking property is more enhanced and not only the film strength of the protective layer is more increased to raise the scratch resistance but also a matting property can be imparted to a specific protective layer.

Examples of the inorganic layered compound include a mica group such as natural mica represented by the formula: A(B,C)₂-5D₄O₁₀(OH,F,O)₂, [wherein A is Li, K, Na, Ca, Mg or an organic cation, B and C each is Fe(II), Fe(III), Mn, Al, Mg or V, and D is Si or Al] and synthetic mica; a talc represented by the formula: 3MgO.4SiO.H₂O; teniolite; montmorillonite; saponite; hectolite; and zirconium phosphate.

Out of the mica compound, examples of the natural mica include muscovite, paragonite, phlogopite, biotite and lepidolite. Examples of the synthetic mica include a non-swelling mica such as fluorphlogopite KMg₃(AlSi₃O₁₀)F₂ and potassium tetrasilicon mica KMg_{2.5}(Si₄O₁₀)F₂; and a swelling mica such as Na tetrasilicic mica NaMg_{2.5}(Si₄O₁₀)F₂, Na or Li teniolite (Na,Li)Mg₂Li(Si₄O₁₀)F₂, and montmorillonite-based Na or Li hectolite (Na,Li)_{1/8}Mg_{2/5}Li_{1/8}(Si₄O₁₀)F₂. Synthetic smectite is also useful.

Among these mica compounds, a fluorine-based swelling mica that is a synthetic layered compound is particularly useful. More specifically, the swelling clay minerals such as mica, montmorillonite, saponite, hectolite and bentonite have a layered structure comprising a unit crystal lattice layer having a thickness of approximately from 10 to 15 Å and are significantly larger in the extent of the intra-lattice metallic atom substitution than other clay minerals. As a result, the lattice layer causes lack of positive charge and in order to compensate for the lack, a cation such as Li⁺, Na⁺, Ca²⁺, Mg²⁺ and organic cation (e.g., amine salt, quaternary ammonium salt, phosphonium salt, sulfonium salt) is adsorbed between layers. The layered compound swells with water and when a shearing force is applied in this state, the layers are easily cleaved to form a stable sol in water. This tendency is strong in bentonite and swelling synthetic mica, and these materials are useful in the present invention. Above all, in view of easy availability and uniform quality, swelling synthetic mica is preferred.

The shape of the layered compound is tabular and from the standpoint of diffusion control, the thickness is preferably as small as possible. Also, insofar as the smoothness of the coated surface or the transmission of the actinic ray is not inhibited, the plane size is preferably as large as possible. Accordingly, the aspect ratio is 20 or more, preferably 100 or more, more preferably 200 or more. Incidentally, the aspect ratio is a ratio of the thickness to the long diameter of a particle and may be determined, for example, from the projection drawing by the microphotograph of a particle. As the aspect ratio is larger, the effect obtained is greater.

As for the particle diameter of the layered compound, the average long diameter is from 0.3 to 20 μm, preferably from 0.5 to 10 μm, more preferably from 1 to 5 μm. If the particle diameter is less than 0.3 μm, penetration of oxygen or moisture is insufficiently inhibited and the effect brought out is not enough, whereas if it exceeds 20 μm, storage stability in the coating solution is insufficient and this causes a problem that the coating cannot be stably performed. The average thickness of the particle is 0.1 μm or less, preferably 0.05 μm or less, more preferably 0.01 μm or less. For example, the swelling synthetic mica as a typical compound out of the layered inorganic compounds has a thickness of 1 to 50 nm and a plane size of approximately from 1 to 20 μm.

When a particle of such an inorganic layered compound having a large aspect ratio is incorporated into the protective layer, the coated film strength is increased and permeation of oxygen or moisture can be effectively inhibited, as a result, the protective layer is prevented from deterioration due to deformation or the like and the lithographic printing plate precursor obtained can have excellent storage stability without causing reduction in the image forming property due to change in the humidity even if stored under high humidity condition for a long period of time.

An example of the dispersion method in general when using a layered compound in the protective layer is described below.

First, from 5 to 10 parts by mass of the swelling layered compound described above as a preferred layered compound is added to 100 parts by mass of water and after well wetting and swelling with water, dispersed by means of a dispersing machine. Examples of the dispersing machine used here include various mills of directly applying a mechanical force to effect dispersing, a high-speed stirring dispersing machine having a high shear force, and a dispersing machine giving a high-intensity ultrasonic energy. Specific examples thereof include a ball mill, a sand grinder mill, a viscomill, a colloid mill, a homogenizer, a dissolver, a Polytron, a homomixer, a homoblender, a Keddy mill, a jet agitator, a capillary emulsifier, a liquid siren, an electromagnetic strain ultrasonic generator, and an emulsifier having a Pohlman whistle. The dispersion containing 5 to 10 mass % of the inorganic layered compound dispersed by the method above is highly viscous or gelled and extremely good in the storage stability.

At the time of preparing a coating solution for protective layer by using this dispersion, the coating liquid is preferably prepared by diluting the dispersion with water and after thoroughly stirring, blending it with a binder solution.

The content of the inorganic layered compound in the protective layer is preferably from 5/1 to 1/100 in terms of the mass ratio based on the amount of the binder used in the protective layer. Even in the case of using a plurality of kinds of inorganic layered compounds in combination, the total amount of these inorganic layered compounds is preferably in the range of mass ratio above.

As to other additives to the protective layer, for example, glycerin, dipropylene glycol, propionamide, cyclohexanediol or sorbitol may be added to the water-soluble or water-insoluble polymer in an amount of several mass % based on the polymer so as to impart flexibility. Also, a known additive such as water-soluble (meth)acrylic polymer or water-soluble plasticizer may be added so as to improve the physical properties of the film.

In the present invention, the protective layer is formed using the later-described coating solution for protective layer, and in this coating solution, known additives for enhancing the adherence to the image recording layer or the aging stability of the coating solution may be added.

That is, in the coating solution for protective layer, an anionic surfactant, a nonionic surfactant, a cationic surfactant and a fluorine-containing surfactant may be added for enhancing the coatability, and specific examples thereof include an anionic surfactant such as sodium alkylsulfate and sodium alkylsulfonate; an amphoteric surfactant such as alkylaminocarboxylate and alkylaminodicarboxylate; and a nonionic surfactant such as polyoxyethylene alkyl phenyl ether. The amount of the surfactant added is from 0.1 to 100 mass % based on the water-soluble or water-insoluble polymer.

In addition, for improving the adherence to the image part, it is indicated, for example, in JP-A-49-70702 and British Patent Publication 1303578 that sufficiently high adherence can be obtained when from 20 to 60 mass % of an acrylic emulsion, a water-insoluble vinylpyrrolidone-vinyl acetate copolymer or the like is mixed with a hydrophilic polymer mainly composed of polyvinyl alcohol and the polymer is stacked on the image recording layer. In the present invention, these known techniques all can be used.

Furthermore, the above-described ink receptivity agent such as low-molecular nitrogen compound or ammonium alt-containing polymer may also be added to the protective layer. By this addition, an effect of more enhancing the inking property can be obtained. In the case of adding an ink receptivity agent to the protective layer, the amount added is preferably from 0.5 to 30 mass %.

Other functions may also be imparted to the protective layer. For example, by adding a colorant (e.g., water-soluble dye) having excellent transmittance to the infrared light used for exposure and being capable of efficiently absorb light at other wavelengths, the safelight immunity can be enhanced without causing reduction in the sensitivity. Also, for the purpose of controlling the slipperiness on the outermost surface of the lithographic printing plate precursor, the protective layer may contain such a spherical inorganic fine particle as added to the image recording layer. Suitable examples of the inorganic fine particle include silica, alumina, magnesium oxide, titanium oxide, magnesium carbonate, calcium alginate and a mixture thereof. The inorganic fine particle preferably has an average particle diameter of 5 nm to 10 μm, more preferably from 50 nm to 3 μm. The inorganic fine particle described above is easily available on the market as a colloidal silica dispersion or the like.

The content of the inorganic fine particle is preferably 40 mass % or less, more preferably 20 mass % or less, based on the entire solid content of the protective layer.

The coating solution for protective layer prepared by dispersing or dissolving these protective layer components in a solvent is coated on the image recording layer and dried, whereby the protective layer is formed.

The coating solvent may be appropriately selected according to the binder but in the case of using a water-soluble polymer, distilled water or purified water is preferably used as the solvent.

The coating method of the protective layer is not particularly limited, and a known method such as method described in U.S. Pat. No. 3,458,311 and JP-B-55-49729 may be applied.

Specific examples of the coating method when forming the protective layer include a blade coating method, an air knife coating method, a gravure coating method, a roll coating method, a spray coating method, a dip coating method and a bar coating method.

The coated amount of the protective layer is, in terms of the coated amount after drying, preferably from 0.01 to 10 g/m², more preferably from 0.02 to 3 g/m², and most preferably from 0.02 to 1 g/m².

### [Backcoat Layer]

After the support is subjected to a surface treatment or an undercoat layer (described later) is formed, a backcoat may be provided on the back surface of the support, if desired.

Suitable examples of the backcoat layer include a coat layer comprising an organic polymer compound described in JP-A-5-45885 and a coat layer comprising a metal oxide obtained by hydrolyzing and polycondensing an organic or inorganic metal compound described in JP-A-6-35174. Among these, those using an alkoxy compound of silicon, such as Si(OCH₃)₄, Si(OC₂H₅)₄, Si(OC₃H₇)₄ and Si(OC₄H₉)₄, are preferred because the raw material is inexpensive and easily available.

### [Plate-Making Method]

The plate-making method of the lithographic printing plate precursor of the present invention includes on-press development comprising a step of imagewise exposing the lithographic printing plate precursor, and a printing step of performing printing by supplying an oil-based ink and an aqueous component without applying any development processing to the lithographic printing plate precursor after exposure, where the unexposed area of the lithographic printing plate precursor is removed during the printing step. The imagewise exposure may be performed after first loading the lithographic printing plate precursor on a printing press, or the lithographic printing plate precursor after exposure may be loaded on a printing press. The printing plate precursor is then directly subjected to printing using the printing press by supplying a printing ink and a fountain solution, whereby on-press development, that is, removal of the image recording layer in the unexposed region, is effected in the early stage in the process of printing. As a result, the hydrophilic support surface is exposed to provide a fountain solution-accepting region and the printing can be performed.

This is described in more detail below.

The light source used for image exposure in the present invention is preferably a laser. The laser for use in the present invention is not particularly limited, but suitable examples thereof include a solid or semiconductor laser of emitting an infrared ray at a wavelength of 760 to 1,200 nm.

The output of the infrared laser is preferably 100 mW or more and the exposure time per one pixel is preferably 20 microseconds or less. Also, the dose of energy irradiated is preferably from 10 to 300 mJ/cm². As for the laser, in order to shorten the exposure time, a multi-beam laser device is preferably used.

The exposed lithographic printing plate precursor is loaded on a plate cylinder of a printing press. In the case of a printing press with a laser exposure unit, the lithographic printing plate precursor is imagewise exposed after loading it on the plate cylinder of the printing press.

When the lithographic printing plate precursor is imagewise exposed with an infrared laser and then used for printing by supplying a fountain solution and a printing ink without passing through a development step such as wet development, the image recording layer cured by the exposure forms a printing ink-receiving part with a lipophilic surface in the exposed area of the image recording layer. On the other hand, in the unexposed area, the uncured image recording layer is removed by dissolving or dispersing in the supplied fountain solution and/or printing ink, and the hydrophilic surface in this portion is revealed. As a result, the fountain solution adheres to the revealed hydrophilic surface and the printing ink adheres to the image recording layer in the exposed region, thereby initiating the printing.

Here, either the fountain solution or the printing ink may be first supplied to the plate surface, but the printing ink is preferably first supplied so as to prevent the fountain solution from being contaminated by the image recording layer components removed. As for the fountain solution and the printing ink, a fountain solution and a printing ink for normal lithographic printing are used.

In this way, the lithographic printing plate precursor is on-press developed on an off-set printing press and used directly for printing a large number of sheets.

### EXAMPLES

The present invention is described in greater detail below by referring to the Examples, but the present invention should not be construed as being limited thereto.

### Examples 1 to 12 and Comparative Examples 1 to 3

### 1. Production of Lithographic Printing Plate Support

Aluminum plates 1 to 7 were continuously subjected to a surface roughening treatment (here, a broad surface roughening treatment including an alkali etching treatment and a desmutting treatment), an anodization treatment and a hydrophilic treatment in this order to obtain a lithographic printing plate support.

### <Aluminum Plates 1 to 7>

A molten metal was prepared using an aluminum alloy (Aluminum 1 to 7) containing various metals in a ratio (mass %) shown in Table 1 (with the balance of Al and unavoidable impurities) and after molten metal treatment and filtration, an ingot having a thickness of 500 mm and a width of 1,200 mm was produced by a DC casting method. The surface was scalped in an average thickness of 10 mm by a scalping machine, and the ingot was then held at a soaking temperature of 550° C. for about 5 hours and when the temperature dropped to 400° C., rolled using a hot rolling mill into a 2.7 mm-thick rolled plate. The rolled plate was further heat-treated at 500° C. by using a continuous annealing machine and finished to a thickness of 0.24 mm by cold rolling. In this way, Aluminum Plates 1 to 7 with a thickness of 1,030 mm were obtained.

TABLE 1

| Alu- | | | | | | | | | |
|---|---|---|---|---|---|---|---|---|---|
| minum | Si | Fe | Cu | Mn | Mg | Cr | Zn | Ti | Bal. |
| 1 | 0.080 | 0.280 | 0.005 | 0.001 | 0.010 | 0.001 | 0.003 | 0.021 | Al |
| 2 | 0.080 | 0.260 | 0.005 | 0.001 | 0.010 | 0.001 | 0.003 | 0.021 | Al |
| 3 | 0.080 | 0.240 | 0.005 | 0.001 | 0.010 | 0.001 | 0.003 | 0.021 | Al |
| 4 | 0.080 | 0.200 | 0.005 | 0.001 | 0.010 | 0.001 | 0.003 | 0.021 | Al |
| 5 | 0.080 | 0.240 | 0.005 | 0.001 | 0.200 | 0.001 | 0.003 | 0.021 | Al |
| 6 | 0.080 | 0.300 | 0.005 | 0.001 | 0.010 | 0.001 | 0.003 | 0.021 | Al |
| 7 | 0.080 | 0.320 | 0.005 | 0.001 | 0.010 | 0.001 | 0.003 | 0.021 | Al |

* Unit is mass %.

### <Surface Roughening Treatment>

After applying a degreasing treatment with an aqueous 10 mass % sodium aluminate solution at 50° C. for 30 seconds to remove the rolling oil on the surface, the aluminum plate surface was grained using three nylon brushes implanted with bundled bristles having a bristle diameter of 0.3 mm and a water suspension (specific gravity: 1.1 g/cm³) of pumice having a median diameter of 25 μm and then thoroughly washed with water. This plate was etched by dipping it in an aqueous 25 mass % sodium hydroxide solution at 45° C. for 9 seconds and after washing with water, dipped in 20 mass % nitric acid at 60° C. for 20 seconds, followed by washing with water. At this time, the etched amount of the grained surface was about 3 g/m².

Subsequently, the aluminum plate was subjected to continuous electrochemical surface-roughening treatment by using an AC voltage at 60 Hz. The electrolytic solution used here was an aqueous 1 mass % nitric acid solution (containing 0.5 mass % of aluminum ion) at a liquid temperature of 50° C. This electrochemical surface-roughening treatment was performed using an AC power source of giving AC with a trapezoidal rectangular waveform such that the time TP necessary for the current value to reach the peak from zero was 0.8 msec and the duty ratio was 1:1, by disposing a carbon electrode as the counter electrode. For the auxiliary anode, ferrite was used. The current density was 30 A/dm² in terms of the peak value of current, and 5% of the current flowing from the power source was split to the auxiliary anode.

The quantity of electricity at the nitric acid electrolysis was 175 C/dm² when the aluminum plate was serving as the anode. Thereafter, the aluminum plate was washed with water by spraying.

Thereafter, the aluminum plate was subjected to electrochemical surface-roughening treatment in the same manner as in the nitric acid electrolysis above by using an electrolytic solution of an aqueous 0.5 mass % hydrochloric acid solution (containing 0.5 mass % of aluminum ion) at a liquid temperature of 50° C. under the conditions of the quantity of electricity being 50 C/dm² when the aluminum plate was serving as the anode, and then washed with water by spraying.

### <Anodization Treatment>

A DC anodic oxide film having a thickness of 2.5 g/m² was formed on the plate by using an electrolyte solution of 15 mass % sulfuric acid (containing 0.5 mass % of aluminum ion) at an electric current density of 15 A/dm², then washed with water and dried.

### <Hydrophilic Treatment>

For ensuring hydrophilicity of the non-image part, the plate was subjected to a silicate treatment with an aqueous 2.5 mass % No. 3 sodium silicate solution at 70° C. for 10 seconds. The amount of Si attached was 10 mg/m². Thereafter, the plate was washed with water. In this way, Aluminum Supports 1 to 7 were obtained. The centerline average roughness (Ra) of these substrates was measured using a needle having a diameter of 2 μm and found to be 0.51 μm in all substrates.

### 2. Formation of Undercoat Layer

The coating solution shown below was coated on each of Aluminum Supports 1 to 7 to have a dry coated amount of 28 mg/m², thereby providing an undercoat layer.

### <Coating Solution for Undercoat Layer>

| | |
|---|---|
| Compound (1) for Undercoat Layer having a | 0.18 g |
| structure shown below | |
| Hydroxyethyliminodiacetic acid | 0.10 g |
| Methanol | 55.24 g |
| Water | 6.15 g |

### Compound (I) for Undercoat Layer:

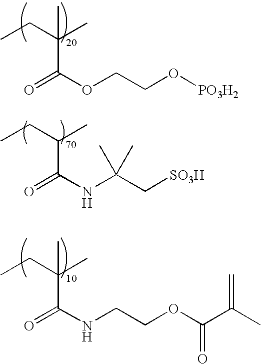

### 3. Formation of Image Recording Layer

On the undercoat layer formed as above, a coating solution for image recording layer was bar-coated and then dried in an oven at 100° C. for 60 seconds to form an image recording layer having a dry coated amount of 1.3 g/m².

The coating solution for image recording layer was obtained by mixing each photosensitive solution shown in Table 2 and a microgel solution immediately before coating.

### <Photosensitive Solutions 1 to 5>

| Binder Polymer (1) [having a structure shown below: | 0.24 | g |
|---|---|---|
| component (E)] | | |
| Infrared Absorbent (1) [having a structure shown below: | 0.030 | g |
| component (A)] | | |
| Radical Polymerization Initiator (1) [having a structure shown | Shown in | |
| below: component (B)] | Table 2 | |
| Polymerizable compound [component (C)]: | 0.192 | g |
| tris(acryloyloxyethyl)isocyanurate (NK ESTER A-9300, | | |
| produced by Shin-Nakamura Chemical Co., Ltd.) | | |
| Hydrophilic low-molecular compound: tris(2- | 0.062 | g |
| hydroxyethyl)isocyanurate | | |
| Hydrophilic Low-Molecular Compound (1) [having a | shown in | |
| structure shown below] | Table 2 | |
| Ink receptivity agent: Phosphonium Compound (1) [having a | 0.055 | g |
| structure shown below] | | |
| Ink receptivity agent: benzyl-dimethyl-octyl ammonium PF₆ | shown in | |
| salt | Table 2 | |
| Betaine compound [Compound C-1) | 0.010 | g |
| Fluorine-Containing Surfactant (1) [having a structure shown | 0.008 | g |
| below] | | |
| Methyl ethyl ketone | 1.091 | g |
| 1-Methoxy-2-propanol | 8.609 | g |

### <Microgel Solution (1)>

| | | |
|---|---|---|
| Microgel (1) | 2.640 | g |
| Distilled water | 2.425 | g |

Structures of Binder Polymer (1), Infrared Absorbent (1), Radical Polymerization Initiator (1), Phosphonium Compound (1), Hydrophilic Low-Molecular Compound (1) and Fluorine-Containing Surfactant (1) are shown below.

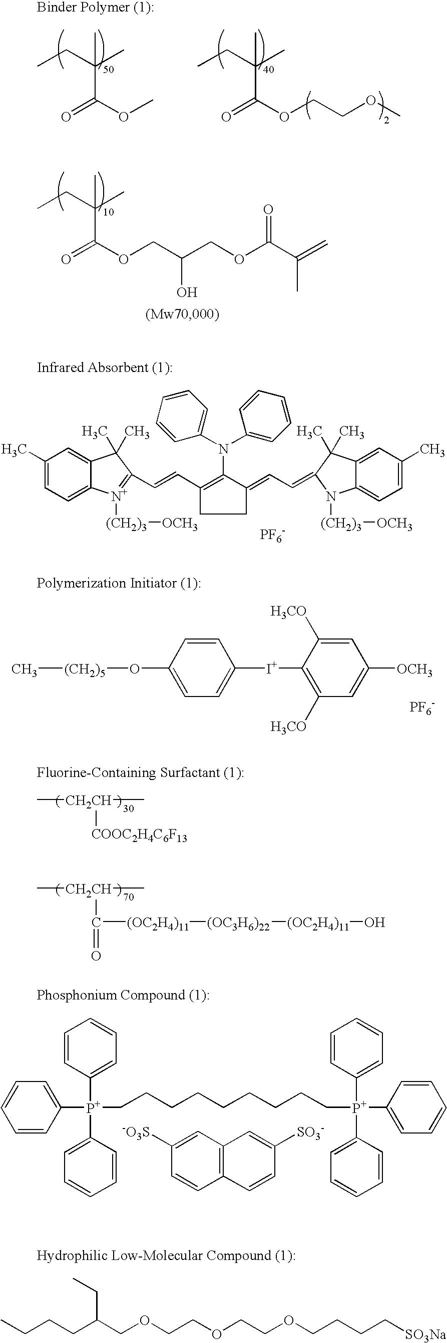

Microgel (1) was synthesized as follows.

### Synthesis of Microcapsule (1):

As the oil phase component, 10 g of trimethylolpropane and xylene diisocyanate adduct (Takenate D-110N, produced by Mitsui Takeda Chemicals, Inc.), 3.15 g of pentaerythritol triacrylate [component (C)] (SR444, produced by Nippon Kayaku Co., Ltd.), 0.1 g of Pionin A-41C (produced by Takemoto Yushi Co., Ltd.) were dissolved in 17 g of ethyl acetate. As the aqueous phase component, 40 g of an aqueous 4 mass % PVA-205 solution was prepared. The oil phase component and the aqueous phase component were mixed and emulsified in a homogenizer at 12,000 rpm for 10 minutes. The resulting emulsified product was added to 25 g of distilled water, and the mixture was stirred at room temperature for 30 minutes and then stirred at 50° C. for 3 hours. The thus-obtained microgel solution was diluted with distilled water to a solid content concentration of 15 mass %. This is used as Microgel (1). The average particle diameter of the microgel was measured by a light scattering method, as a result, the average particle diameter was 0.2 μm.

### 4. Formation of Protective Layer (1)

Coating Solution (1) for Protective Layer having the following composition was bar-coated on the image recording layer formed above and then dried in an oven at 120° C. for 60 seconds to form Protective Layer (1) having a dry coated amount of 0.15 g/m², thereby obtaining a lithographic printing plate precursor.

### <Coating Solution (1) for Protective Layer>

| | |
|---|---|
| Inorganic Layered Compound Liquid Dispersion (1) | 1.5 g |
| Polyvinyl alcohol (CKS50, produced by The Nippon | 0.55 g |
| Synthetic Chemical Industry Co., Ltd., modified with sulfonic | |
| acid, saponification degree: 99 mol % or more, polymerization | |
| degree: 300), 6 mass % aqueous solution | |
| Polyvinyl alcohol (PVA-405, produced by Kuraray Co., Ltd., | 0.03 g |
| saponification degree: 81.5 mol %, polymerization degree: | |
| 500), 6 mass % aqueous solution | |
| Surfactant (Emalex 710, produced by Nihon Emulsion Co., | 8.60 g |
| Ltd.), 1 mass % aqueous solution | |
| Ion-exchanged water | 6.0 g |

### (Preparation of Inorganic Layered Compound Liquid Dispersion (1))

In 193.6 g of ion-exchanged water, 6.4 g of synthetic mica, SOMASIF ME-100 (produced by CO-OP Chemical Co., Ltd.), was added and dispersed using a homogenizer until the average particle diameter (according to a laser scattering method) became 3 μm. The aspect ratio of the resulting dispersed particle was 100 or more.

TABLE 2

| | | | Amount Added of | Amount Added of | | |
|---|---|---|---|---|---|---|
| | | | Radical | Hydrophilic Low- | Amount Added of Benzyl- | Quantitative |
| | Aluminum | Photosensitive | Polymerization | Molecular Compound | dimethyl-octyl ammonium | Determination of |
| | Plate | Solution | Initiator (g) | (1) (g) | PF₆ Salt (g) | Anion (mmol/m²) |
| Example 1 | 1 | 3 | 0.162 | 0.052 | 0.018 | 0.520 |
| Example 2 | 2 | 3 | 0.162 | 0.052 | 0.018 | 0.520 |
| Example 3 | 3 | 3 | 0.162 | 0.052 | 0.018 | 0.520 |
| Example 4 | 4 | 3 | 0.162 | 0.052 | 0.018 | 0.520 |
| Example 5 | 1 | 1 | 0.263 | 0.052 | 0.018 | 0.720 |
| Example 6 | 1 | 2 | 0.175 | 0.052 | 0.018 | 0.600 |
| Example 7 | 1 | 4 | 0.088 | 0.052 | 0.018 | 0.450 |
| Example 8 | 1 | 5 | 0.088 | 0.000 | 0.012 | 0.270 |
| Example 9 | 3 | 1 | 0.263 | 0.052 | 0.018 | 0.720 |
| Example 10 | 3 | 4 | 0.088 | 0.052 | 0.018 | 0.450 |
| Example 11 | 3 | 5 | 0.088 | 0.000 | 0.012 | 0.270 |
| Example 12 | 5 | 3 | 0.162 | 0.052 | 0.018 | 0.520 |
| Comparative | 6 | 3 | 0.162 | 0.052 | 0.018 | 0.520 |
| Example 1 | | | | | | |
| Comparative | 7 | 3 | 0.162 | 0.052 | 0.018 | 0.520 |
| Example 2 | | | | | | |
| Comparative | 7 | 5 | 0.088 | 0.000 | 0.012 | 0.270 |
| Example 3 | | | | | | |

### 5. Evaluation of Lithographic Printing Plate Precursor

The obtained lithographic printing plate precursor was evaluated for the on-press developability and printing stain associated with corrosion as follows. The results are shown in Table 2.

### (1) On-Press Developability

The obtained lithographic printing plate precursor was exposed by Luxel PLATESETTER T-6000111 equipped with an infrared semiconductor laser, produced by Fujifilm Corp. under the conditions of a rotational number of outer surface drum of 1,000 rpm, a laser output of 70% and a resolution of 2,400 dpi. The exposure image was designed to contain a solid image and a 50% halftone dot chart of a 20 μm-dot FM screen.

The exposed lithographic printing plate precursor was loaded on a plate cylinder of a printing press (LITHRONE 26, manufactured by Komori Corp.) without performing development. Using a fountain solution (Ecolity-2, produced by Fujifilm Corp./tap water=2/98 (by volume)) and a black ink (Values-G(N), produced by Dainippon Ink & Chemicals, Inc.), the printing plate precursor was on-press developed by supplying the fountain solution and the ink according to the standard automatic printing start method of LITHRONE 26 and then used for printing on 100 sheets of Tokubishi art paper (76.5 kg) at a printing speed of 10,000 sheets per hour.

The number of printing papers required until completing the on-press development of the unexposed area of the image recording layer on the printing press and providing a state of the ink being not transferred to the non-image part was measured and evaluated as the on-press developability. The results obtained are shown in Table 3. As to the number of sheets in terms of waste paper for the on-press development, the allowable level was set at 30 sheets or less.

(2) Printing Stain Associated with Corrosion

The obtained lithographic printing plate precursor was humidity-conditioned together with inserting paper in an environment of 25° C. and 70% RH for 1 hour and after packaged with aluminum craft paper, heated in an oven set to 60° C. for 5 days. Thereafter, the temperature was lowered to room temperature, and the printing plate precursor was loaded on a plate cylinder of a printing press (LITHRONE 26, manufactured by Komori Corp.) without performing development. Using a fountain solution (Ecolity-2, produced by Fujifilm Corp./tap water=2/98 (by volume)) and a black ink (Values-G(N), produced by Dainippon Ink & Chemicals, Inc.), the printing plate precursor was on-press developed by supplying the fountain solution and the ink according to the standard automatic printing start method of LITHRONE 26 and then used for printing on 500 sheets of Tokubishi art paper (76.5 kg).

The 500th printed matter was confirmed with an eye, and the number of printing stains of 20 μm or more per 100 cm² was calculated. As for the number of printing stains due to corrosion, the allowable level in practical use was set at 200 stains or less per 100 cm². The results are also shown in Table 3.

TABLE 3

| | | | | | Printing Stain |
|---|---|---|---|---|---|
| | | Photo- | Quantitative | On-Press | of 20 μm or |
| | Aluminum | sensitive | Determination of | Developability | More (stains/ |
| | Plate | Solution | Anion (mmol/m²) | (sheets) | 100 cm²) |
| Example 1 | 1 | 3 | 0.520 | 20 | 150 |
| Example 2 | 2 | 3 | 0.520 | 20 | 100 |
| Example 3 | 3 | 3 | 0.520 | 20 | 70 |
| Example 4 | 4 | 3 | 0.520 | 20 | 10 |
| Example 5 | 1 | 1 | 0.720 | 20 | 190 |
| Example 6 | 1 | 2 | 0.600 | 20 | 170 |
| Example 7 | 1 | 4 | 0.450 | 22 | 100 |
| Example 8 | 1 | 5 | 0.270 | 28 | 90 |
| Example 9 | 3 | 1 | 0.720 | 20 | 100 |
| Example 10 | 3 | 4 | 0.450 | 21 | 50 |
| Example 11 | 3 | 5 | 0.270 | 29 | 30 |
| Example 12 | 5 | 3 | 0.520 | 20 | 70 |
| Comparative | 6 | 3 | 0.520 | 20 | 650 |
| Example 1 | | | | | |
| Comparative | 7 | 3 | 0.520 | 20 | 1000 |
| Example 2 | | | | | |
| Comparative | 7 | 5 | 0.270 | 28 | 700 |
| Example 3 | | | | | |

As seen from Table 3, by virtue of reduction in the iron content of the aluminum plate, stain resistance of the non-image part can be improved. Also, it is confirmed that as the anion amount is smaller, the stain resistance is more improved.

What is claimed is:

1. A lithographic printing plate precursor comprising: an image recording layer; and a support obtained by subjecting an aluminum plate having an iron content of 0.28 mass % or less to a surface roughening treatment and to an anodization treatment.

2. The lithographic printing plate precursor as claimed in claim 1, wherein the image recording layer is an on-press developable image recording layer

3. The lithographic printing plate precursor as claimed in claim 1, wherein the iron content of the aluminum plate is 0.26 mass % or less.

4. The lithographic printing plate precursor as claimed in claim 1, wherein a content of an anion component in the lithographic printing plate precursor is 0.7 mmol/m² or less.

5. The lithographic printing plate precursor as claimed in claim 4, wherein the content of an anion component in the lithographic printing plate precursor is 0.5 mmol/m² or less.

6. The lithographic printing plate precursor as claimed in claim 5, wherein the content of an anion component in the lithographic printing plate precursor is 0.3 mmol/m² or less.

7. The lithographic printing plate precursor as claimed in claim 1, wherein the image recording layer is of photopolymerization type.

8. The lithographic printing plate precursor as claimed in claim 1, wherein the image recording layer comprises: an infrared absorbent; a radical polymerization initiator; and a polymerizable compound.

9. The lithographic printing plate precursor as claimed in claim 1, wherein the image recording layer comprises: an infrared absorbent; and a hydrophobing precursor.

10. The lithographic printing plate precursor as claimed in claim 1, wherein the aluminum plate has a thickness of from 0.1 to 0.6 mm.
